(19) United States
(12) Patent Application Publication
(10) Pub. No.: US 2026/0227772 A1
(43) Pub. Date: Aug. 6, 2026

(54) Inspection Management System and Method

(71) Applicant: Hitachi High-Tech Corporation, Minato-ku, Tokyo (JP)

(72) Inventors: Ayana MURAKI, Tokyo (JP); Yutaka IKKU, Tokyo (JP); Makoto SATO, Tokyo (JP)

(21) Appl. No.: 19/150,218

(22) PCT Filed: Jan. 25, 2023
(86) PCT No.: PCT/JP2023/002231

§ 371 Date: Jul. 23, 2025

(51) Int. Cl. G05B 19/418

(52) U.S. Cl. CPC G05B 19/4189; G05B 19/41855; G05B 2219/32114; G05B 2219/45031

(57) ABSTRACT

The invention provides a technique capable of improving efficiency and the like of inspection processing including a transfer processing operation for a plurality of sites of a plurality of wafers in an inspection system. An inspection system 1 performs an inspection processing sequence including processing of producing a thin piece from a sample (a wafer) for each side which is an inspection target location, transferring the thin piece to a carrier, and inspecting each thin piece on the carrier. An inspection management system 2 creates instruction information including an instruction of an order of transfer and the transfer destination carrier for a processing operation of taking out a plurality of the thin pieces from a plurality of the sites of a plurality of the samples and transferring the thin pieces to a plurality of the carriers, which is instruction information related to a processing operation of the inspection processing sequence of the inspection system 1.

### TECHNICAL FIELD

The present disclosure relates to a semiconductor manufacturing process and a semiconductor device inspection processing technique.

### BACKGROUND ART

As the miniaturization of a structure of a semiconductor device, an increased density of a circuit pattern, multi-layered wiring, and the like progress, the importance of cross section analysis and the like becomes increasingly critical for a wafer by using, for example, a transmission electron microscope (TEM) or a scanning transmission electron microscope (STEM) in order to improve reliability or the like.

In imaging, observation, measurement, analysis, evaluation, inspection, and the like (which may be collectively referred to as inspection for the sake of description) of a sample in a semiconductor manufacturing process, for example, a focused ion beam (FIB) device performs thinning machining on a designated location of a wafer to produce a thin piece (also referred to as a lamella, a thin film sample, or the like) where a cross-sectional structure of a device is exposed. The thin piece is transferred to a carrier, and a cross-sectional structure of the thin piece is observed using, for example, a TEM device.

Examples of the related art include JP2014-022296A (PTL 1). PTL 1 discloses a charged particle beam device capable of performing machining using an FIB and performing observation using a scanning electron microscope (SEM). In the charged particle beam device, a cross section of a machined lamella (a thin piece) is acquired as an SEM image, the SEM image is compared with a reference image prepared in advance, and when the images do not match, the cross section is specified as a defective portion. The machined lamella is extracted by a mechanical probe and a deposition function provided in the charged particle beam device.

### CITATION LIST

### Patent Literature

PTL 1: JP2014-022296A

### SUMMARY OF INVENTION

### Technical Problem

Efficient operation and management are required for a series of sequences (which may be referred to as an inspection processing sequence or the like) related to inspection processing of a semiconductor device in the related art. The inspection processing sequence is shared and implemented by various devices such as an FIB-SEM device, a lift out device, and a TEM device.

For example, an inspection in an IC manufacturing process is performed by observing a TEM image using a TEM device. In this case, a manufacturing management system of a manufacturing line of a semiconductor manufacturing plant sets an inspection target location on a wafer which is a sample, and provides inspection target location information, an inspection instruction, the wafer, and the like to an inspection system. The inspection system forms and produces a thin piece by perform thinning machining on the inspection target location of the wafer using, for example, an FIB-SEM device. On the wafer on which the thin piece is formed, the thin piece is taken out by, for example, a lift out device, and the thin piece is transferred to a carrier. Thereafter, a cross section of the thin piece on the carrier is observed using a TEM image obtained by, for example, a TEM device.

The inspection system in the related art needs to be improved in terms of efficiency and the like when performing inspection processing including a transfer processing operation, for example, a processing operation of taking out the thin piece from the wafer and transferring the thin piece to the carrier for a plurality of inspection target locations (may referred to as sites) of a plurality of wafers.

For example, suitable TEM observation conditions may be different for each site of a wafer in the related art. In the related art, when such a plurality of sites of a plurality of wafers are subject to inspection processing performed by an inspection system, thin pieces taken out from sequentially loaded wafers are sequentially simply transferred to a carrier. The plurality of thin pieces transferred to the carrier may have different suitable TEM observation conditions. In this case, when a plurality of thin pieces on the carrier are sequentially observed with a TEM device, switching of observation conditions and the like may frequently occur. In this case, a time such as a turnaround time (TAT) in the TEM device becomes long, and observation efficiency is not good.

On the other hand, when a carrier which is a transfer destination is changed for each site of a wafer in an FIB-SEM device or a lift out device, loading and unloading of the wafer, loading and unloading of the carrier, and the like may frequently occur. In this case, a time such as a TAT in the FIB-SEM device or the lift out device becomes long, and efficiency in the FIB-SEM device or the lift out device is not good.

An object of the present disclosure is to provide a technique capable of improving efficiency and the like of inspection processing including a transfer processing operation for a plurality of sites of a plurality of wafers in an inspection system in relation to the above-described inspection processing technique.

### Solution to Problem

A representative embodiment of the present disclosure has the following configuration. An inspection management system according to an embodiment is an inspection management system for managing an inspection of a sample performed by an inspection system that inspects the sample. The inspection performed by the inspection system is implemented as an inspection processing sequence in which first processing, second processing, and third processing are sequentially performed by a first type device, a second type device, and a third type device that are devices for performing different kinds of processing. The inspection system is configured to perform the inspection processing sequence including producing a thin piece from the sample at each site that is a target location of the inspection, transferring the thin piece to a carrier, and performing processing related to the inspection for each of the thin pieces on the carrier. The inspection management system is configured to create instruction information including an instruction of an order of transfer and the transfer destination carrier for a processing operation of taking out a plurality of the thin pieces from a plurality of the sites of a plurality of the samples and transferring the thin pieces to a plurality of the carriers, which is instruction information related to a processing operation of the inspection processing sequence of the inspection system.

### Advantageous Effects of Invention

According to a representative embodiment of the present disclosure, it is possible to improve efficiency and the like of inspection processing including a transfer processing operation for a plurality of sites of a plurality of wafers in the inspection system in relation to the above-described inspection processing technique. Problems, configurations, effects, and the like other than those described above will be made clear in embodiments for carrying out the invention.

### BRIEF DESCRIPTION OF DRAWINGS

FIG. 1 shows a system configuration including an inspection management system and an inspection system according to Embodiment 1.

FIG. 2 shows a configuration example in which a plurality of devices of the inspection system are communicably connected to the inspection management system according to Embodiment 1.

FIG. 3 shows a configuration example of the inspection management system according to Embodiment 1 which is a computer system.

FIG. 4 shows a flow of an outline of inspection processing in the inspection system according to Embodiment 1.

FIG. 5 shows an outline of processing of each device in the inspection system according to Embodiment 1.

FIG. 6 shows an inspection processing sequence in a first type inspection system according to Embodiment 1.

FIG. 7 shows an inspection processing sequence in a second type inspection system according to Embodiment 1.

FIG. 8 shows a configuration example of an FIB-SEM device serving as a thin piece production device according to Embodiment 1.

FIG. 9 shows a configuration example of a lift out device serving as a thin piece transfer device according to Embodiment 1.

FIG. 10 shows a configuration example of a TEM device serving as a thin piece observation device according to Embodiment 1.

FIG. 11 shows a structure example of a thin piece according to Embodiment 1.

FIG. 12 shows a state in which a thin piece is taken out by the lift out device according to Embodiment 1.

FIG. 13 shows a state in which a thin piece is imaged by the lift out device according to Embodiment 1.

FIG. 14 shows a structure example of a carrier according to Embodiment 1.

FIG. 15 shows a state in which a thin piece is transferred to a carrier by the lift out device according to Embodiment 1.

FIG. 16 shows a configuration example when a thin piece is transferred to a carrier according to a micro-sampling method according to Embodiment 1.

FIG. 17 shows another configuration example when a thin piece is transferred to a carrier according to Embodiment 1.

FIG. 18 shows a configuration example when a carrier is held inside a TEM device according to Embodiment 1.

FIG. 19 shows a functional block configuration example of the inspection management system according to Embodiment 1.

FIG. 20 shows a processing flow of the inspection management system according to Embodiment 1.

FIG. 21 shows an example of FOUP information according to Embodiment 1.

FIG. 22 shows an example of a GUI screen when a machining instruction is created according to Embodiment 1.

FIG. 23 shows an example of machining instruction information and a site example according to Embodiment 1.

FIG. 24 shows a GUI example when a classification name is set in the machining instruction according to Embodiment 1.

FIG. 25 shows a screen example when execution of the inspection processing sequence is started according to Embodiment 1.

FIG. 26 shows an example of FOUP and wafer association information in a first step according to Embodiment 1.

FIG. 27 is a schematic diagram showing setting of a FOUP and the like in an FIB-SEM device in a first step in Example 1 according to Embodiment 1.

FIG. 28 is a schematic diagram showing setting of a FOUP, an LC, and the like in a lift out device in a second step in Example 1 according to Embodiment 1.

FIG. 29 shows an example of transfer instruction information in Example 1 according to Embodiment 1.

FIG. 30 shows details of a transfer processing operation in a lift out device in the second step in Example 1 according to Embodiment 1.

FIG. 31 is a schematic diagram showing setting of an LC and the like in a TEM device in a third step in Example 1 according to Embodiment 1.

FIG. 32 is a schematic diagram showing setting of a FOUP, an LC and the like in a first type FIB-SEM device in a first step in Example 2 according to Embodiment 1.

FIG. 33 is a schematic diagram showing setting of an LC and the like in a second type FIB-SEM device in a second step in Example 2 according to Embodiment 1.

FIG. 34 shows a screen example when a priority is set in Example 3 according to Embodiment 1.

FIG. 35 shows an example of machining instruction information in Example 3 according to Embodiment 1.

FIG. 36 shows an example of transfer in consideration of a priority in a lift out device in a second step in Example 3 according to Embodiment 1.

FIG. 37 shows a screen example when a priority is changed in Example 4 according to Embodiment 1.

FIG. 38 shows a screen example when an automatic classification pattern is set in Example 5 according to Embodiment 1.

FIG. 39 shows details of a transfer processing operation in a lift out device in a second step in Example 6 according to Embodiment 1.

FIG. 40 shows an example of a normal operation mode according to Embodiment 1.

FIG. 41 shows an example of a processing operation of a first policy according to a modification of Embodiment 1.

FIG. 42 shows an example of a processing operation of a second policy according to a modification of Embodiment 1.

FIG. 43 shows an example of FOUP management information and LC management information according to a modification of Embodiment 1.

FIG. 44 shows an example in which a transfer destination is determined according to vacancies of an LC according to a modification of Embodiment 1.

FIG. 45 shows an example of an additional inspection according to a modification of Embodiment 1.

FIG. 46 shows an example of an instruction method and communication between the inspection management system and each device of the inspection system according to Embodiment 1.

FIG. 47 shows an example in which a work instruction is issued from the inspection management system according to Embodiment 1.

FIG. 48 shows an example in which efficiency is improved using a plurality of devices of the inspection system according to Embodiment 1.

FIG. 49A is a diagram showing a first example related to transfer and observation of a plurality of thin pieces, which is a diagram related to problems and the like.

FIG. 49B is a diagram showing a second example related to transfer and observation of a plurality of thin pieces, which is a diagram related to problems and the like.

### DESCRIPTION OF EMBODIMENTS

Hereinafter, embodiments of the present disclosure will be described in detail with reference to the drawings. In the drawings, the same components are denoted by the same reference numerals in principle, and repeated description thereof is omitted. In order to facilitate understanding of the invention, expressions of components in the drawings may not represent an actual position, size, shape, range, and the like.

For the sake of description, in the case of describing processing executed by a program, a program, a function, a processing unit, and the like may be described as a main body, but a main body of hardware of processing is a processor, or a controller, a device, a computer, a system or the like implemented by a processor. The computer executes processing according to a program read into a memory by the processor while appropriately using resources such as a memory and a communication interface. Accordingly, a predetermined function, a processing unit, and the like are implemented. The processor is implemented by, for example, a semiconductor device such as a CPU or a GPU. The processor is implemented by a device or a circuit capable of execute a predetermined calculation. Processing can be executed not only by software program processing but also by a dedicated circuit. The dedicated circuit may be an FPGA, an ASIC, a CPLD, or the like.

The program may be installed as data in a target computer in advance, or may be distributed as data from a program source to a target computer. The program source may be a program distribution server on a communication network, or may be a non-transitory computer-readable storage medium (for example, a memory card). The program may include a plurality of modules. A computer system may include a plurality of devices. The computer system may be implemented as a cloud computing system, an IoT system, or the like. Various kinds of data and information are configured with a structure such as a table or a list, but are not limited thereto. Expressions such as identification information, an identifier, an ID, a name, and a number can be mutually replaced.

### Problems and the Like

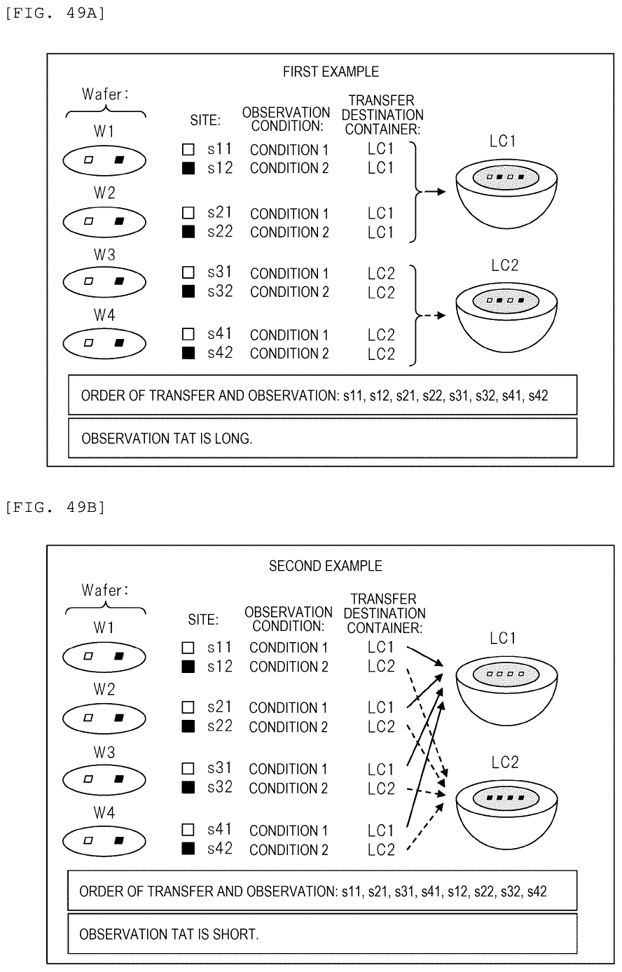

FIGS. 49A and 49B are supplementary diagrams related to problems and the like. FIG. 49A shows a first example. In FIG. 49A, for example, wafers W1 to W4 are conveyed from a manufacturing line to an inspection system. The wafer W1 has sites s11 and s12 as inspection target locations. Similarly, the wafer W2 has sites s21 and s22, the wafer W3 has sites s31 and s32, and the wafer W4 has sites s41 and s42. The sites may have different observation conditions suitable for a TEM device. For example, a suitable observation condition for the sites s11, s21, s31, and s41 indicated by white is a condition 1, and a suitable observation condition for the sites s12, s22, s32, and s42 indicated by black is a condition 2.

In an example of the related art, in a case where there are such target wafers or the like, in inspection processing of an inspection system, thin pieces are sequentially simply taken out from sites of each of a plurality of wafers and transferred to a container (for example, an LC to be described later). In FIG. 49A, for example, a lift out device transfers a thin piece taken out from the site s11 of the wafer W1 to an “LC 1” which is a carrier (a transfer destination container), and transfers a thin piece taken out from the site s12 to the “LC 1”. Next, the lift out device transfers a thin piece taken out from the site s21 of the wafer W2 to the “LC 1”, and transfers a thin piece taken out from the site s12 to the “LC 1”. For example, it is assumed that up to four thin pieces can be transferred to the “LC 1” as a maximum number of transfer. Next, the lift out device transfers a thin piece taken out from the site s31 of the wafer W3 to an “LC 2”, and transfers a thin piece taken out from the site s32 to the “LC 2”. Next, the lift out device transfers a thin piece taken out from the site s41 of the wafer W4 to the “LC 2”, and transfers a thin piece taken out from the site s42 to the “LC 2”. In the first example, an order of transfer and observation is s11, s12, s21, s22, s31, s32, s41, s42.

In the first example, since the transfer of a plurality of thin pieces is subject only to simple sequential processing, a TAT for a transfer processing operation can be relatively shortened. However, when a plurality of thin pieces on a carrier are sequentially observed with a TEM device, since an observation condition changes for each thin piece, a TAT for an observation processing operation becomes long, and observation efficiency is not good.

In the related art, as in the first example, for example, when an observation condition is different for each site of a wafer or when observation conditions are different among wafers, a plurality of thin pieces having different observation conditions are mixed and transferred onto a carrier. In this case, observation efficiency is low. In the related art, in order to increase the efficiency in this case, it is necessary for a user to create and set a detailed inspection instruction in consideration of efficiency and the like. However, it takes much time and effort to create and set such an inspection instruction.

FIG. 49B shows a second example of a transfer processing operation or the like, which is different from the first example. In the second example, an order of transfer and a transfer destination container are controlled in consideration of observation efficiency, that is, in consideration of a difference in an observation condition. In the second example, for the sites of the wafers W1 to W4 the same as in the first example, thin pieces corresponding to the condition 1 are transferred to the “LC 1”, and thin pieces corresponding to the condition 2 are transferred to the “LC 2”. In the second example, an order of transfer and observation is s11, s21, s31, s41, s12, s22, s32, s42.

In the second example, thin pieces are collectively transferred onto the same container (LC) for each observation condition. Accordingly, in a TEM device, since observation is performed under the same observation condition for each container (LC), a switching frequency of the observation condition is few, a TAT for an observation processing operation can be shortened, and observation efficiency can be increased.

The first example is effective when the transfer efficiency is emphasized. The second example is effective when the observation efficiency is emphasized. As in the above examples, an effect varies depending on the order of transfer, the selection of a transfer destination, and the like. An inspection management system according to an embodiment has a function of instructing and controlling different transfer processing operations as in the first example and the second example by using classification information to be described later. According to the embodiment, it is possible to support creation and setting of a complicated inspection instruction, and to reduce the time and effort for a user.

### [Solutions]

In the embodiment, an inspection management system (hereinafter, also simply referred to as a management system) is provided for efficient operation and management of an inspection processing sequence for a semiconductor device performed by an inspection system. The inspection management system according to the embodiment has a function of operating and managing each device constituting each step of the inspection processing sequence in the inspection system, for example, each device such as an FIB-SEM device, a lift out device, and a TEM device. In other words, the inspection management system is a computer system for managing an inspection processing sequence of the inspection system, or an inspection processing sequence management system.

The inspection management system is connected to each device of the inspection system through communication, and has a function of instructing each device to perform a processing operation or the like. The inspection management system has a function of creating instruction information for a processing operation of the inspection processing sequence. The inspection management system has a function of managing execution of the inspection processing sequence by the inspection system based on the instruction information.

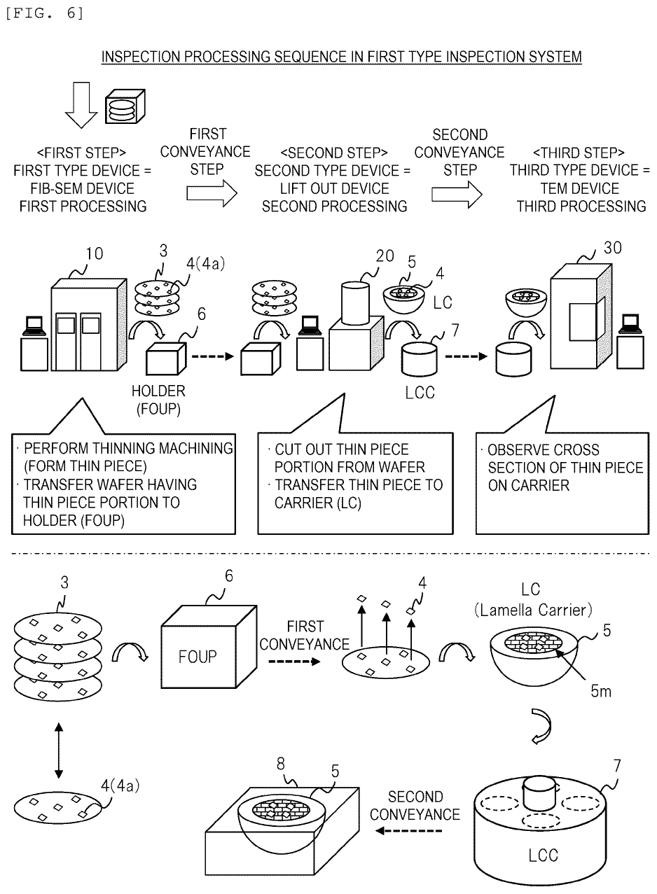

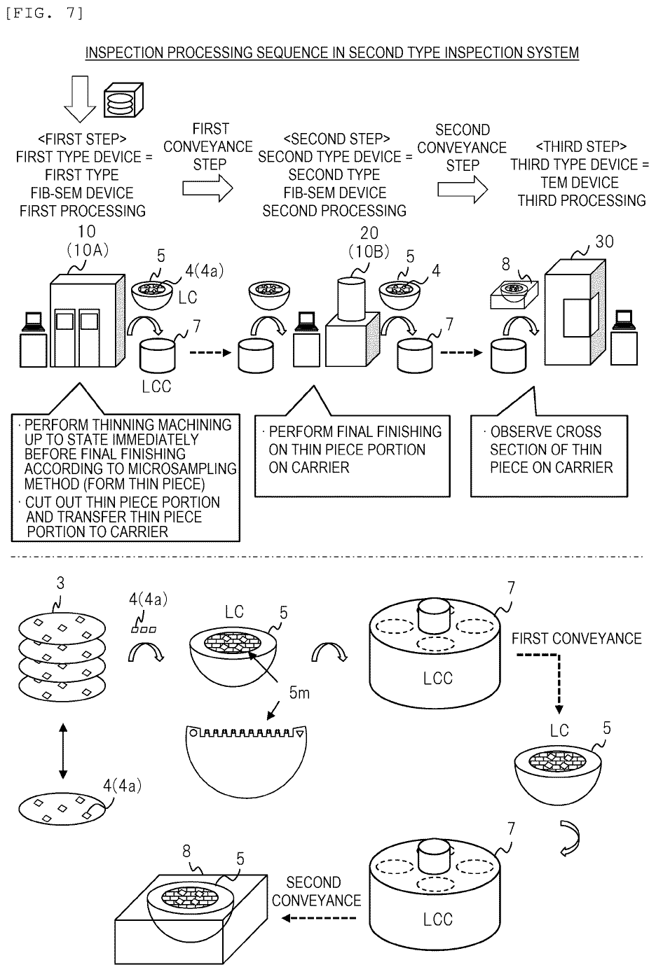

The inspection management system has a function of managing inspection processing sequences of at least two types of inspection systems (FIGS. 6 and 7 to be described later). The two types of management coexist. Two types of inspection systems may be provided in an inspection environment. In this case, the management system creates, as the target, instruction information corresponding to each type of inspection system. The number of devices in each step in the inspection system is one or more, and may be the same or different. For example, in a case where one FIB-SEM device, one lift out device, and one TEM device are set as one set, addition may be performed for each set.

The inspection management system has a function of performing management, instruction, control, and the like for a processing operation of taking out a thin piece from a wafer and transferring the thin piece to a container by devices of the inspection system. The inspection management system has a function of managing containers such as FOUPs and LCs related to transfer, and managing the order of transfer, a transfer destination container, and the like for a processing operation of transferring a plurality of thin pieces. The inspection management system has a function of managing a source, a destination, and the like to and from which a container is conveyed between the devices of the inspection system.

The inspection management system creates a machining instruction or a transfer instruction for new inspection processing based on a sample, an inspection instruction, inspection target location information, and the like from a manufacturing management system. At this time, the inspection management system assigns and sets a classification to a site of a target wafer to be subject to the inspection processing. The inspection management system instructs and controls a processing operation such as transfer based on the classification. Based on the classification, the inspection management system selects the order of transfer of a plurality of thin pieces, a transfer destination container, and the like. Examples of the classification include classification according to a difference in an observation condition in a thin piece observation device, and classification for each wafer.

The inspection management system may assign a classification to each target wafer or each site based on an inspection instruction or the like from the manufacturing management system. A user of the inspection management system may assign the classification. Alternatively, the manufacturing management system may add information corresponding to the classification.

Based on an instruction and information from the inspection management system, each device of the inspection system controls the order of transfer of a plurality of thin pieces, a transfer destination container, a container conveyance destination, and the like, which is a processing operation of inspection processing, and in particular is a processing operation related to transfer.

As control according to the classification, for example, the inspection management system and the inspection system transfer a plurality of thin pieces taken out from a plurality of sites of a target wafer to the same container for the same classification. A plurality of thin pieces on the same container are observed in a thin piece observation device. For example, in a TEM device, an observation condition corresponding to a classification is set and pre-processing is performed on thin pieces on a carrier, and then a plurality of thin pieces can be observed without switching the observation condition for each thin piece. Therefore, observation efficiency of a plurality of thin pieces can be improved.

The inspection management system may set a priority in addition to the classification for a site of a target wafer. When a priority is set, the inspection management system and the inspection system perform control for preferentially performing a processing operation such as transfer of a thin piece according to a level of the priority, in addition to control for determining a transfer destination or the like according to the classification. The priority may be set by the inspection management system or a user, or may be set by the manufacturing management system.

In addition, the inspection management system provides a plurality of predetermined policies (automatic classification patterns and the like) for a method of assigning the classification, and enables a user to select and apply the policies. The inspection management system automatically assigns the classification based on a policy selected by the user. The policy includes, for example, the above-described classification according to a difference in an observation condition in a thin piece observation device, the classification for each wafer, and the like.

The inspection management system according to the embodiment has a function of managing, instructing, controlling, supporting, and the like a transfer processing operation in the inspection system. In a narrow sense, the transfer is an operation of taking out a thin piece formed at a site of a wafer and mounting the thin piece on a carrier by, for example, a lift out device or a first type FIB-SEM device. However, the invention is not limited thereto, and as transfer in a broad sense, the inspection management system according to the embodiment manages, as targets, an operation of storing a wafer on which a thin piece is formed in a holder, an operation of storing a carrier on which a thin piece is mounted in another container (an LCC or a cartridge), an operation of conveying a container such as a holder, a carrier, or an LCC, and the like. That is, the inspection management system according to the embodiment improves efficiency of the inspection processing by managing a processing operation and an object related to movement of a thin piece.

### Embodiment 1

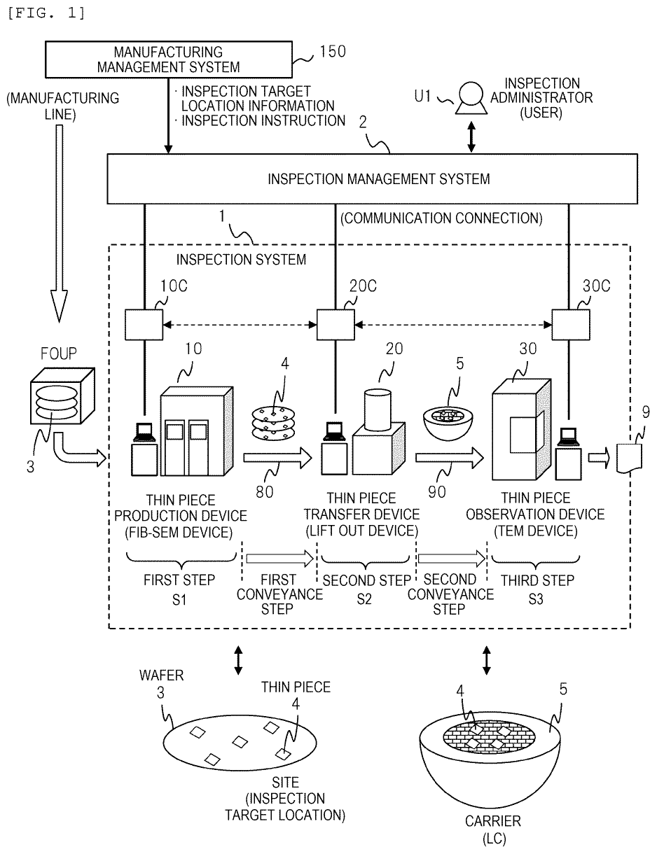

An inspection management system and the like according to Embodiment 1 of the present disclosure will be described with reference to FIG. 1 and subsequent drawings. The inspection management system according to Embodiment 1 is a system that is connected to an inspection system and manages inspection processing executed by the inspection system. An inspection management method according to Embodiment 1 is a method executed by the inspection management system according to Embodiment 1.

### [Overall System]

FIG. 1 shows a configuration of the entire system including the inspection management system according to Embodiment 1 and an inspection system. A management system 2 which is the inspection management system according to Embodiment 1 is communicably connected to an inspection system 1. The inspection system 1 is a system that performs production, transfer, observation, analysis, and the like on thin pieces 4 from a wafer 3 as inspection processing. The management system 2 operates and manages an inspection processing sequence executed by the inspection system 1. In FIG. 1, a case of the inspection system 1 of a first type (FIG. 6) to be described later is shown as an example, but the invention is not limited thereto. A user U1 such as an inspection administrator operates the inspection management system 2 to use a function.

The inspection system 1 includes a thin piece production mechanism, a thin piece transfer mechanism, a thin piece observation mechanism, a control mechanism, and the like. In FIG. 1, the thin piece production mechanism includes a thin piece production device 10, and for example, an FIB-SEM device is applied as the thin piece production device 10. The thin piece transfer mechanism includes a thin piece transfer device 20, and for example, a lift out device is applied as the thin piece transfer device 20. The thin piece observation mechanism includes a thin piece observation device 30, and for example, a TEM device is used as the thin piece observation device 30. The control mechanism includes, for example, controllers 10C, 20C, and 30C provided for each device. The controller for each device manages information of own device and controls a processing operation of own device.

In FIG. 1, for ease of description, the controllers of the devices of the inspection system 1 are shown as blocks of the controllers 10C, 20C, and 30C. These controllers may be built in the devices or may be externally connected. The controllers of the devices may communicate with one another as appropriate. In a case where a controller which is a host control unit is provided for each device such as the FIB-SEM device 10 or the lift out device 20, one controller may control a plurality of devices. The controllers of the devices may be each configured to control the corresponding devices while cooperating with one another through communication.

The inspection system 1 receives an inspection instruction and inspection target location information from a manufacturing management system 150 in a semiconductor manufacturing plant. The inspection system 1 conveys and receives a wafer 3, which is a sample to be inspected, from a semiconductor manufacturing line in the semiconductor manufacturing plant. The wafer 3 is set in the thin piece production device 10. The wafer 3 is conveyed between the semiconductor manufacturing line and the thin piece production device 10 of the inspection system 1 by a predetermined conveyance mechanism. For example, a FOUP, which is a container for storing the wafer 3, is conveyed by an automatic conveyance system, or is manually conveyed by a worker.

The FIB-SEM device 10 which is the thin piece production device 10 forms and produces the thin pieces 4 by performing thinning machining on a designated location (site) of the wafer 3. The lift out device 20 which is the thin piece transfer device 20 takes out the thin piece 4 from the wafer 3 on which the thin piece 4 is formed, the thin piece 4 being produced by the thin piece production device 10, and transfers the thin piece 4 to a carrier 5. Then, a TEM device 30 which is the thin piece observation device 30 observes and analyzes a cross section of the thin piece 4 on the carrier 5, and creates and outputs data 9 and the like as a result.

Various types of data and information may be appropriately exchanged among the devices of the inspection system 1 through communication in order to control the inspection processing. The various types of data and information include, for example, data indicating an inspection target position on a surface of the wafer 3, data indicating a position where the thin piece 4 is successfully created, and data indicating a position of the thin piece 4 mounted on the carrier 5. The data 9 which is an inspection result includes a detection signal related to secondary electrons generated from the thin piece 4 irradiated with a beam, an image obtained based on the detection signal, data obtained as a result of processing the image, data related to X-rays generated from the thin piece 4, and the like.

The inspection system 1 performs a processing operation of producing the thin piece 4 at a designated position of the designated wafer 3 and transferring the thin piece 4 to a designated position on the designated carrier 5 using the devices in a shared manner, and grasps information such as a processing operation, a state, and a position in terms of control. Then, the inspection system 1 outputs an inspection result of the thin piece 4 as the data 9. The management system 2 communicates with each device of the inspection system 1 to grasp the above-described processing operation, state, position, inspection result, and the like in the inspection processing of the inspection system 1.

The wafer 3 on which the thin piece 4 is formed is conveyed between the thin piece production device 10 and the thin piece conveyance device 20 by a conveyance mechanism 80. For example, a holder (details will be described later) for storing the wafer 3 is conveyed by an automatic conveyance system, or is manually conveyed by a worker.

The thin piece 4 is conveyed between the thin piece conveyance device 20 and the thin piece observation device 30 by a conveyance mechanism 90. For example, the carrier 5 (details will be described later) to which the thin piece 4 is transferred is conveyed by an automatic conveyance system, or is manually conveyed by a worker.

It is also possible to convey and return the wafer 3 from the thin piece transfer device 20 to the semiconductor manufacturing line by a conveyance mechanism (not shown). A FOUP, the carrier 5, or the like is used during various types of conveyance. The FOUP is a container filled with an inert gas such as nitrogen, and can store a wafer or the like by loading and unloading the wafer into and from the container.

The wafer 3 used in Embodiment 1 includes a semiconductor substrate formed with a p type or n type impurity region, a semiconductor element such as a transistor formed on the semiconductor substrate, and a wiring layer formed on the semiconductor element. The thin piece 4 is a portion formed on a part of the wafer 3 and taken out. Therefore, the thin piece 4 similarly includes a structure of the semiconductor substrate, the semiconductor element, the wiring layer, and the like of the wafer 3. In Embodiment 1, mainly the thin piece 4 of the wafer 3 used in the semiconductor manufacturing line is an inspection target, but the invention is not limited thereto, and a sample may be a structure used in fields other than the semiconductor technology.

### [Plural Devices and Communication Connection]

The inspection processing in the inspection system 1 for a semiconductor manufacturing process and a semiconductor device is shared and performed by various devices that perform different kinds of processing, and these kinds of processing are sequentially performed as sequence processing among the devices. Such kinds of inspection processing may be referred to as an inspection processing sequence. The management system 2 has a function of operating and managing such an inspection processing sequence of the inspection system 1.

In Embodiment 1, the inspection processing sequence of the inspection system 1 is divided into a plurality of pieces of processing such as first processing executed by the thin piece production device 10 which is a first type device in a first step, second processing executed by the thin piece transfer device 20 which is a second type device in a second step, and third processing executed by the thin piece observation device 30 which is a third type device in a third step. The inspection processing sequence may include two or more types of devices in two or more steps.

A plurality of devices constituting the inspection system 1 include, for example, one or more FIB-SEM devices 10 serving as the first type devices, one or more lift out devices 20 serving as the second type devices, and one or more TEM devices 30 serving as the third type devices in the first type inspection system 1, but the invention is not limited thereto. The number of devices in each step may be only one.

The management system 2 is communicably connected to each device of the inspection system 1. Examples of the communication include, but are not limited to, communication via a LAN. The devices of the inspection system 1, for example, the FIB-SEM device 10, the lift out device 20, and the TEM device 30 may be communicably connected to one another, which is not essential. In Embodiment 1, since the management system 2 is provided, the communication among the devices may be replaced with communication via the management system 2. Each device of the inspection system 1 includes a controller (for example, the controller 10C in FIG. 1) for controlling own device, which is not essential. The management system 2 may also serve as a controller of the devices. In other words, control functions for some devices may be implemented by the management system 2.

When there are a plurality of devices in a step, a device used for a processing operation of the step can be selected from the plurality of devices. Alternatively, a processing operation of a step can be simultaneously processed in parallel by the plurality of devices. Each of the devices of the inspection system 1 may be devices of the same type or may have different functions or the like. For example, when a plurality of FIB-SEM devices 10 are provided in the first step, specifications or the like may be different among the plurality of FIB-SEM devices 10. The management system 2 manages such a difference as information.

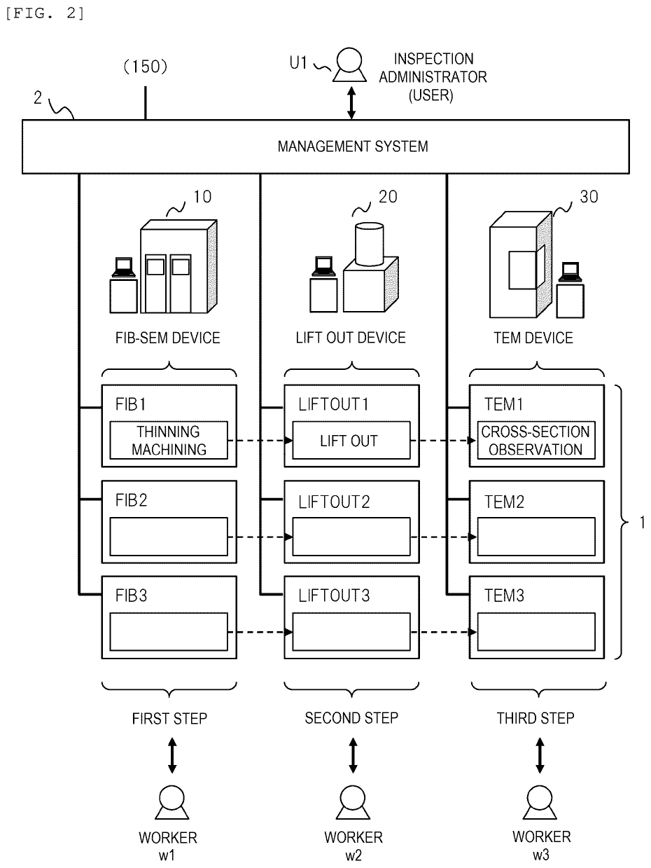

FIG. 2 shows a configuration example in which a plurality of devices constituting the inspection system 1 are connected to the management system 2 by communication (wired or wireless) based on FIG. 1. In the present example, a plurality of the FIB-SEM devices 10 are provided as the thin piece production device 10 in the first step, a plurality of the lift out devices 20 are provided as the thin piece transfer device 20 in the second step, and a plurality of the TEM devices 30 are provided as the thin piece observation device 30 in the third step. In the present example, when one of the FIB-SEM devices 10, one of the lift out devices 20, and one of the TEM devices 30 are set as one set, a case where there are three sets is shown in which the devices are provided together.

The thin piece observation device 30 is not limited to the TEM device, and an STEM device may be applied. The lift out device which is the thin piece transfer device 20 is a device that automatically performs a processing operation of taking out a thin piece portion formed on the wafer 3 as the thin piece 4 and transferring the thin piece portion onto the carrier 5 in the device.

The management system 2 is operated and used by, for example, an inspection administrator such as a user U1. The management system 2 provides a management screen to the user U1. The screen is a screen accompanied by a graphical user interface (GUI) for preforming operation, management, aid, support, visualization, and the like of the inspection processing sequence. In the related art, the inspection system 1 provides a control screen for each device. A device of the inspection system 1 provides a control screen to a user who uses the device. An example of the screen will be described later.

A part of the inspection processing of the inspection system 1 may be performed by a worker. FIG. 2 shows an example in which a worker in charge is associated with each step of the inspection processing sequence. For example, a first worker w1 is associated with the FIB-SEM device 10 in the first step, a second worker w2 is associated with the lift out device 20 in the second step, and a third worker w3 is associated with the TEM device 30 in the third step. The association is not limited thereto, and for example, the same worker may be in charge of a plurality of steps or a plurality of devices.

Each user such as an inspection administrator or a worker may have a mobile terminal or the like for work, and the management system 2 may transmit information to the mobile terminal of each user and display the information on a screen of the mobile terminal. Information transmission and information output from the management system 2 are not limited to the form of screen display, and sound output, lamp lighting control, or the like may be used.

### [Management System]

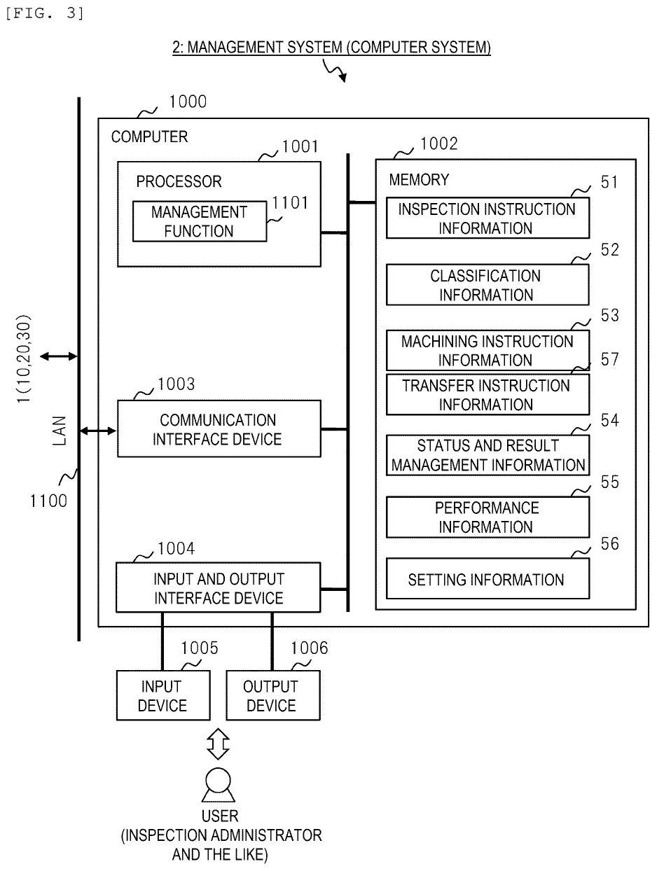

FIG. 3 shows a configuration example of the management system 2 as a computer system 2 and a configuration example of data and information. The computer system 2, which is the management system 2 in FIG. 3, mainly includes a computer 1000. In the present example, the computer 1000 is connected to a LAN 1100 which is a communication network. The computer 1000 may be a PC, a server device, or the like in an implementation example. Each device of the inspection system 1 in FIG. 1 is connected to the LAN 1100. The computer 1000 can communicate with each device of the inspection system 1 through a communication interface device 1003 and the LAN 1100.

The computer 1000 includes a processor 1001, a memory 1002, the communication interface device 1003, an input and output interface device 1004, and the like, which are connected to a bus. The computer 1000 implements a management function 1101 and the like as an execution module by the processor 1001 executing processing according to a control program. The management function 1001 is a part that implements various functions to be described later. The processor 1001 includes, for example, a CPU. The memory 1002 includes, for example, a nonvolatile storage device. The memory 1002 stores preset information, various types of information input by a user, various types of information generated by the computer 1000, and the like. The communication interface device 1003 is mounted with, for example, a communication interface for communicating with an external device via the LAN 1100. An input device 1005 and an output device 1006 are externally connected to the input and output interface device 1004. The input device 1005 and the output device 1006 may be built in the computer 1000. Examples of the input device 1005 include a keyboard, a mouse, and a microphone. Examples of the output device 1006 include a display, a printer, and a speaker.

In the present example, the memory 1002 stores inspection instruction information 51, classification information 52, machining instruction information 53, transfer instruction information 57, status and result management information 54, performance information 55, setting information 56, and the like, which will be described later. These kinds of data and information are created as necessary. The memory 1002 may be implemented as a storage area of an external storage device.

The setting information 56 includes setting information related to a mode of a function related to management of the inspection processing of the inspection system 1, configuration information of the inspection system 1, operation manual information, information on a semiconductor manufacturing plant, design information on a sample, and other kinds of data and information necessary for operation and management in the management system 2.

Other devices may be further connected to the LAN 1100 in FIG. 3. Examples of the other devices include a client terminal device of a user, an external defect inspection device, and a manufacturing execution system (MES). The computer 1000 may communicate with these external devices to input and output necessary data and information. The computer 1000 may be a server, and a client-server system may be provided between the computer 1000 and a client terminal device of a user. In this case, the computer 1000 serving as a server performs main processing, and the client terminal device of the user serves as a GUI. The computer 1000 generates GUI information and data information in a form of a Web page or the like, and transmits the information to the client terminal device of the user. The user can confirm the GUI information and the data information displayed on a screen of the client terminal device, and inputs an instruction and a setting as necessary. The client terminal device transmits the instruction and the like to the computer 1000. The computer 1000 performs processing according to the instruction or the like, and transmits GUI information or the like including a processing result to the client terminal device. The client terminal device displays the information on a screen, and the user can confirm the information on the screen.

### [Inspection Processing Flow of Inspection System]

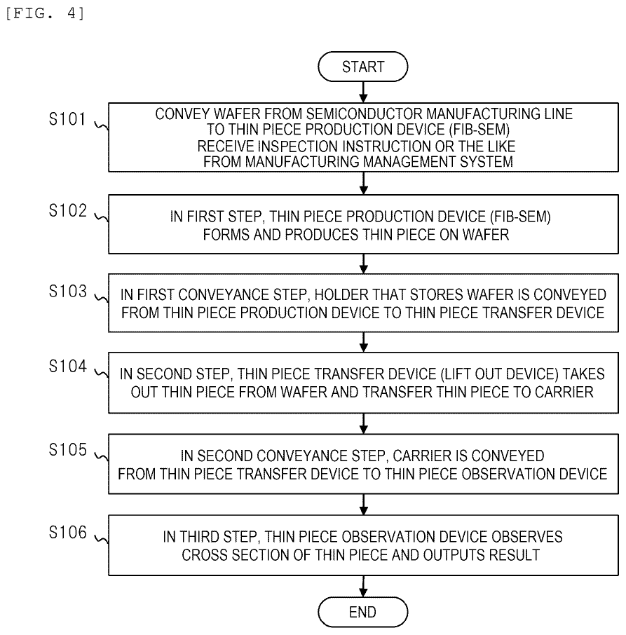

FIG. 4 shows a flow of an outline of inspection processing of the inspection system 1, and includes steps S101 to S106. FIG. 4 shows a case of the inspection processing sequence of the first type inspection system (FIG. 6). The flow is automatically performed and controlled by each device (particularly, the controller 10C or the like in FIG. 1) of the inspection system 1 based on an instruction from the management system 2, but a part of the flow may be manually operated by a user. For example, not only automatic conveyance by an automatic conveyance system but also manual conveyance work by a worker may be applied in a first conveyance step and a second conveyance step. In each step such as the first step, a worker may press a start button at the start of processing in a device.

In step S101, a FOUP that stores the wafer 3 to be inspected is conveyed from a manufacturing line by a conveyance mechanism and reaches a place of the thin piece production device 10 of the inspection system 1. The thin piece production device 10 receives the FOUP and places the wafer 3 on a stage. At this time, a controller of the inspection system 1 or the management system 2 acquires data and information such as inspection target location information and an inspection instruction of the wafer 3 from the manufacturing management system 150. In Embodiment 1, the management system 2 receives data and information such as an inspection instruction from the manufacturing management system 150, and the management system 2 instructs the inspection system 1 to perform inspection processing.

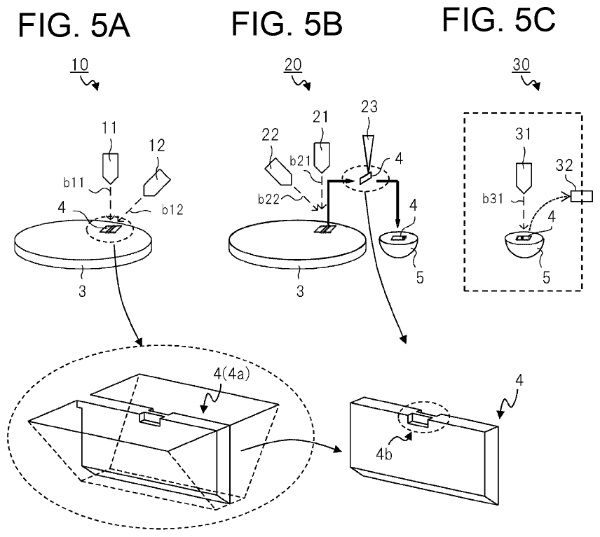

In step S102, the FIB-SEM device 10 which is the thin piece production device 10 in the first step performs a processing operation of thinning machining for forming and producing one or more thin pieces 4 on the wafer 3, which is the first processing. Based on the information received from the management system 2, the thin piece production device 10 positions the field of view at an inspection target position (a site) on a surface of a wafer 1 by moving the stage. Then, the thin piece production device 10 forms a thin piece portion 4a corresponding to the thin piece 4 by irradiating the inspection target position with a beam which is an FIB (see FIG. 5 to be described later).

In step S103, the first conveyance step is performed. In the first conveyance step, the wafer 3 on which the thin piece portion 4a is formed is conveyed from the thin piece production device 10 to the thin piece transfer device 20 by an automatic conveyance system serving as the conveyance mechanism 80 or manual conveyance performed by a worker. The wafer 3 is conveyed in a state of being stored in, for example, a holder (for example, a FOUP) to be described later.

In step S104, the lift out device 20 which is the thin piece transfer device 20 in a second step performs a lift out processing operation of taking out the thin piece 4 from a target position (site) of the wafer 3 and transferring the thin piece 4 onto the carrier 5, which is the second processing. An LC to be described later is used as the carrier 5.

In step S105, the second conveyance step is performed. In the second conveyance step, the carrier 5 on which the thin piece 4 is mounted is conveyed from the thin piece transfer device 20 to the thin piece observation device 30 by an automatic conveyance system serving as the conveyance mechanism 90 or manual conveyance performed by a worker. The carrier 5 is conveyed, for example, in a state of being stored in an LCC to be described later.

In step S106, the TEM device 30 which is the thin piece observation device 30 in a third step observes a cross section of the thin piece 4 on the carrier 5 using a TEM image, performs analysis and inspection, and stores and outputs a result as the data 9, which is the third processing.

### [Devices of Inspection Processing and Outline of Steps]

FIG. 5 shows an outline configuration of processing operations of individual devices of the thin piece production device 10 in the first step, the thin piece transfer device 20 in the second step, and the thin piece observation device 30 in the third step in the first type inspection system 1. (A) of FIG. 5 shows a processing operation of thinning machining performed by, for example, the FIB-SEM device 10 which is the thin piece production device 10 in the first step. (B) of FIG. 5 shows a processing operation of lifting out performed by the lift out device 20 which is the thin piece transfer device 20 in the second step. (C) of FIG. 5 shows a processing operation of observing a cross section by the TEM device 30 which is the thin piece observation device 30 in the third step. An example of the thin piece portion 4a is shown in an enlarged manner on a lower side of (A), and an example of the thin piece 4 is shown in an enlarged manner on a lower side of (B) (details will be described later).

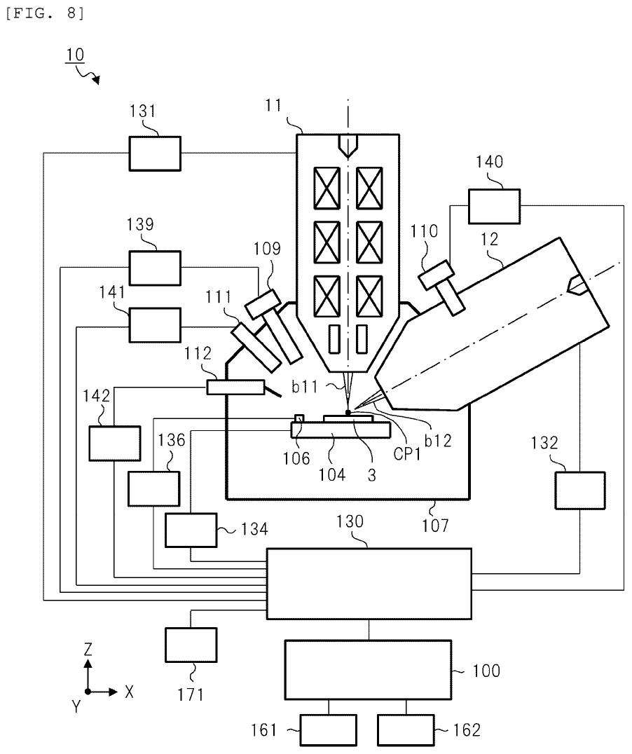

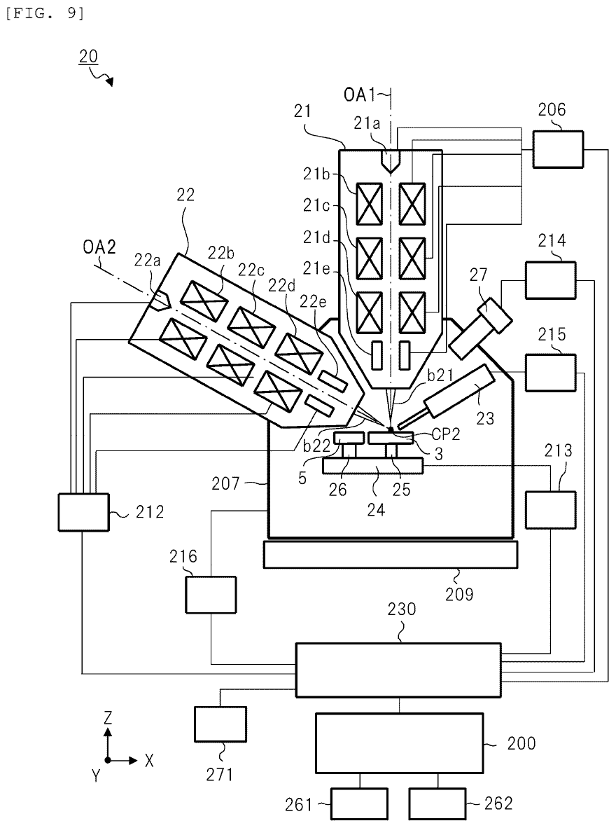

The thin piece production device 10 is implemented by, for example, an FIB-SEM device as shown in FIG. 8 to be described later. The thin piece transfer device 20 is implemented by, for example, a lift out device as shown in FIG. 9 to be described later. The thin piece observation device 30 is implemented by, for example, a TEM device as shown in FIG. 10 to be described later. In other words, these devices are a charged particle beam device, a microscope device, and the like.

In (A) of FIG. 5, the thin piece production device 10 includes at least an FIB column 11 which is an ion beam column 11 and an SEM column 12 which is an electron beam column 12. The ion beam column 11 includes all components necessary for an FIB device, such as an ion source for generating a charged particle beam b11 which is an ion beam b11, a lens for focusing the ion beam b11, and a deflection system for performing scanning using the ion beam b11 and shifting the ion beam b11. The electron beam column 12 includes all components necessary for an SEM device, such as an electron source for generating a charged particle beam b12 which is an electron beam b12, a lens for focusing the electron beam b12, and a deflection system for performing scanning using the electron beam b12 and shifting the electron beam b12.

In the first step, the thin piece production device 10 irradiates the wafer 3 with the ion beam b11 from the ion beam column 11 and performs etching machining on a part of the wafer 3 to produce an outer shape of the thin piece 4 as the thin piece portion 4a. Further, the thin piece production device 10 performs etching machining on a part of the thin piece 4 with the ion beam b11 to produce an analysis portion 4b near an upper surface of the thin piece 4. The analysis portion 4b is subjected to finishing surface processing or the like for later analysis by the TEM device 30. The etching using the ion beam column 11 is performed while irradiating the wafer 3 with the electron beam b12 from the electron beam column 12 and observing an etched location, in other words, imaging and monitoring. One or more thin piece portions 4a corresponding to one or more thin pieces 4 are formed on an upper surface of one wafer 3.

In the first conveyance step, the wafer 3 on which a plurality of the thin pieces 4 are formed is conveyed from the thin piece production device 10 to the thin piece transfer device 20 by the conveyance mechanism 80 in a state where the wafer 3 is stored in, for example, a FOUP. At this time, the management system 2 (or the controller of the inspection system 1) acquires data and information such as a production position of the thin piece 4 on the wafer 3 from the thin piece production device 10. Then, the management system 2 transmits the data and information such as the production position to the thin piece transfer device 20.

In the second step, based on the data and information received from the management system 2, the thin piece transfer device 20 takes out the thin piece 4 from the production position of the wafer 3 using an electron beam column 21, an electron beam column 22, an attaching and detaching device 23, and the like to be described later, and transfers the thin piece 4 onto an LC which is the carrier 5. This transfer is repeated until the transfer is completed for all the thin pieces 4 formed on the surface of the wafer 3.

In the second conveyance step, the carrier 5 to which the thin piece 4 was transferred is conveyed from the thin piece transfer device 20 to the thin piece observation device 30 by the conveyance mechanism 90 in a state where the carrier 5 is set in an LCC or the like. At this time, the management system 2 (or the controller of the inspection system 1) acquires data and information such as a position of the thin piece 4 mounted on the carrier 5 from the thin piece transfer device 20. Then, the management system 2 transmits the data and information to the thin piece observation device 30.

In the third step, the thin piece observation device 30 observes a cross section of the thin piece 4 (particularly, the analysis portion 4b) at a target position on the carrier 5 set inside the device based on the data and information received from the management system 2. The thin piece observation device 30 includes at least an electron beam column 31. The electron beam column 31 includes all components necessary for a TEM device, such as an electron source for generating a charged particle beam b31 which is an electron beam b31, a lens for focusing the electron beam b31, and a deflection system for performing scanning using the electron beam b31 and shifting the electron beam b31. The thin piece observation device 30 is also provided with a detector 32 such as a charged particle detector and an X-ray detector. A TEM image is obtained based on a detection signal from the detector 32.

Observation and analysis for the analysis portion 4b of the thin piece 4 in the thin piece observation device 30 is performed in a state where the thin piece 4 is mounted on the carrier 5 inside the device. In addition, the carrier 5 on which the thin piece 4 is mounted is disposed such that a front surface of the analysis portion 4b of the thin piece 4 (that is, a surface where a cross-sectional structure is exposed) faces the electron beam column 31, in other words, the front surface of the analysis portion 4b is irradiated with the electron beam b31.

The thin piece observation device 30 first irradiates the analysis portion 4b of the thin piece 4 with the electron beam b31 from the electron beam column 31. Particles generated from the analysis portion 4b of the thin piece 4 due to the irradiation are detected by the detector 32 as a detection signal. The detection signal of the detected particles is subjected to calculation processing by a calculation processing unit provided in the detector 32 to form an image. The thin piece observation device 30 analyzes and inspects a structure and the like of the analysis portion 4b of the thin piece 4 based on the acquired image. Further, X-rays generated from the analysis portion 4b are detected by an X-ray detector, and similarly, a substance or the like constituting the analysis portion can be analyzed based on an acquired image.

The data 9 (FIG. 1) generated as a result of the observation and analysis in the thin piece observation device 30 in such a manner is stored in a memory of a controller (for example, the controller 30C in FIG. 1) of the inspection system 1. Further, the data 9 is output and transmitted to the management system 2 and stored in a memory of the management system 2. The management system 2 can store the data 9 in a memory of the management system 2 and display an inspection result on a screen for the user U1 such as an inspection administrator based on the data 9.

### [Transfer Method]

A transfer method of the thin piece 4 differs depending on a configuration of the inspection system 1, in the first type inspection system 1 (FIG. 6), for example, the thin piece 4 is taken out from the wafer 3 by the lift out device 20 in the second step, and the thin piece 4 is transferred to an LC which is the carrier 5. In the second type inspection system 1 (FIG. 7), a first type FIB-SEM device 10A in the first step cuts out the thin piece 4 from the wafer 3 and transfers the thin piece 4 to an LC that is the carrier. The inspection processing sequence including production, transfer, and observation of the thin piece 4 as described above takes a relatively long time. In order to efficiently perform processing operations and work of such an inspection processing sequence, techniques for automation and efficiency improvement are required.

In the related art, a lift out method and a micro-sampling method are known as methods for producing and transferring the thin piece 4. In the case of the lift out method, as shown as a first type (FIG. 6), for example, the thin piece portion 4a formed on the wafer 3 in the FIB-SEM device 10 is taken out and transferred to the carrier by the lift out device 20. In the case of the micro-sampling method, as shown in a second type (FIG. 7), the production of the thin piece 4 and the transfer of the thin piece 4 to the carrier can be performed in the same device, for example, in the first type FIB-SEM device 10A. In either one of the methods, for example, the lift out device 20 or the first type FIB-SEM device 10A can perform a processing operation while monitoring a sample or the like according to an image imaged by an SEM mechanism.

### [Inspection Processing Sequence in First Type Inspection System]

FIG. 6 shows a configuration outline of an inspection processing sequence in the first type inspection system 1. The inspection system 1 receives the wafer 3 which is an inspection target sample from a semiconductor manufacturing line in a plant by, for example, conveying the wafer 3 in a FOUP. The management system 2 receives information such as inspection target location information and an inspection instruction from the manufacturing management system 150 in the plant.

The inspection processing sequence of the first type inspection system 1 includes observation of a cross section of the thin piece 4. The inspection processing sequence of the first type inspection system 1 mainly includes first to third steps. The first type inspection system 1 includes, for example, three types of devices such as the FIB-SEM device 10, the lift out device 20, and the TEM device 30, and the inspection processing sequence is a sequence of continuous processing in the order of these devices. The first step is a thinning machining step, and for example, the FIB-SEM device 10 is used as a first type device. The second step is a lift out step, and the lift out device 20 is used as a second type device. The third step is a cross section observation step, and the TEM device 30 is used as a third type device.

In the first step, the FIB-SEM device 10 performs thinning machining according to a designated recipe at a time (from a start time to an end time) designated by the management system 2, which is first processing. A designated FOUP that stores the designated wafer 3 is set in the FIB-SEM device 10. The FIB-SEM device 10 performs thinning machining, which is the designated first processing, on the designated wafer 3 taken out from the FOUP. The first processing is processing of forming and producing the thin piece portion 4a by perform thinning machining on a region of an inspection target location of the wafer 3 with a charged particle beam. The FIB-SEM device 10 forms the thin piece portion 4a on the wafer 3 while performing monitoring using an SEM image imaged based on the beam. At this time, the thin piece portion 4a is still coupled to the wafer 3 via a part of the wafer 3. The FIB-SEM device 10 stores the wafer 3 on which the thin piece portion 4a is formed in a FOUP which is a holder 6.

There is a first conveyance step between the first step and the second step. In the first conveyance step, for example, an automatic conveyance system conveys the holder 6 (the FOUP) that stores the wafer 3 to the lift out device 20 in the second step via the conveyance mechanism 80. Then, the holder 6 is set in the lift out device 20. In the case of manual conveyance, a worker conveys the holder 6 (the FOUP) to the lift out device 20 and sets the holder 6 in the lift out device 20.

In the second step, the lift out device 20 performs a lift out processing operation according to a designated recipe at a time (from a start time to an end time) designated by the management system 2, which is second processing. The lift out device 20 takes out the thin piece portion 4a from a site at a designated position of the wafer 3 taken out from the set FOUP using the attaching and detaching device 23 (FIG. 5), and transfers the thin piece portion 4a to a designated position on an LC which is the designated carrier 5.

There is a second conveyance step between the second step and the third step. In the second conveyance step, for example, an automatic conveyance system conveys the carrier 5 (specifically, an LCC 7 to be described later) to the TEM device 30 in the third step via the conveyance mechanism 90. Then, the carrier 5 (the LCC 7) is set in the TEM device 30. In the case of manual conveyance, a worker conveys the carrier 5 (the LCC 7) to the TEM device 30 and sets the carrier 5 in the TEM device 30.

In the third step, the TEM device 30 performs a processing operation of observing a cross section of the thin piece 4 according to a designated recipe at a time (from a start time to an end time) designated by the management system 2, which is third processing. The TEM device 30 loads the set carrier 5 (specifically, a cartridge 8 to be described later) into the TEM device 30, and performs TEM image observation for the thin piece 4 on the carrier 5. At this time, the TEM device 3 acquires an image (a TEM image, an STEM image, EBSD, or the like) of the analysis portion 4b of the thin piece 4 on the LC that is the carrier 5 under conditions such as a designated position and magnification. At this time, since a reference capable of low magnification search is designated for positioning the analysis portion 4b to an observation position, search to a final observation position can be automated. The TEM device 30 loads the carrier 5 to the outside after performing the processing operation for a designated number of times and for the designated number of carriers 5.

The TEM device 30 stores, as the data 9, image data of the acquired TEM image and data of a result of processing such as measurement and analysis on the image and transmits the data 9 to the management system 2. The management system 2 receives the data 9 from the TEM device 30 and stores the data 9 in a memory. The management system 2 can display a cross section observation result among inspection processing results on a screen based on the data 9. In addition to transmitting the data 9 from the TEM device 30 to the management system 2, the cross section observation result may be output to a screen of an output device of the TEM device 30 at a place of the TEM device 30.

A specific example of cross section observation on the thin piece 4 in the TEM device 30 is as follows. In the cross section observation, a position, a shape, and a dimension of stacked films and the like are measured, analyzed, and evaluated for a cross-sectional structure appearing in a front surface (particularly, the analysis portion 4b) of the thin piece 4. For example, a width, a depth, and the like of a trench, a hole, or the like are measured. Then, for example, whether a position, a shape, or a dimension of a film or the like is appropriate is evaluated and determined by comparing a measurement value with a reference value.

A conveyance step includes conveyance of the holder 6 (the FOUP) from the manufacturing line to the FIB-SEM device 10, conveyance of the holder 6 (the FOUP) from the FIB-SEM device 10 to the lift out device 20 which is the first conveyance step, and conveyance of the carrier 5 (the LCC 7) from the lift out device 20 to the TEM device 30 which is the second conveyance step. For these conveyance steps, an automatic conveyance method using an automatic conveyance system may be applied, a manual conveyance method by a worker may be applied, or these methods may be mixed. When the automatic conveyance method is used, completely automatic inspection processing can be achieved. Such a conveyance method is defined in advance for each environment of the inspection system 1. The management system 2 has a function corresponding to such a conveyance method. When the manual conveyance method is used, as will be described later, the management system 2 can transmit and notify a work instruction to a worker in charge.

### [Configuration Example of Carrier and the Like of First Type]

In FIG. 6, a configuration example of the carrier 5 and the like in the inspection processing sequence of the first type inspection system 1 is as follows. In the first step, one or more thin piece portions 4a are formed on a surface of the wafer 3 by the FIB-SEM device 10. The wafer 3 on which the thin piece portion 4a is formed is stored in, for example, a front opening unified pod (FOUP) serving as the holder 6. For example, a predetermined number (for example, 20 to 30) of wafers 3 can be stored in one FOUP. The FOUP is conveyed to the lift out device 20.

The lift out device 20 in the second step takes out the thin piece 4 from the wafer 3 using the attaching and detaching device 23, and transfers the taken-out thin piece 4 onto a mesh 5m of a Lamella Carrier (LC) which is the carrier 5. At this time, the thin piece 4 is inserted into, for example, pillars of support portions on the mesh 5m (which will be described later). A predetermined number (for example, 4 to 20) of thin pieces 4 can be mounted on one LC. The LC which is the carrier 5 is further stored in the lamella carrier container (LCC) 7. The LCC 7 is a container capable of storing a plurality of LCs. For example, up to a predetermined number (for example, 8) of LCs can be stored in one LCC 7. The LCC 7 is conveyed to the TEM device 30. In the TEM device 30, the LC which is the carrier 5 is taken out from the LCC 7 and transferred to the cartridge 8 for the TEM device 30, and the cartridge 8 is loaded and set inside the TEM device 30.

### [Second Type Inspection System and Inspection Processing Sequence]

FIG. 7 shows a configuration outline of an inspection processing sequence in the second type inspection system 1. An inspection instruction, conveyance, and the like from a plant are the same as those in the case of the first type. The inspection processing sequence of the second type is mainly different from the inspection processing sequence of the first type in that the second type FIB-SEM device 20 (10B) is used without using the lift out device 20. In addition, in the second type, planar observation of the thin piece 4 (in other words, planar view imaging) can be implemented by the TEM device 30. In the planar observation, TEM image observation is performed in a planar direction of the wafer 3. The function of the management system 2 can be applied to the inspection processing sequence of the second type in a similar manner to the inspection processing sequence of the first type.

The inspection processing sequence of the second type inspection system 1 mainly includes first to third steps. The second type inspection system 1 includes, for example, a set of three types of devices such as the first type FIB-SEM device 10 (10A), the second type FIB-SEM device 20 (10B), and the TEM device 30, and the inspection processing sequence is a sequence of continuous processing in the order of these devices. The first step is a thinning machining step, and for example, the first type FIB-SEM device 10 (10A) is used as a first type device. The second step is a final finishing step, and for example, the second type FIB-SEM device 20 (10B) is used as a second type device. The third step is a cross section observation step, and the TEM device 30 is used as a third type device.

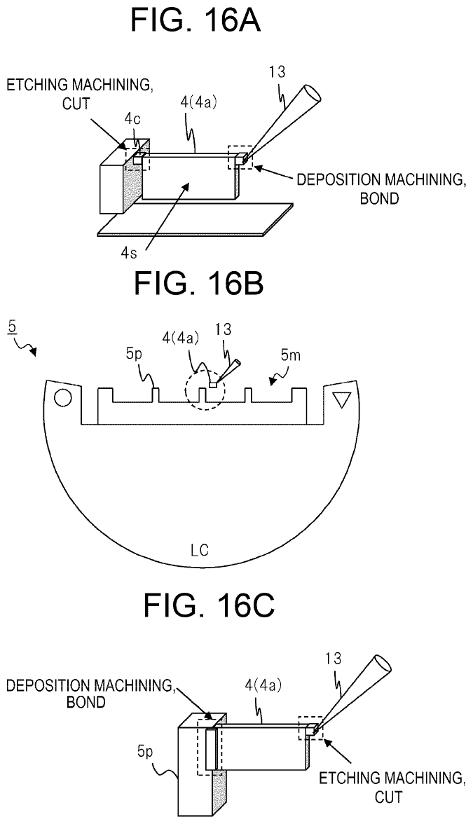

In the first step, the first type FIB-SEM device 10A performs FIB machining up to a state immediately before final finishing as thinning machining on an inspection target position (a site) of the wafer 3 according to a designated recipe, and forms the thin piece portion 4a in such a state, which is first processing. After the machining, the first type FIB-SEM device 10A cuts out the thin piece portion 4a from the wafer 3 by FIB machining and transfers the thin piece portion 4a onto the carrier 5 (see FIG. 16 to be described later). The first type FIB-SEM device 10A loads the carrier 5 to the outside and stores the carrier 5 in the LCC 7. In the case of the second type, the first step includes a processing operation for transferring the thin piece 4 as described above.

In a first conveyance step, for example, an automatic conveyance system transfers the carrier 5 to which the wafer 3 was conveyed to the second type FIB-SEM device 10B in the second step via the conveyance mechanism 80 in a state where the carrier 5 is stored in the LCC 7. Then, the LCC 7 that stores the carrier 5 is set in the second type FIB-SEM device 10B.

In the second step, the second type FIB-SEM device 10B loads the carrier 5 (LC) from the LCC 7, and performs final finishing FIB machining on the thin piece portion 4a on the carrier 5 according to a designated recipe, which is second processing. At this time, the second type FIB-SEM device 10B moves the stage to a final finishing position while observing the final finishing position using an SEM image, and irradiates the thin piece portion 4a at the position with the FIB to perform final finishing FIB machining. This final finishing may take a relatively long time. Therefore, it is effective to improve efficiency of the overall inspection processing by the management system 2 according to Embodiment 1.

The second type FIB-SEM device 10B performs the above-described processing operation for a designated number of times and for the designated number of thin pieces 4, and then loads, to the outside, the LCC 7 that stores the carrier 5 (LC) on which the thin piece 4 in a state after the final finishing is mounted.

In the second conveyance step, for example, an automatic conveyance system conveys the LCC 7 that stores the carrier 5 to the TEM device 30 in the third step via the conveyance mechanism 90. Then, the carrier 5 is set in the TEM device 30 in a state where the carrier 5 is stored in the cartridge 8.

In the third step, the TEM device 30 performs cross section observation (in particular, planar observation) which is third processing. The TEM device 30 loads the cartridge 8 that stores the carrier 5 into the TEM device 30, and brings the processing into a state where the thin piece 4 on the carrier 5 is irradiated with the beam. The TEM device 30 acquires a TEM image of the thin piece 4 on the mesh of the carrier 5 under conditions such as a designated position and magnification. The TEM device 30 loads the cartridge 8 that stores the carrier 5 to the outside after performing the above-described processing operation for a designated number of times and for the designated number of cartridges 8.

### [Configuration Example of Carrier and the Like of Second Type]

In FIG. 7, a configuration example of the carrier 5 and the like in the inspection processing sequence of the second type inspection system 1 is as follows. In the first step, the first type FIB-SEM device 10A forms one or more thin piece portions 4a up to a state immediately before the final finishing on a surface of the wafer 3. The first type FIB-SEM device 10A cuts out the thin piece portion 4a from the wafer 3 and transfers the cut-out thin piece portion 4a onto the mesh 5m of the LC which is the carrier 5. At this time, the thin piece portion 4a in a finishing remaining state is bonded to, for example, a pillar of a support portion on the mesh 5m (see FIG. 16 to be described later). The LC which is the carrier 5 is stored in the LCC 7. The LCC 7 is conveyed to the second type FIB-SEM device 10B in the first conveyance step.

The second type FIB-SEM device 10B in the second step performs final finishing on the thin piece 4 on the carrier 5 (LC) loaded from the LCC 7. The carrier 5 (LC) on which the thin piece 4 after the final finishing is mounted is unloaded and stored in the LCC 7. The LCC 7 at this time may be the same as the LCC 7 at the time of loading. The LCC 7 is conveyed to the TEM device 30 in the second conveyance step. Similarly, in the TEM device 30, the LC which is the carrier 5 is transferred from the LCC 7 to the cartridge 8 for TEM, and the cartridge 8 is loaded and set inside the TEM device 30.

Although depending on mounting, it is assumed that only one wafer 3 and only one LC can be arranged at the same time in a sample chamber of the first type lift out device 20 according to Embodiment 1. Further, it is assumed that only one wafer 3 can be arranged at the same time in a sample chamber of the FIB-SEM device 10 or the first type FIB-SEM device 10A. Further, it is assumed that only one LC can be arranged at the same time in the TEM device 30.

### [Thin Piece Production Device: FIB-SEM Device]

FIG. 8 shows a configuration example of the FIB-SEM device 10 that can be applied as the thin piece production device 10 in the first step in the first type or second type inspection system 1. The FIB-SEM device 10 in FIG. 8 is a device including both an FIB mechanism and an SEM mechanism. The FIB-SEM device 10 can form the thin piece 4 on the wafer 3 using the FIB mechanism, and can image and observe the wafer 3 and the thin piece 4 using the SEM mechanism.

The FIB-SEM device 10 in FIG. 8 includes a sample chamber 107, the ion beam column 11, an ion beam column controller 131, the electron beam column 12, an electron beam column controller 132, a wafer stage 104, a wafer stage controller 134, a sub stage 106, a sub stage controller 136, a probe unit 112, a probe unit controller 142, and the like. The FIB-SEM device 10 includes charged particle detectors 109 and 110, detector controllers 139 and 140, an X-ray detector 111, an X-ray detector controller 141, an integrated control unit 130, a computer system 100, and the like.

The FIB-SEM device 10 includes an ID reader 171, a wafer loading mechanism (not shown), and the like. The ID reader 171 reads an ID of a FOUP set in the FIB-SEM device 10. The wafer loading mechanism is a mechanism that loads the wafer in the FOUP into the sample chamber 107 and unloads the wafer in the sample chamber 107 into the FOUP.

The ion beam column 11 and the electron beam column 12 are mounted in the sample chamber 107. The ion beam column 11 is disposed along a Z-axis direction in which an optical axis (indicated by a one-dot chain line) is a vertical direction. The electron beam column 12 is disposed along a direction in which an optical axis (indicated by a one-dot chain line) is inclined relative to an optical axis of the ion beam column 11. The ion beam b11 which is an FIB is emitted from the ion beam column 11 toward a cross point CP1, and the electron beam b12 is emitted from the electron beam column 12 toward the cross point CP1. The ion beam b11 emitted from the ion beam column 11 and the electron beam b12 emitted from the electron beam column 12 are focused at the cross point CP1 which is an intersection of respective optical axes. In this example, the optical axis of the electron beam column 12 is inclined relative to the optical axis of the ion beam column 11, but the invention is not limited to such a configuration.

The ion beam column 11 includes components necessary for the SEM device, such as an ion source for generating the ion beam b11, a lens for focusing the ion beam b11, a deflection system for performing scanning using the ion beam b11, and a blanking deflection system for blanking the ion beam b11.

The electron beam column 12 includes components necessary for the FIB device, such as an electron source for generating the electron beam b12, a lens for focusing the electron beam b12, a deflection system for performing scanning using the electron beam b12, and a blanking deflection system for blanking the electron beam b12.

The wafer stage 104 is a moving stage on which the wafer 3 serving as a sample can be placed. The sub stage 106 is a moving stage on which the thin piece 4 or the carrier 5 can be placed. The wafer stage 104 and the like can perform planar movement and rotational movement. The integrated control unit 130 controls the movement of the wafer stage 104 via the wafer stage controller 134 to position the wafer stage 104 so that a target location (for example, a location where the thin piece 4 is formed) on the surface of the wafer 3 can be irradiated with a beam.

The charged particle detector 109 detects charged particles generated when a sample is irradiated with the ion beam b11 as a detection signal. The charged particle detector 110 detects charged particles generated when a sample is irradiated with the electron beam b12 as a detection signal. The detector controller 139 performs calculation processing on the detection signal of the charged particle detector 109 to form an image. The detector controller 140 performs calculation processing on the detection signal of the charged particle detector 110 to form an image. The detector controllers 139 and 140 includes a calculation processing unit implemented by a circuit or program processing.

The probe unit 112 picks up the thin piece portion 4a formed on the wafer 3 by a probe under control of the probe unit controller 142. In the case of the second type, the probe unit 112 may be, for example, a mechanism that drives a needle 13 in FIG. 16.

The sample chamber 107 includes, as other components, a gas supply unit (not shown) that supplies a gas used for etching or deposition machining. The sample chamber 107 may include a backscattered electron detector that detects backscattered electrons generated from a sample as another type of detector.

The thin piece production device 10 is not limited to the FIB-SEM device as described above, and an FIB device not including the SEM mechanism may be applied, or an FIB device including an optical microscope instead of the SEM mechanism may be applied.

The integrated control unit 130 controls the entire and each unit of the FIB-SEM device 10. The integrated control unit 130 is electrically connected to a controller of each unit such as the wafer stage controller 134, and can communicate with the controller. The integrated control unit 130 controls a controller and the like of each unit using a control signal. A plurality of controllers may be integrated as one controller. Each controller may be implemented by a computer system, a dedicated circuit, or the like. The computer system 100 is connected to the integrated control unit 130. The integrated control unit 130 controls the entire and an operation of each unit of the FIB-SEM device 10 according to an instruction or the like from the computer system 100.

The computer system 100 provides a user interface including a GUI to a user who uses the FIB-SEM device 10, and receives input of various instructions, settings, and the like by the user. An input device 162, an output device 161, a storage device, and the like are built in or externally connected to the computer system 100. Examples of the input device 162 include a keyboard, a mouse, a touch panel, and a microphone. Examples of the output device 161 include a display, a printer, a speaker, and a lamp. A screen with a GUI is displayed on the display. An image imaged by the FIB-SEM device 10, setting information, user instruction information, and the like are displayed on the screen.

A user such as a worker can confirm various kinds of information, images, and the like on a screen displayed on the display. The user inputs various instructions and settings to the screen using a keyboard or the like. The computer system 100 transmits an instruction or the like to the integrated control unit 130 based on the input instruction, setting, or the like.

The integrated control unit 130 and the computer system 100 may be integrated. The controller 10C in FIG. 1 may be the same as the integrated control unit 130 or the computer system 100, or may be another computer system connected to the integrated control unit 130 or the computer system 100.

The same FIB-SEM device 10 as described above can also be applied to the second type FIB-SEM device 20 (10B) in the second type in FIG. 7.

### [Thin Piece Transfer Device: Lift Out Device]

FIG. 9 shows a configuration example of the lift out device 20 that can be applied as the thin piece conveyance device 20 in the second step in the first type inspection system 1.

The lift out device 20 includes the sample chamber 207, and the sample chamber 207 is provided with the electron beam column 21 serving as a first column, the electron beam column 22 serving as a second column, the attaching and detaching device 23, a movable stage 24, a rotation stage 25 for the wafer 3, a rotation stage 26 for the carrier 5, a charged particle detector 27, and the like. Although details are omitted, a holder for holding the wafer 3 is provided on the rotation stage 25, and a holder for holding the carrier 5 is provided on the rotation stage 26.

The electron beam column 21 which is the first column includes all components necessary for an SEM device, such as an electron source 21a for generating a charged particle beam b21 which is an electron beam b21, condenser lenses 21b and 21c for focusing the electron beam b21, an objective lens 21d, and a deflector 21e for performing scanning using the electron beam b21. The electron source 21a, the condenser lenses 21b and 21c, the objective lens 21d, and the deflector 21e are electrically connected to a controller 206 through a drive control unit (not shown). An operation of the electron beam column 21 is controlled by transmitting a control signal from the controller 206 to each drive control unit.

The electron beam column 22 which is the second column includes all components necessary for an SEM device, such as an electron source 22a for generating a charged particle beam which is an electron beam b22, condenser lenses 22b and 22c for focusing the electron beam b22, an objective lens 22d, and a deflector 22e for performing scanning using the electron beam b22. The electron source 22a, the condenser lenses 22b and 22c, the objective lens 22d, and the deflector 22e are electrically connected to a controller 212 through a drive control unit (not shown). An operation of the electron beam column 22 is controlled by transmitting a control signal from the controller 212 to each drive control unit.

The electron beam column 22 is mounted in the sample chamber 207 at an angle different from that of the electron beam column 21. The electron beam column 21 is disposed in a Z-axis direction which is a vertical direction in the drawing, and the electron beam column 22 is disposed in a direction inclined relative to the Z-axis direction. Therefore, the electron beam b22 is emitted at an angle different from that of the electron beam b21. The electron beam b21 emitted from the electron beam column 21 and the electron beam b22 emitted from the electron beam column 22 are mainly focused on a cross point CP2 which is an intersection of an optical axis OA1 of the electron beam column 21 and an optical axis OA2 of the electron beam column 22.

The movable stage 24 is provided in the sample chamber 207. The rotation stage 25 and the rotation stage 26 are coupled to the movable stage 24. The integrated control unit 230 controls the movement of the movable stage 24 and the like through a controller 213 to position the electron beam b21 and the electron beam b22 so that a target position of a surface of the wafer 3 is irradiated with a beam. The movable stage 24 including the rotation stage 25 and the rotation stage 26 is a movable stage that can perform planar movement, vertical movement, rotational movement, and inclined movement based on drive control.

The detector 27 detects charged particles generated when the wafer 3 or the thin piece 4 is irradiated with the electron beam b21 and the electron beam b22. The detector 27 is electrically connected to a controller 214. The detector 27 is driven and controlled by the controller 214. The controller 214 includes a calculation processing unit that performs calculation processing on a detection signal from the detector 27 to obtain an image. The calculation processing unit is implemented by a circuit or program processing. The sample chamber 207 may be provided with an X-ray detector, a backscattered electron detector, or the like for detecting X-rays, backscattered electrons, or the like generated from the thin piece 4.

The attaching and detaching device 23 is provided in the sample chamber 207 as a mechanism that can reach the cross point CP2. The attaching and detaching device 23 is electrically connected to a controller 215. The attaching and detaching device 23 is driven and controlled by the controller 215. By driving the attaching and detaching device 23, the thin piece 4 can be taken out from the wafer 3 and the thin piece 4 can be transferred to the carrier 5. Further, the attaching and detaching device 23 can perform planar movement, vertical movement, and rotational movement based on drive control. Therefore, when the attaching and detaching device 23 holds the thin piece 4, an orientation of the thin piece 4 can be freely changed. For example, Nano-tweezers are applied as the attaching and detaching device 23.

A degree of vacuum inside the sample chamber 207 is controlled by a controller 216. The sample chamber 207 may be provided on a vibration-proof table 209 in order to prevent vibration. The sample chamber 207 may be further provided with a pressure reduction device for evacuation, a cold trap, an optical microscope, and the like.

The lift out device 20 includes an ID reader 271, a wafer loading mechanism, a carrier loading mechanism, and the like (not shown). The ID reader 271 reads an ID of a FOUP or the carrier 5 set in the lift out device 20. The wafer loading mechanism is a mechanism that loads a wafer in the FOUP into the sample chamber 207 and unloads the wafer in the sample chamber 207 into the FOUP. The carrier loading mechanism is a mechanism that loads an LC of the LCC 7 set in the lift out device 20 into the sample chamber 207 and unloads the LC in the sample chamber 207 into the LCC 7.

Since the lift out device 20 in FIG. 9 includes the electron beam columns 21 and 22 installed in different optical axis directions, it is possible to monitor and grasp a three-dimensional positional relation or the like among the wafer 3, the thin piece 4, the carrier 5, the attaching and detaching device 23, and the like, and to perform an accurate and efficient processing operation (which will be described later).

The integrated control unit 230 controls the entire and each unit of the lift out device 20. The integrated control unit 230 is electrically connected to a controller of each unit such as the controller 213, and can communicate with the controller. The integrated control unit 230 controls a controller and the like of each unit using a control signal. A plurality of controllers may be integrated as one controller. Each controller may be implemented by a computer system, a dedicated circuit, or the like. A computer system 200 is connected to the integrated control unit 230. The integrated control unit 230 controls the entire and an operation of each unit of the lift out device 20 according to an instruction or the like from the computer system 200.

The computer system 200 provides a user interface including a GUI to a user who uses the lift out device 20, and receives input of various instructions, settings, and the like by the user. An input device 262 such as a keyboard, an output device 261 such as a display, a storage device, and the like are built in or externally connected to the computer system 200. A screen with a GUI is displayed on the display. An image imaged by the lift out device 20, setting information, user instruction information, and the like are displayed on the screen.

A user such as a worker can confirm various kinds of information, images, and the like on a screen displayed on the display. The user inputs various instructions and settings to the screen using a keyboard or the like. The computer system 200 transmits an instruction or the like to the integrated control unit 230 based on the input instruction, setting, or the like.

The integrated control unit 230 and the computer system 200 may be integrated. The controller 20C in FIG. 1 may be the same as the integrated control unit 230 or the computer system 200, or may be another computer system connected to the integrated control unit 230 or the computer system 200.

The invention is not limited to the configuration example of the lift out device 20 in FIG. 9. For example, an optical microscope may be provided instead of the electron beam columns 21 and 22. In the configuration example in FIG. 9, the processing operation can be performed in a sealed space in the sample chamber 207, but the invention is not limited thereto, and the sample chamber 207 may be omitted and the processing operation may be performed in the atmosphere.

### [Thin Piece Observation Device: TEM Device]

FIG. 10 shows a configuration example of the TEM device 30 that can be applied as the thin piece observation device 30 in the third step in first type or second type the inspection system 1. The TEM device 30 in FIG. 10 includes an electron beam column 31, an electron beam column controller 32, a sample holder 303 on which the carrier 5 can be placed, a sample holder stage 304, a sample holder stage controller 324, a secondary electron detector 305, a detector controller 325, an X-ray detector 308, an X-ray detector controller 328, and the like. The secondary electron detector 305 and the like correspond to the detector 32 in (C) of FIG. 5.

In addition, the TEM device 30 includes a fluorescent plate 306, a camera 307, a camera controller 327, and the like installed below the electron beam column 31. The TEM device 30 includes an integrated control unit 330 connected to each controller, a computer system 300 connected to the integrated control unit 330, and the like. A keyboard or the like serving as an input device 362 and a display or the like serving as an output device 361 are connected to the computer system 300.

The fluorescent plate 306 is a fluorescent plate that projects a TEM image which is a transmission electron microscope image. The camera 307 is a camera that images the fluorescent plate 306.

The secondary electron detector 305 detects, as a detection signal, particles such as secondary electrons emitted from the thin piece 4 on the carrier 5 serving as a sample. The X-ray detector 308 detects, as a detection signal, X-rays emitted from the thin piece 4 on the carrier 5 serving as a sample.

The TEM device 30 includes an ID reader 371, a carrier loading mechanism (not shown), and the like. The ID reader 371 reads an ID of the carrier 5 set in the TEM device 30. The carrier loading mechanism is a mechanism that loads the carrier 5 (LC) set in the TEM device 30 into the electron beam column 31 and unloads the LC in the electron beam column 31.

The integrated control unit 330 controls the entire and each unit of the TEM device 30. The integrated control unit 330 is electrically connected to a controller of each unit such as a controller 321, and can communicate with the controller. The integrated control unit 330 controls a controller and the like of each unit using a control signal. A plurality of controllers may be integrated as one controller. Each controller may be implemented by a computer system, a dedicated circuit, or the like. A computer system 300 is connected to the integrated control unit 330. The integrated control unit 330 controls the entire and an operation of each unit of the TEM device 30 according to an instruction or the like from the computer system 300.

The computer system 300 provides a user interface including a GUI to a user who uses the TEM device 30, and receives input of various instructions, settings, and the like by the user. An input device 362 such as a keyboard, an output device 361 such as a display, a storage device, and the like are built in or externally connected to the computer system 300. A screen with a GUI is displayed on the display. An image imaged by the TEM device 30, setting information, user instruction information, and the like are displayed on the screen.

A user such as a worker can confirm various kinds of information, images, and the like on a screen displayed on the display. The user inputs various instructions and settings to the screen using a keyboard or the like. The computer system 300 transmits an instruction or the like to the integrated control unit 330 based on the input instruction, setting, or the like.

The integrated control unit 330 and the computer system 300 may be integrated. The controller 30C in FIG. 1 may be the same as the integrated control unit 330 or the computer system 300, or may be another computer system connected to the integrated control unit 330 or the computer system 300.

The electron beam column 31 may be configured to, for example, support both a TEM mode and an STEM mode. The electron beam column 31 includes an electron source, an irradiation lens group, an objective lens, a projection lens group, and the like as a configuration example corresponding to the TEM mode. An electron energy loss spectrometer (EELS), an EELS detector, and the like are provided below the electron beam column 31. In the TEM mode, the above-described analysis portion 4b (FIG. 5) on a front surface (a main surface on which a cross-sectional structure is formed) of the thin piece 4 on the carrier 5 placed on the sample holder 303 is set as an observation region, and the electron beam b31 (only an optical axis is indicated by a one-dot chain line) emitted by the electron beam column 31 is emitted to spread over the entire observation region. The TEM device 30 acquires a projection image, an interference image, a diffraction pattern, and the like generated by the irradiation of the electron beam b31 as a TEM image.

As a configuration example corresponding to the STEM mode, the electron beam column 31 is provided with a polarization system for performing scanning using an electron beam, a diaphragm for controlling an opening angle of the electron beam, and the like, in addition to the components in the TEM mode. In the configuration of the STEM mode, an annular detector for detecting transmitted electrons scattered at a wide angle and a transmitted electron detector for detecting electrons transmitted through a sample are provided instead of the fluorescent plate 306. In the case of the STEM mode, a TEM image is acquired by focusing the electron beam on the thin piece 4 and scanning the analysis portion 4b which is the observation region.

A cold trap, a cooling mechanism, a heating mechanism, a gas supply mechanism, or the like may be provided in the vicinity of the sample (the thin piece 4 on the carrier 5) in the sample holder 303.

### [Structure Example of Thin Piece]

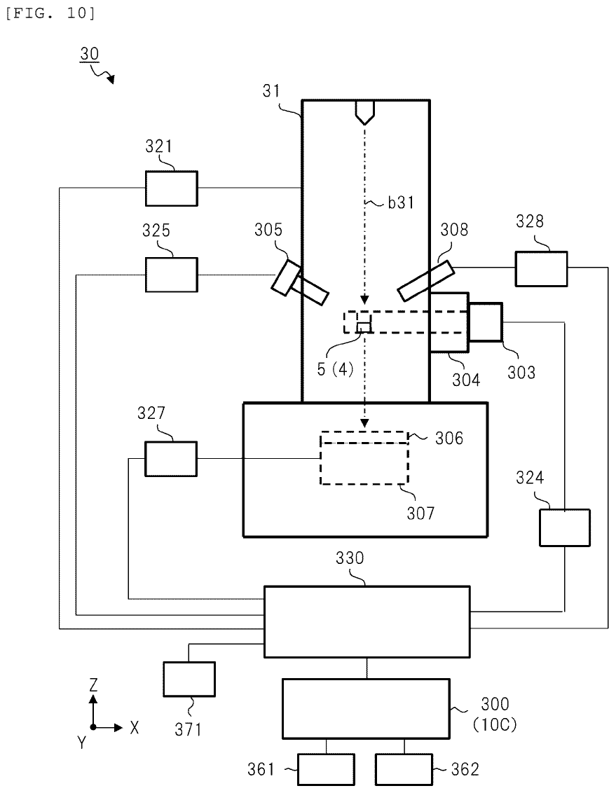

FIG. 11 shows an example of a detailed structure of the thin piece 4. For example, FIG. 11 shows a state of the thin piece 4 and the like when the thin piece 4 is taken out while the thin piece 4 formed on the wafer 3 is observed in the lift out device 20 (FIG. 9) in the second step in the first type inspection system 1. FIG. 11 schematically shows an example of an arrangement of the electron beam column 21 and the electron beam column 22 relative to the thin piece portion 4a on the wafer 3. In the drawings, (X, Y, Z) or the like may be used as a coordinate system for description. An X axis and a Y axis are two orthogonal axes constituting a horizontal plane direction. A Z axis is a vertical direction perpendicular to the X axis and the Y axis.

The thin piece portion 4a as shown is formed on a surface of the wafer 3 by the FIB-SEM device 10 in the first step. A state in which the thin piece 4 was not yet separated from the wafer 3 may be referred to as the thin piece portion 4a. In FIG. 11, a part of the surface of the wafer 3 where the thin piece portion 4a is formed is schematically shown as a perspective view. The thin piece 4 has a width and a thickness in a Y direction smaller than a width and a thickness in an X direction and a width and a thickness in a Z direction. In the thin piece 4, the analysis portion 4b is provided at an upper portion in the Z direction and a central portion in the X direction. The analysis portion 4b is a region to be observed by the thin piece observation device 30. As shown in the drawing, a width and a thickness of the analysis portion 4b in the Y direction are smaller than a width and a thickness of a portion of the thin piece 4 around the analysis portion 4b.

The analysis portion 4b is formed to be thinner than a main body of the thin piece 4, but is not limited thereto, and may have any thickness as long as TEM image observation can be performed. A size of the wafer 3 is, for example, 100 mm to 300 mm, a size of the thin piece 4 is, for example, several μm to several tens of μm, a thickness of the thin piece 4 is, for example, several μm, and a thickness of the analysis portion 4b is, for example, several nm to several tens of nm.

### [Example (1) of Processing Operation of Transferring Thin Piece]

As shown in FIG. 11, in a state before the thin piece portion 4a is taken out, the thin piece 4 is coupled to the wafer 3 by a part of a coupling portion 4c, and the thin piece portion 4a, the coupling portion 4c, and the wafer 3 are integrated. Alternatively, one thin piece portion 4a may be connected by a plurality of coupling portions 4c. When the thin piece 4 is transferred by the lift out device 20, the thin piece 4 is gripped by the attaching and detaching device 23 and is cut out at the coupling portion 4c, thereby separating the thin piece 4 from the wafer 3.

The wafer 3 is placed on the rotation stage 25 in FIG. 9 such that an upper surface of the thin piece 4 faces the electron beam column 21 and a front surface of the thin piece 4 faces the electron beam column 22. In this state, the electron beam b21 is emitted from the electron beam column 21 along a direction of the optical axis OA1 (a downward direction of the Z axis), and the electron beam b22 is emitted from the electron beam column 22 along a direction of the optical axis OA2 (an inclined direction relative to the Z axis). The cross point CP2 in FIG. 9 is on the analysis portion 4b in FIG. 11.

In FIG. 11, the electron beam b21 of the electron beam column 21 is emitted perpendicularly to the upper surface of the thin piece 4. Since the electron beam column 22 is installed at an angle different from that of the electron beam column 21, the thin piece 4 is irradiated with the electron beam b22 at an angle different from that of the electron beam b21, and in FIG. 11, the front surface of the thin piece 4 is irradiated with the electron beam b22 from an oblique direction. Charged particles generated from the thin piece 4 based on the irradiation are detected as a detection signal by the detector 27 in FIG. 9, and the detection signal is converted into an image by a calculation processing device provided in the controller 214. Accordingly, an SEM image of a top view and an SEM image of a side view are acquired.

In the SEM image of the top view obtained based on the electron beam column 21, mainly a thickness of the analysis portion 4b and a thickness of the entire thin piece 4 can be inspected. In the SEM image of the side view obtained by the electron beam column 22, mainly whether there is a damaged location, foreign matter adhesion, or the like in the thin piece 4 can be inspected. In addition, in the SEM image of the side view, a rough structure of a device formed in the analysis portion 4b can be observed. Each SEM image obtained here is stored in a storage device of the computer system 200.

As described above, in the lift out device 20, it is possible to perform a simple inspection and a quality determination for the thin piece 4 by using two SEM images obtained based on two electron beam columns. As a result of the inspection, the thin piece 4 is classified into a non-defective product and a defective product. The defective product is, for example, the thin piece 4 that is not suitable for observation in the TEM device 30 and has a damaged location or foreign matter adhesion. The thin piece 4 determined as a non-defective product is taken out, and the thin piece determined as a defective product is left. The inspection and the quality determination may be automatically performed by the lift out device 20 or may be manually performed by a user.

Next, while confirming the SEM image obtained by the electron beam column 21 or the electron beam column 22, the lift out device 20 moves the attaching and detaching device 23 to above the thin piece 4 determined to be a non-defective product using the controller 215. The lift out device 20 lowers the attaching and detaching device 23 and brings a tip end of the attaching and detaching device 23 into contact with the thin piece 4. Here, the lift out device 20 can confirm a height of the attaching and detaching device 23 according to the SEM image of the side view obtained by the electron beam column 22, and can confirm that the attaching and detaching device 23 came into contact with the thin piece 4 according to the SEM image of the top view obtained by the electron beam column 21. Further, the lift out device 20 operates the attaching and detaching device 23 in a manner that the analysis portion 4b is not gripped.

### [Example (2) of Processing Operation of Transferring Thin Piece]

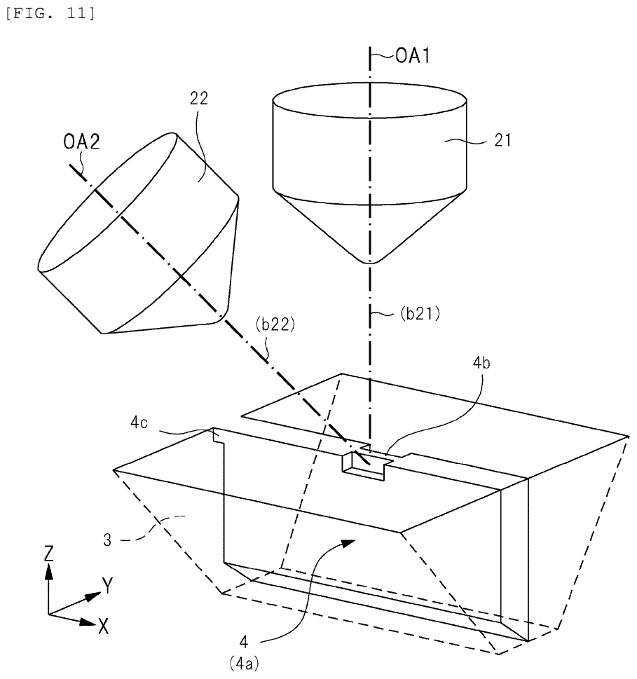

Next, the lift out device 20 takes out the thin piece 4 from a part of the wafer 3. FIG. 12 shows a state in which the lift out device 20 grips and takes out the thin piece 4 from a part of the wafer 3 with a tip end of the attaching and detaching device 23. At this time, the lift out device 20 separates the thin piece 4 from the wafer 3 by cutting out the thin piece 4 at the coupling portion 4c by raising the attaching and detaching device 23 in a state where the thin piece 4 (a portion other than the analysis portion 4b) is held by the attaching and detaching device 23. Alternatively, the lift out device 20 may separate the thin piece 4 from the wafer 3 by cutting out the thin piece 4 at the coupling portion 4c by lowering the movable stage 24. Accordingly, the thin piece 4 is lifted off from the wafer 3. The method described above (a generic term including a method, a system, a mechanism, and the like) is a lift out method. In the first type inspection system 1, the thin piece 4 is taken out from the wafer 3 and transferred to the carrier 5 by the above-described lift out method.

Next, the lift out device 20 acquires an SEM image of the thin piece 4 in a state where the thin piece 4 is held by the attaching and detaching device 23. Thereafter, the lift out device 20 may perform secondary quality determination as a simple inspection on the thin piece 4 based on the acquired SEM image.

### [Example (3) of Processing Operation of Transferring Thin Piece]

According to the characteristics of the SEM device, when a working distance (WD) between the thin piece 4 and the objective lens 22d is short, an image with higher resolution can be obtained. In order to use this characteristic, the lift out device 20 may perform the following operation.

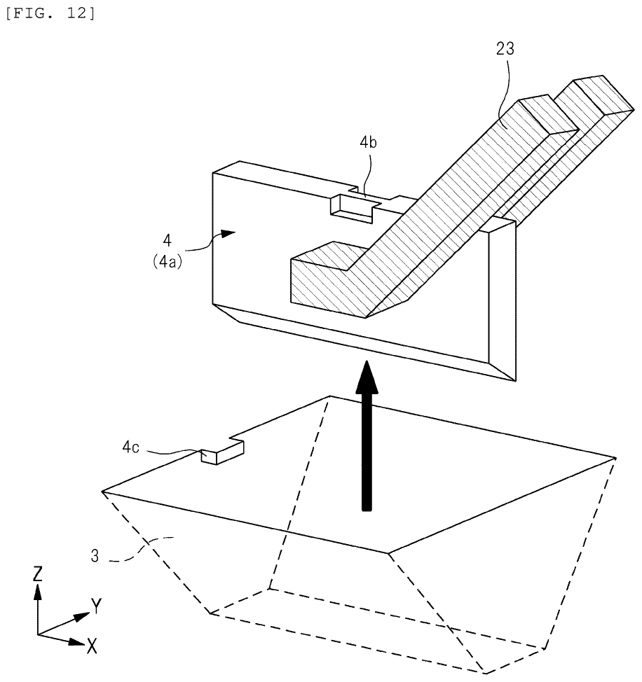

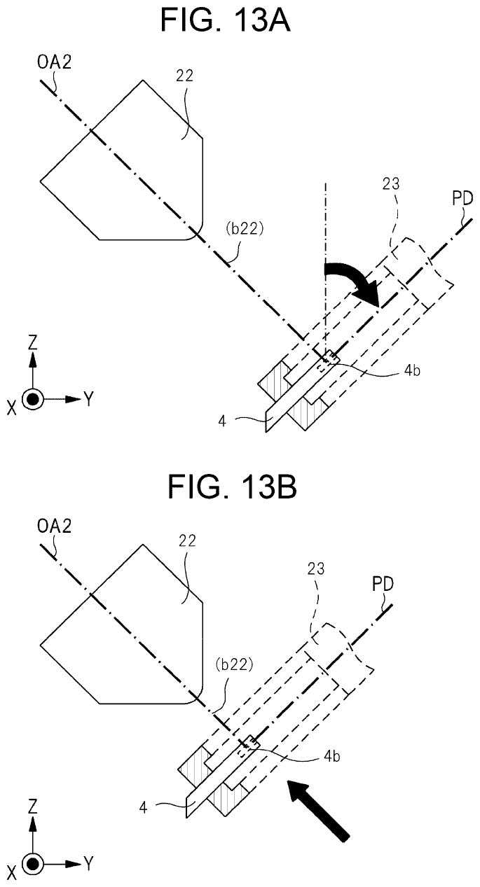

FIG. 13 shows an operation example when a suitable SEM image is imaged by the electron beam column 22 by moving the thin piece 4 using the attaching and detaching device 23 in the lift out device 20. In a state where the thin piece 4 is held by the attaching and detaching device 23 as shown in (A), the lift out device 20 rotates the attaching and detaching device 23 so that the front surface of the analysis portion 4b is perpendicular to an irradiation direction of the electron beam b22 as shown in the drawing. PD is an axis of the attaching and detaching device 23, and the thin piece portion 4a is disposed along the axis. A direction of the optical axis OA2 of the electron beam b22 is perpendicular to the axis.

Subsequently, as shown in (B), the lift out device 20 moves the attaching and detaching device 23 in parallel in the direction of the optical axis OA2 to bring the front surface of the analysis portion 4b closer to the electron beam column 22. In this manner, the WD between the thin piece 4 and the objective lens 22d is adjusted to an appropriate distance. Accordingly, a high-resolution SEM image can be obtained by the electron beam column 22.

Further, the lift out device 20 may perform secondary quality determination on the thin piece 4 using the SEM image in the state as shown in FIG. 13. The secondary quality determination is performed with a higher resolution than primary quality determination. A device structure formed in the analysis portion 4b is observed as a more detailed SEM image than the primary quality determination. The SEM image obtained here is stored in a storage device of the computer system 200. The secondary quality determination may also be automatically performed by the lift out device 20 or may be manually performed by a user.

As a result of the inspection and the secondary quality determination as described above, the thin piece 4 determined as a non-defective product is transferred to the carrier 5, and the thin piece 4 determined as a defective product is stored in a defective product storage place.

### [Structure Example of Carrier]

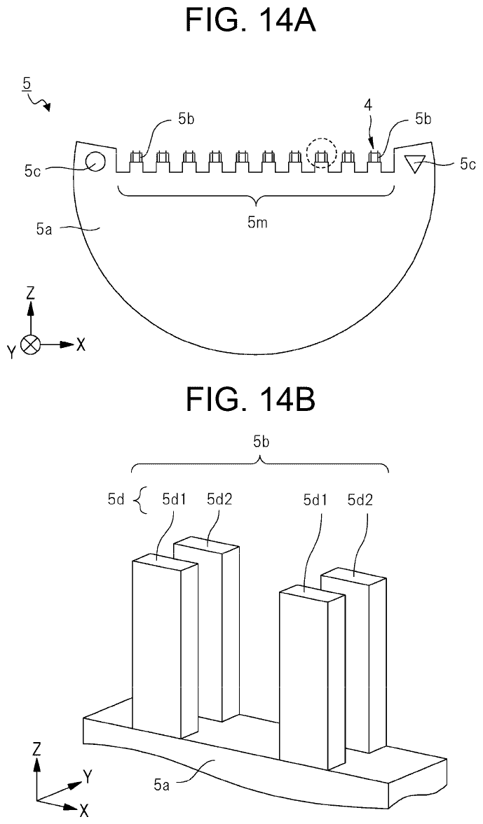

FIG. 14 shows a structure example of the carrier 5 used when the thin piece 4 is transferred to the carrier 5 by the lift out device 20 in the first type inspection system 1. (A) of FIG. 14 is a longitudinal cross section view showing the carrier 5 which is an LC. The carrier 5 which is an LC may be referred to as a lamellar grid, a TEM mesh, or the like. The carrier 5 includes a half-moon type substrate 5a and a plurality of support portions 5b protruding upward from a surface of the substrate 5a in the Z direction. The mesh 5m is implemented by the plurality of support portions 5b. Each support portion 5b is a thin piece support portion having a structure capable of mounting and holding the thin piece 4.

The substrate 5a including the plurality of support portions 5b may be formed of a material such as silicon. Alternatively, a portion of the substrate 5a where the plurality of support portions 5b are provided and the periphery thereof may be formed of a material different from a material for forming the substrate 5a. For example, most of the substrate 5a may be formed of copper, and the plurality of support portions 5b and the periphery thereof may be formed of silicon.

At both end portions (circumferential portions in a plan view of an upper surface of the carrier 5) of the substrate 5a where the support portion 5b is not provided, marks Sc implemented by holes penetrating the substrate 5a are provided. The marks Sc are provided as marks having different shapes, and here, circular and triangular marks Sc are shown. The marks Sc facilitate identification of the front and the rear of the carrier 5. In addition, when determining a position of the support portion 5b to which the thin piece 4 is to be transferred, the desired support portion 5b can be searched with reference to the mark Sc, and a transfer position can be easily specified.

(B) of FIG. 14 shows a structure example of the support portions 5b. (B) shows a state in which the thin piece 4 is not mounted on the support portion 5b. In the present example, one support portion 5b is implemented by four pillars 5d {5d1, 5d2, 5d3, 5d4} as pillars (support columns) 5d protruding upward from the substrate 5a. The pillar 5d1 and the pillar 5d2 are separated from each other in the Y direction, and the pillar 5d3 and the pillar 5d4 are separated from each other in the Y direction. The pillar 5d1 and the pillar 5d2 are separated from the pillar 5d3 and the pillar 5d4 in the X direction. A separation distance between the pillars are designed as distances for supporting the thin piece 4.

In one carrier 5, a plurality of, for example, 4 to 20 such support portions 5b are provided in a mesh shape on the mesh 5m on an X-Y plane. Although a case where a shape of the pillar 5d is a quadrangular prism is shown, the shape may be any shape that can hold the thin piece 4, and may be a polygonal prism, a cylindrical body, or the like. The invention is not limited to the example shown in FIG. 14, and only one end of the thin piece 4 may be held by a pillar pair. In a configuration in which the pillar 5d is raised in the Z direction, a plurality of thin pieces 4 may be inserted and held in the Z direction by one support portion 5b.

### [Example (4) of Processing Operation of Transferring Thin Piece]

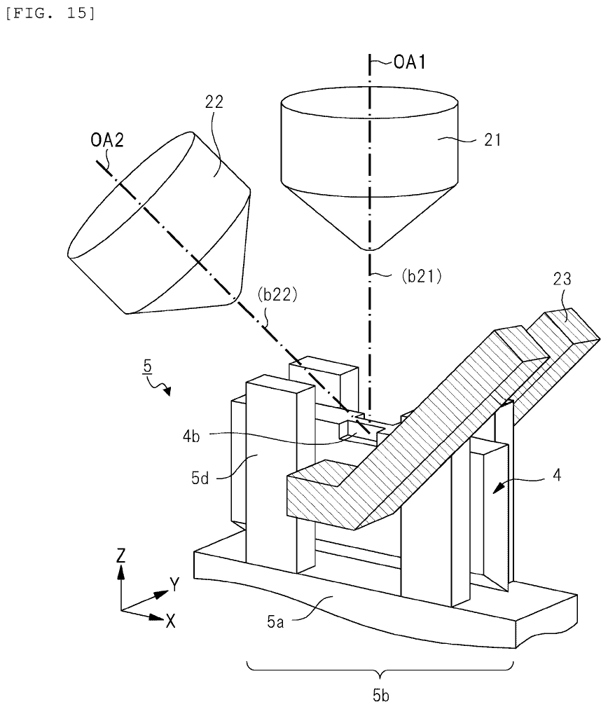

In the lift out device 20, a processing operation of transferring the thin piece 4 determined as a non-defective product to the carrier 5 is performed as follows. At the time of transfer, the thin piece 4 is inserted and held in the support portion 5b as shown in FIG. 14 by the attaching and detaching device 23 as shown in FIG. 15.

The lift out device 20 causes the controller 213 to move the movable stage 24 so that the carrier 5 is disposed at the center of a top view SEM image. At this time, the lift out device 20 controls the rotation stage 26 and the movable stage 24 while confirming a side view SEM image using the obliquely arranged electron beam column 22. In this manner, a desired position of the support portion 5b of the carrier 5 is determined.

The lift out device 20 moves the attaching and detaching device 23 that hold the thin piece 4 to a position above the desired support portion 5b while confirming the top view SEM image using the vertically arranged electron beam column 21.

FIG. 15 shows a state in which the thin piece 4 is transferred by being inserted into the desired support portion 5b of the carrier 5 by the attaching and detaching device 23 in the lift out device 20. The lift out device 20 lowers the attaching and detaching device 23 that holds the thin piece 4 from the position above the desired support portion 5b until a bottom surface of the thin piece 4 comes into contact with or approaches the substrate 5a. At this time, the lift out device 20 adjusts a height of the attaching and detaching device 23 and finely controls a posture of the thin piece 4 while confirming the side view SEM image using the obliquely arranged electron beam column 22. In this manner, as shown in FIG. 15, the target thin piece 4 is inserted into the target support portion 5b. Specifically, one end side of the thin piece 4 in the X direction is inserted and held between the pillar 5d1 and the pillar 5d2, and the other end side is inserted and held between the pillar 5d3 and the pillar 5d4.

The observation on the thin piece 4 in the TEM device 30 is performed for each thin piece 4 in a state where the plurality of thin pieces 4 are mounted on the carrier 5. Therefore, the analysis portion 4b of the thin piece 4 is exposed without overlapping the pillar 5d of the support portion 5b in a plan view viewed from the Y direction so that the analysis portion 4b is not blocked by the support portion 5b.

After the insertion of the thin piece 4 as described above is completed, the lift out device 20 releases gripping of the attaching and detaching device 23 and retracts the attaching and detaching device 23. The lift out device 20 repeats the same processing operation for the other thin pieces 4 taken out from the wafer 3 and transferred to the carrier 5. The number of the thin pieces 4 that can be mounted on one carrier 5 is determined in advance as an allowable range and a maximum number. When the number of the thin pieces 4 mounted on one carrier 5 reaches the allowable range and there is another subsequent thin piece 4, the lift out device 20 transfers the subsequent thin piece 4 to the support portion 5b of another carrier 5. The carrier 5 on which the plurality of thin pieces 4 are transferred and mounted through the above processing operation and the wafer 3 at a transfer source are taken out from the sample chamber 207.

Thereafter, the taken-out carrier 5 is conveyed from the lift out device 20 to the TEM device 30 by the second conveyance step. Further, the taken-out wafer 3 may be returned to the manufacturing line if necessary, or may be discarded if unnecessary. In the TEM device 30 in the third step, the carrier 5 is set, and TEM image observation is performed on the analysis portion 4b of each thin piece 4 on the carrier 5.

### [Thinning Machining and Transfer According to Micro-Sampling Method of Second Type]

FIG. 16 is a diagram showing a detailed example of a processing operation of thinning machining and transfer according to the micro-sampling method by the first type FIB-SEM device 10A in the first step in the inspection processing sequence (FIG. 7) of the second type inspection system 1. First, as shown in (A), the first type FIB-SEM device 10A forms the thin piece portion 4a in a state immediately before the final finishing (in other words, a finishing remaining state) by performing FIB machining on an inspection target location of the wafer 3. A front surface 4s shown in the drawing indicates an observation target cross section.

Next, the first type FIB-SEM device 10A brings the needle 13 close to the thin piece portion 4a in the finishing remaining state. The needle 13 corresponds to a tip end of the probe unit 112 in FIG. 8. Next, the first type FIB-SEM device 10A performs deposition machining to bond the needle 13 to a part of the thin piece portion 4a in the finishing remaining state. Next, the first type FIB-SEM device 10A cuts out the thin piece portion 4a from the wafer 3 by irradiating, with an FIB, the coupling portion 4c on an edge on an opposite side to such a bonding position to perform etching machining.

Next, as shown in (B), the first type FIB-SEM device 10A moves the cut-out thin piece portion 4a held by the needle 13 to a position of the pillar 5p of the support portion to which the thin piece portion 4a is to be mounted, which is a predetermined position on the mesh 5m on the carrier 5 (LC) placed at a position different from the wafer 3. This movement can be implemented by moving a stage. Next, the first type FIB-SEM device 10A moves the needle 13 to bring the thin piece portion 4a close to the position of the pillar 5p on the mesh 5m.

Next, as shown in (C), the first type FIB-SEM device 10A performs deposition machining on a location where the pillar 5p and the thin piece portion 4a are coupled to each other, thereby bonding the pillar 5p and the thin piece portion 4a to each other. Next, the first type FIB-SEM device 10A cuts the needle 13 and the thin piece portion 4a by irradiating a bonding position between the thin piece portion 4a and the needle 13 with an FIB and performing etching machining, and separates the needle 13 from the thin piece portion 4a.

Through the above-described processing operation, the thin piece 4 is transferred and mounted in a manner of being supported by the pillar 5p on the mesh 5m of the carrier 5. The first type FIB-SEM device 10A performs the above-described processing operation for the designated number of times and for the designated number of thin pieces 4a, and then unloads the LCC 7 that stores the LC which is the carrier 5. Although one thin piece 4 is fixed to one pillar 5p in the example shown in FIG. 16, the pillar 5p may be configured to be high, and a plurality of thin pieces 4 may be fixed to one pillar 5p.

In the automatic micro-sampling method as described above, the thin piece 4 is fixed to the pillar 5p by deposition machining or the like. The first type FIB-SEM device 10A can perform control while monitoring the above-described processing operation according to an SEM image.

In FIG. 6, FIG. 7, FIG. 14, and FIG. 16, the mesh 5m of one LC has a predetermined number (for example, 4 to 20) of support portions 5b as positions and locations where the thin piece 4 can be transferred. The inspection management system 2 may handle a plurality of types of LCs. The LCs may have different maximum number of transfer. The inspection management system 2 and each device of the inspection system 1 may manage the maximum number of transfer, the number of transfer, the number of vacancies, and the like as information for each LC.

### [Another Transfer Method]

FIG. 17 is a diagram showing a method for mounting the thin piece 4 in the mesh 5m of the carrier 5 as an example of another method related to the transfer of the thin piece 4 to the carrier 5. In FIG. 17, a part of the mesh 5m of the LC which is the carrier 5 in the X-Y plane in a plan view from above is enlarged and shown on a right side. For example, a plurality of quadrangular frames which are recessed portions 5f are provided as portions constituting the mesh 5m, in other words, a lattice. During the transfer, the thin piece 4 is placed in such a recessed portion 5f of the mesh 5m. In the example of FIG. 17, one thin piece 4 is placed in one recessed portion 5f with the front surface 4s facing upward.

### [Cartridge of TEM Device]

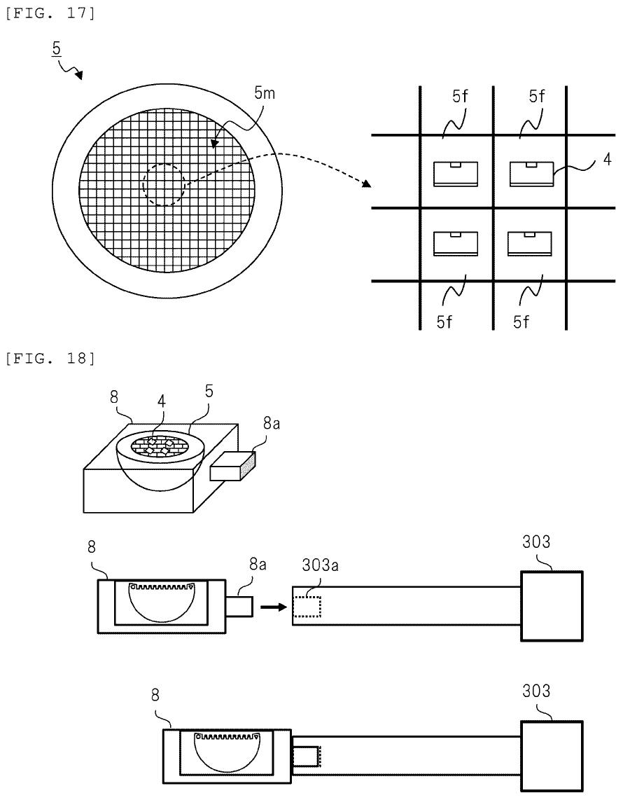

FIG. 18 is a diagram showing a configuration example in which the cartridge 8 in which the carrier 5 is mounted is set in the sample holder 303 of the electron beam column 31 in the TEM device 30 (FIG. 10). The carrier 5 on which the thin piece 4 is mounted is set in the cartridge 8 as shown in the drawing. The cartridge 8 is provided with, for example, a protruding portion 8a. For example, a recessed portion 303a is provided at a tip end of the sample holder 303. The cartridge 8 is fixed by inserting the protruding portion 8a of the cartridge 8 into the recessed portion 303a at the tip end of the sample holder 303. Accordingly, the TEM device 30 holds the carrier 5 of the cartridge 8 by the sample holder 303. In this state, the TEM image observation is performed on the thin piece 4 on the carrier 5.

### [Functional Block of Inspection Management System]

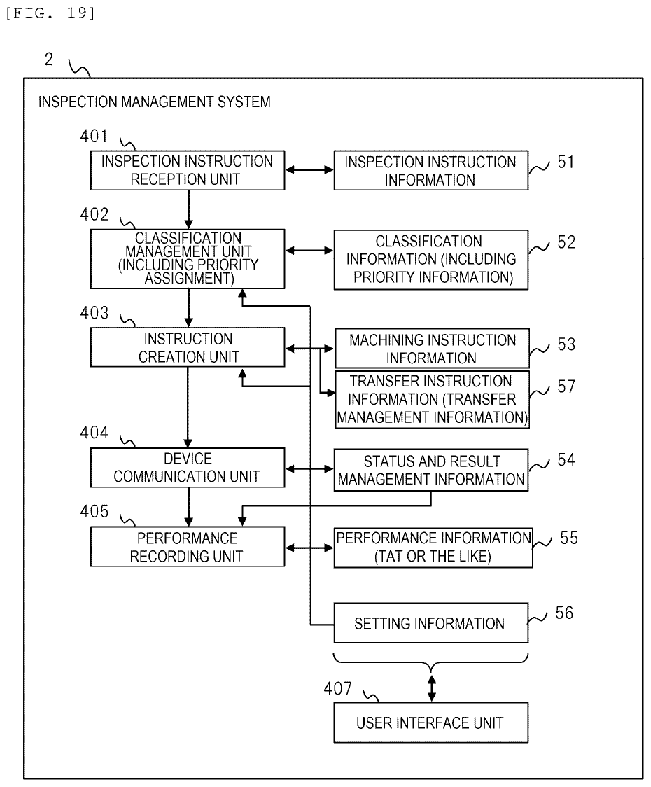

FIG. 19 shows a functional block configuration example of the management system 2 according to Embodiment 1. The management system 2 includes, as functional blocks, an inspection instruction reception unit 401, a classification management unit 402, an instruction creation unit 403, a device communication unit 404, a performance recording unit 405, a user interface unit 407, and the like. Each unit is implemented by, for example, program processing executed by the processor 1001 based on the configuration as shown in FIG. 3.

FIG. 19 also shows an example of data and information handled by each processing unit, which corresponds to those shown in FIG. 3. The data and information is stored in a memory resource of the management system 2. The inspection instruction reception unit 401 reads and writes the inspection instruction information 51 and the like. The classification management unit 402 reads and writes the classification information 52. The classification assigning unit 402 includes a function of assigning a priority, and the classification information 52 includes priority information. The instruction creation unit 403 reads and writes the machining instruction information 53 and the transfer instruction information 57. The device communication unit 404 reads and writes the status and result management information 54. The performance recording unit 405 reads and writes the performance information 55. The performance information 55 is information including performance of a processing operation of each device in each step, for example, a TAT.

The inspection instruction reception unit 401 receives an inspection instruction and inspection target location information from the manufacturing management system 150 (FIG. 1) in a plant, and stores and manages the inspection instruction and the inspection target location information as the inspection instruction information 51. The classification management unit 402 assigns a classification or the like to a target wafer or site based on the inspection instruction information 51, and stores and manages the classification as the classification information 52. Based on an operation of the user U1, the instruction creation unit 403 creates a machining instruction for the target wafer or site based on the inspection instruction information 51, and stores and manages the machining instruction as the machining instruction information 53. The instruction creation unit 403 creates, stores, and manages the transfer instruction information (in other words, transfer management information) 57 for instructing and controlling a processing operation such as transfer in each device of the inspection system 1 based on the classification information 52 and the machining instruction information 53.

The device communication unit 404 communicates with each device of the inspection system 1 in FIG. 1. Based on communication, the device communication unit 404 causes the inspection system 1 to execute inspection processing according to the machining instruction information 53, the transfer instruction information 57, and the like. The device communication unit 404 stores and manages a status and a result of each device related to the inspection processing sequence as the status and result management information 54. The device communication unit 404 may store all pieces of information including transmission information of an instruction to each device of the inspection system 1 and reception information of a response as a log. Based on the status and result management information 54, the performance recording unit 405 calculates and records performance such as a TAT for a processing operation of each device of the inspection system 1 as the performance information 55.

The user interface unit 407 provides a screen with a GUI to the user U1 such as an inspection administrator or a worker. The user interface unit 407 displays various kinds of information from the inspection instruction information 51 to the setting information 56 handled by each unit on the screen. The screen is a display screen of the output device 1006 in FIG. 3. The screen may be provided, for example, in a form of a Web page.

The inspection management system 2 stores and manages a configuration of the inspection system 1 including a plurality of devices as shown in FIG. 2 in the setting information 56. The configuration of the inspection system 1 includes configurations of a type and a method of the inspection system 1 and the inspection processing sequence, a type, the number, and a model of a device, a user such as an associated worker, and the like. The inspection management system 2 manages settings related to various functions including user settings as the setting information 56.

### [Processing Flow of Inspection Management System]

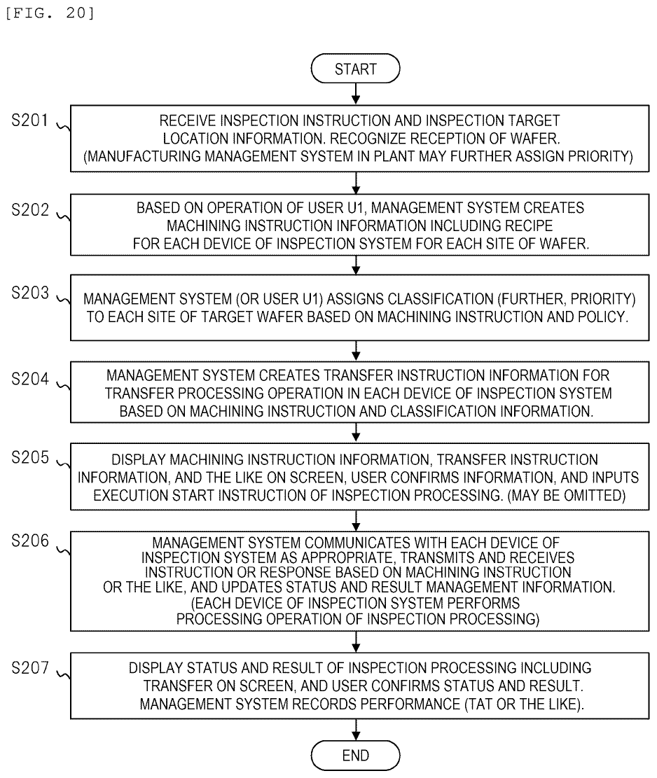

FIG. 20 shows a main processing flow of the inspection management system 2 in FIG. 19, and includes steps S201 to S207. This flow shows an example of detailed processing including cooperation from the manufacturing management system 150 (FIG. 1) in a plant to the inspection management system 2.

In step S201, an inspection instruction, inspection target location information, and the like are issued from the manufacturing management system 150 in a plant. The wafer 3 serving as an inspection target sample is conveyed from a manufacturing line to the inspection system 1. The inspection instruction reception unit 401 of the management system 2 receives the inspection instruction, the inspection target location information, and other related information such as manufacturing process information from the manufacturing management system 150, recognizes that the inspection system 1 receives the wafer 3 conveyed from the manufacturing line, and stores the information as the inspection instruction information 51. The inspection instruction reception unit 401 grasps the target wafer 3, an inspection target location (site), the number of necessary thin pieces 4, and the like from an inspection instruction or the like.

In addition, the inspection instruction reception unit 401 may display contents of the inspection instruction or the like on a screen for the user U1 using the user interface unit 407. Further, in step S201, the manufacturing management system 150 in the plant may assign and set a priority to the wafer 3 or the like as in an example to be described later. In this case, an inspection instruction or the like added with priority information is transmitted to the inspection management system 2.

In step S202, based on an operation of the user U1 on the GUI screen, the instruction creation unit 403 of the management system 2 creates a machining instruction for a site of the target wafer based on the inspection instruction information 51. The machining instruction is information including, for each site of the wafer 3, setting of a recipe for a processing operation of each device of the inspection system 1. The instruction creation unit 403 stores the machining instruction information 53. Although the machining instruction is created before the assignment of the classification, and the classification is assigned based on contents of the machining instruction in the present example, the invention is not limited thereto.

In step S202, for example, the user U1 selects a recipe for a processing operation of each device in each step on the screen. The selection of the recipe is, for example, a selection from standard recipes defined in advance. The recipe is information for controlling a processing operation of a device. For example, as a recipe of the FIB-SEM device 10, there is information such as a condition for controlling irradiation of a charged particle beam as a recipe corresponding to a function. The instruction creation unit 403 may adjust a parameter value of a recipe.

In the present example, a device of the inspection system 1 used for the inspection processing sequence is a device selected from a plurality of devices of the inspection system 1 as shown in FIG. 2. In each step, when there are a plurality of available candidate devices, the management system 2 or the user U1 may select a device to be used.

In step S203, the classification management unit 402 of the management system 2 assigns a classification to each site of the target wafer 3 based on the machining instruction information 53 and a predetermined policy. At this time, the user U1 may assign a classification based on an operation of the user U1 on the screen. The predetermined policy is a policy for assigning a classification, and may be defined by implementation in advance or may be selectable by the user U1 on a screen as will be described later.

Further, in step S203, the management system 2 or the user U1 may assign a priority, which will be described later, to each site of the target wafer 3 in addition to the classification. The classification management unit 402 stores the classification information 52. In Embodiment 1, at least the classification is assigned to sites of at least a part of the wafer 3, and priority assignment is an additional element. The classification information is used for main control, and the added priority information is used for secondary control.

In step S204, the instruction creation unit 403 of the management system 2 may create transfer instruction information related to a transfer processing operation in each device of the inspection system 1 based on the machining instruction information 53 and the classification information 52. The instruction creation unit 403 stores the transfer instruction information 57.

In step S205, the management system 2 uses the user interface unit 207 to display contents of the machining instruction information 53 and the transfer instruction information 57 on a screen for the user U1. The user U1 confirms the contents of the machining instruction information 53 and the like on the screen and inputs an execution start instruction of the inspection processing sequence. Step S205 may be omitted, and the management system 2 may automatically execute inspection processing.

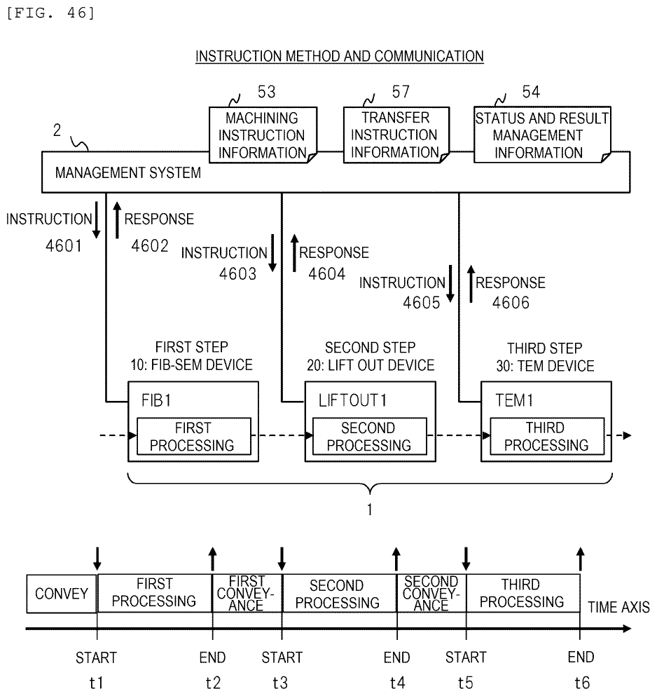

In step S206, the device communication unit 404 of the management system 2 appropriately communicates with each device of the inspection system 1 based on the inspection processing execution start instruction input by the user U1, the machining instruction information 53, the transfer instruction information 57, and the like, and transmits an instruction related to the execution of the inspection processing. Accordingly, the inspection system 1 is caused to execute the inspection processing sequence. The device communication unit 404 sequentially transmits an instruction or the like to each device in each step (see FIG. 46 to be described later). Each device executes a processing operation of own device according to information read from a container set in own device and information such as an instruction from the management system 2. Each device transmits information indicating a status and a result of the processing operation in own device to the management system 2 as a response as appropriate. The device communication unit 404 of the management system 2 receives information such as a response from each device, grasps the status and the result of the processing operation in each device, and updates the status and result management information 54.

The invention is not limited to a form in which the processing operation of the inspection system 1 is controlled by transmitting an instruction from the management system 2 to a device of the inspection system 1 as in step S206. The processing operation of each device may be performed by appropriately transmitting a request or the like to the management system 2 from each device of the inspection system 1 and acquiring and referring to necessary information. For example, each device may transmit a request to the management system 2 in response to reading of an ID of a container set in own device, pressing of a processing start button by a worker, or the like, and the management system 2 that received the request may transmit information for a processing operation in own device. Alternatively, necessary information is transmitted from the management system 2 to each device in advance, and each device holds the information in own device. Then, each device may perform a processing operation with reference to the information at the start of the processing operation in own device. Communication of information between each device and the management system 2 may be performed by, in particular, the controller 10C or the like in FIG. 1.

In step S207, based on the status and result management information 54, the management system 2 uses the user interface unit 407 to display a status and a result of the inspection processing including transfer on the GUI screen for the user U1. The user U1 can confirm the status and the result of the inspection processing including transfer on the screen. The performance recording unit 405 of the management system 2 calculates performance such as a TAT of each device of the inspection system 1 based on the status and result management information 54, and records the performance in the performance information 55. The management system 2 may use the user interface unit 407 to display the performance information on a screen for the user U1.

As a modification of the above flow, in step S201, the manufacturing management system 150 in the plant may assign classification information to the target wafer 3 or site. In this case, in step S203, the user U1 of the management system 2 confirms the classification information.

When the transfer instruction information 57 is created in step S204, the transfer instruction information 57 is information for instructing how to perform a processing operation such as transfer of the wafer 3 or the thin piece 4 between devices in each step. The transfer instruction information 57 is instruction information indicating which wafer 3 is loaded from which FOUP in which order, which carrier 5 is loaded, which thin piece of which site of the wafer 3 is transferred to which carrier 5 in order, and the like. Further, when there are a plurality of candidate devices in each step, the transfer instruction information 57 may be instruction information indicating which container is conveyed to which device.

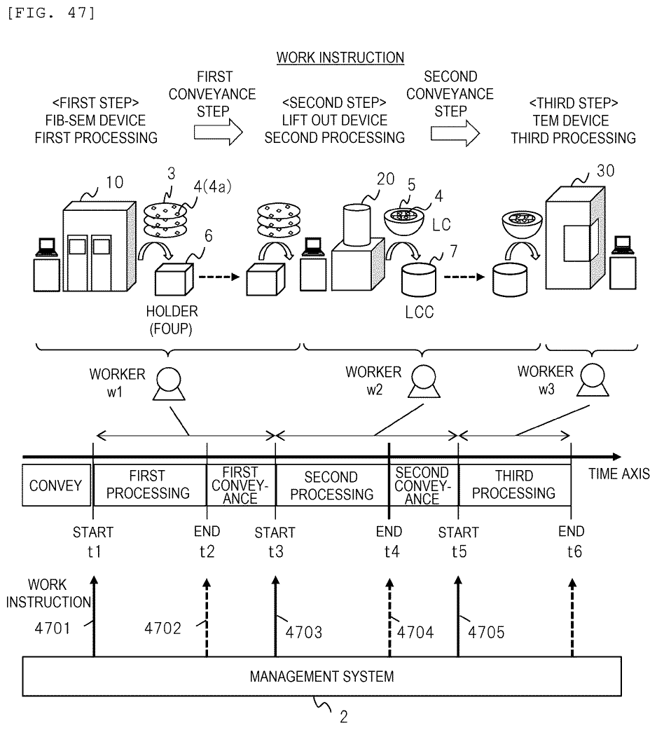

When the management system 2 transmits the instruction information to a device of the inspection system 1 in step S206, the management system 2 may transmit a work instruction not only to a device in each step but also to a worker associated with work of each step, which will be described later (FIG. 47). For example, the management system 2 may transmit the work instruction to a mobile terminal carried by the worker.

Hereinafter, a specific example of each processing and each function will be described along a flow or order of processing in the management system 2 and the entire inspection system 1.

### [Inspection Instruction Information]

In step S201, the inspection instruction reception unit 401 grasps an inspection target, contents to be performed as the inspection processing, and the like based on the inspection instruction. The inspection instruction transmitted from the manufacturing management system 150 in the plant to the management system 2 includes, for example, the following information. The inspection instruction information includes information such as a lot ID, a FOUP ID, a cassette slot position (or a wafer ID), an inspection position, and an inspection type. The lot ID is identification information of a lot of the wafers 3 which are inspection target samples. The FOUP ID is identification information of a FOUP which is a container that stores the wafer 3. The cassette slot position is information indicating a position of a slot in the FOUP in which the wafer 3 is stored. The wafer ID is identification information of the wafer 3 which is the inspection target sample. The inspection position is an inspection target position on the wafer 3, and is, for example, two-dimensional coordinates. The inspection position is represented by, for example, an ID of a die in the wafer 3 and position coordinates in the die. The inspection position corresponds to an inspection target location (a site) and a position where the thin piece 4 is produced. The inspection type includes information that defines, for example, an observation type of a cross section observation or a planar observation, a size of the thin piece 4, a production direction of the thin piece 4, and the like.

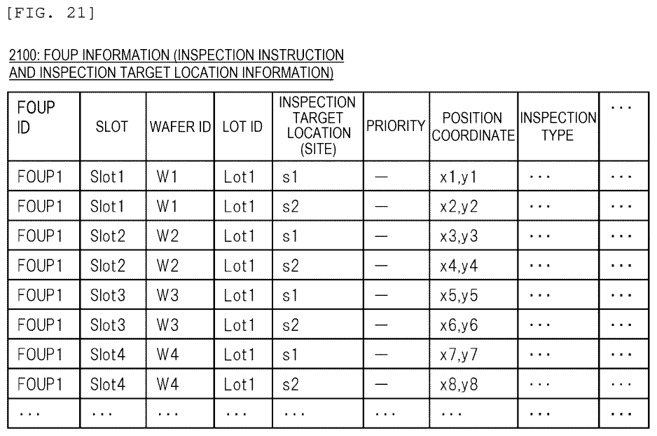

FIG. 21 shows an example of FOUP information 2100 as an example of an inspection instruction and inspection target location information given from the manufacturing management system 150. The FOUP information is information on a FOUP conveyed from the manufacturing line to the inspection system 1. A table of the FOUP information 2100 in FIG. 21 includes information such as a FOUP ID, a slot, a wafer ID, a lot ID, a site, a priority, position coordinates, and an inspection type.

### [ID Management]

An ID and a position of each object such as the wafer 3, the thin piece 4, the carrier 5, and the holder 6 handled in the present system are managed individually. The management system 2 grasps the ID and the position of each individual. An ID may be assigned as information to the wafer 3 or the thin piece 4, or an ID may be created by machining. The ID may be read by image processing, a code reader, or the like. The management system 2 and the inspection system 1 grasp and manage information including an ID such as at which position of which holder 6, which carrier 5, or the like each wafer 3 or thin piece 4 is mounted, in which device of which step the wafer 3 or thin piece 4 is currently present, and the like. The management system 2 and the inspection system 1 also grasp and manage information such as what kind of processing is performed by which device for each wafer 3 or thin piece 4. Information such as the ID is reflected in the machining instruction information 53 and the transfer instruction information 57. For example, information such as which site of which wafer 3 in which FOUP the thin piece 4 is formed and in which holder 6 the thin piece 4 is stored is determined in the FIB-SEM device 10 of the first step and information such as transfer of the thin piece 4 at which site of which wafer 3 in which FOUP to which carrier 5 is determined in the lift out device 20 of the second step.

Each device in each step may perform a processing operation of reading an ID for a target object conveyed to own device. For example, the FIB-SEM device 10 in the first step may read an ID of the set FOUP or the wafer 3 using the ID reader 171 described above, and receive information from the management system 2 or transmit information to the management system 2 based on the ID. The lift out device 20 in the second step may read an ID of the set FOUP, the wafer 3, or an LC using the ID reader 271 described above, and receive information from the management system 2 or transmit information to the management system 2 based on the ID. Each device may determine a processing operation for the target object according to the information obtained based on the read ID.

### Specific Example

Hereinafter, specific examples related to management, instruction, and control of the inspection processing, which can be implemented based on a configuration of the inspection management system or the like according to Embodiment 1, will be separately described as Example 1 to Example 6.

### Example 1

In Example 1, the user U1 such as an inspection administrator of the inspection management system 2 assigns and sets a classification (particularly, a classification name) to a target site of a target wafer in an inspection instruction. In Example 1, a priority is not used. In Example 1, a case (FIG. 6) of the first type inspection system 1 including the lift out device 20 will be described.

(1-1) The inspection management system 2 receives the inspection instruction, the inspection target location information, and the like from the manufacturing management system 150. The user U1 creates a machining instruction for the target wafer 3 and a site based on the inspection instruction on the GUI screen of the management system 2 (corresponding to step S202). The management system 2 creates the corresponding machining instruction information 53. The management system 2 also creates the transfer instruction information 57, which is instruction information on a transfer processing operation in the inspection system 1, in correspondence with the machining instruction information 53. The machining instruction is information viewed from the user U1 and includes recipe information for controlling a processing operation such as machining in each device of the inspection system 1. The transfer instruction information 57 is control information inside the management system 2, which relates to a processing operation including transfer in each device of the inspection system 1.

The wafer 3 or site to be classified by the management system 2 or the user U1 may be all the wafers 3 or sites in the inspection instruction, or may be only a specific part of the wafers 3 or sites selected by the management system 2 or the user U1.

(1-2) The machining instruction includes a thin piece ID, a wafer ID, a site ID, wafer machining position coordinates, a recipe of a processing operation in each device in each step, classification information (for example, a classification name), and the like.

FIG. 22 shows an example of a GUI screen when the management system 2 creates a machining instruction (“machining instruction creation screen”) to be provided to the user U1. The screen includes an inspection instruction field 2201, a target wafer field 2202, and a machining instruction field 2203. On this screen, contents (for example, FIG. 21) of the inspection instruction information 51 can be confirmed in the inspection instruction field 2201, and a target wafer can be confirmed in the target wafer field 2202. Further, in the target wafer field 2202, the user U1 can select a specific part of wafers as a target wafer from all wafers in the inspection instruction.

In the machining instruction field 2203, the user U1 can confirm and set the machining instruction information on the target wafer. In the machining instruction field 2203, a table of the machining instruction is displayed for each selected target wafer (a wafer W1 in the present example). In the machining instruction field 2203, the user U1 first confirms contents of a default machining instruction created by the management system 2, corrects and edits contents as necessary, and sets desired contents. At the beginning, a classification name is not set in the machining instruction in the machining instruction field 2203.

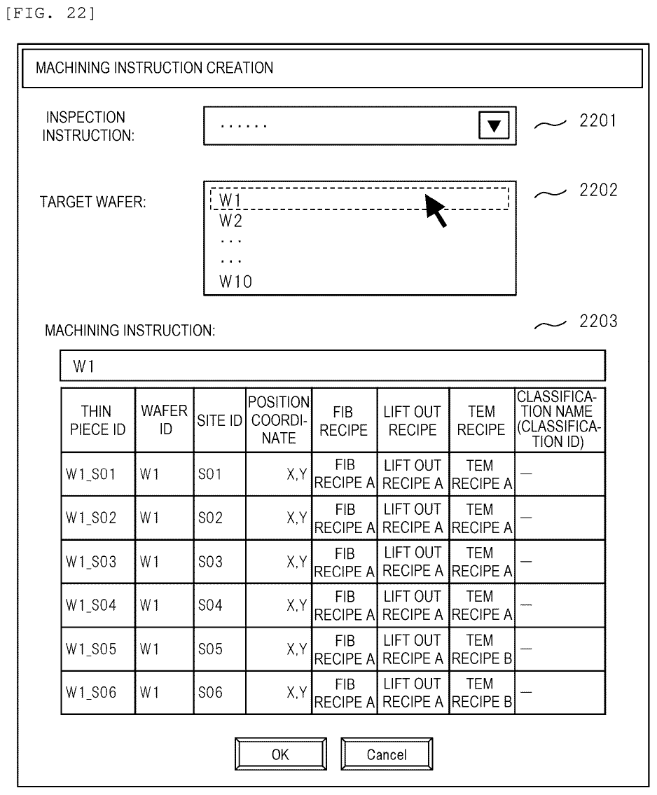

FIG. 23 shows an example of a table of the machining instruction information 53 that can be set in the machining instruction field 2203. A machining instruction information table 2300 in FIG. 23 is, for example, machining instruction information on the wafer W1, and includes column items such as a thin piece ID, a wafer ID, a site ID, a die X, a die Y, a machining coordinate X, a machining coordinate Y, an FIB recipe, a lift out recipe, a TEM recipe, and a classification name. The thin piece ID is an ID (for example, a character string) for identifying the thin piece 4 formed at a site of the wafer 3 and taken out, and includes a set of a wafer ID and a site ID in the present example. The die X, the die Y, the machining coordinate X, and the machining coordinate Y are configuration examples of position coordinates of a site. The die X and the die Y indicate X and Y positions of a die on the wafer 3. The machining coordinate X and the machining coordinate Y indicate X and Y position coordinates of a machining target in a die.

A recipe of a processing operation of the FIB-SEM device 10 is set in the “FIB recipe” item. A recipe of a processing operation of the lift out device 20 is set in the “lift out recipe” item. A recipe of a processing operation of the TEM device 30 is set in the “TEM recipe” item. A recipe of each device is a generic term for control information and setting information on a processing operation of the device. For example, the TEM recipe is information including observation conditions related to observation processing in the TEM device 30. The user U1 can select and set a recipe of each device from a recipe list (not shown) displayed on the screen. These recipes can be selected and set from, for example, predetermined recipes, and parameters of the recipes can be adjusted. For example, the management system 2 acquires a predetermined recipe from each device of the inspection system 1 in advance as an export. The example of FIG. 23 is an example of setting recipes for the FIB-SEM device 10, the lift out device 20, and the TEM device 30 in the case of the first type inspection system 1. Similarly, in the case of the second type inspection system 1, the recipes for the first type FIB-SEM device 10A, the second type FIB-SEM device 10B, and the TEM device 30 can be set.

The “classification name” item is an item in which the user U1 can set a classification name. The classification ID in parentheses is identification information of a classification for management inside the management system 2. The “classification name” item is not set at the beginning.

Images of a plurality of site examples set in the table are schematically shown on a lower side of the table in FIG. 23. In an X-Y plane of the wafer W1, a plurality of sites S01 to S06 are designated corresponding to configurations of a plurality of dies. In the present example, in the case as rough on-wafer positions, the sites S01 to S04 are positioned in a region close to edges (outer periphery) of the wafer W1, while the sites S05 and S06 are positioned in a region close to the center of the wafer W1.

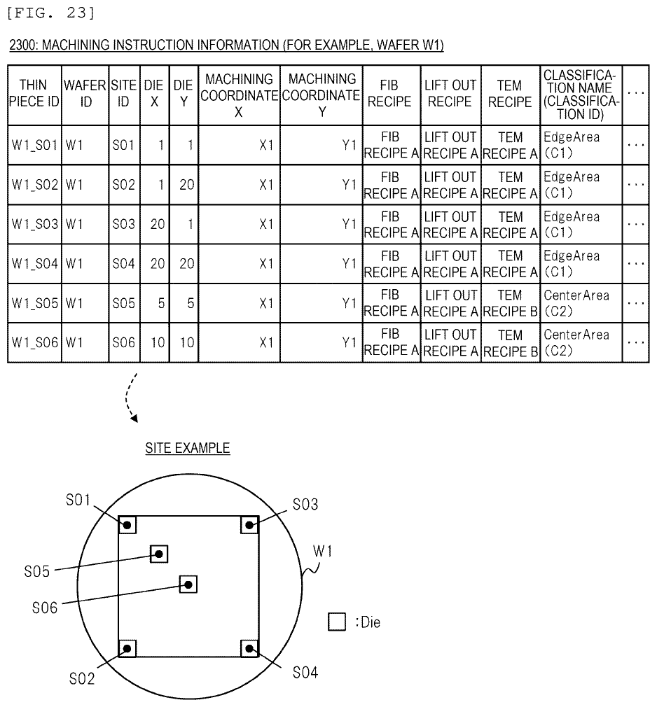

(1-3) The user U1 assigns a classification to each site based on the machining instruction (corresponding to step S203). FIG. 24 shows an example of a GUI screen when a classification name is set. In FIG. 24, the user U1 can freely input and set the classification name by operating the “classification name” item of the table by commonly using the machining instruction field 2203 in FIG. 23. The user U1 may directly input a character string of the classification name to the “classification name” item. In the present example, in the “classification name” item, when the user U1 operates a cursor or the like, options of existing classification names are displayed in a list box, and the user U1 can select and set one. The user U1 can also newly create an option for the classification name.

FIG. 24 and the like show an example of assigning a classification to a site. In the present example, when an appropriate TEM observation condition is different for each site of the wafer, in other words, for each on-wafer position, the user U1 assigns a classification name corresponding to a difference in the TEM recipe including the TEM observation condition. In this case, in the present example, for example, a classification name “Edge Area” (a classification C1) is set in the case of a “TEM recipe A”, and a classification name “Center Area” (a classification C2) is set in the case of a “TEM recipe B” in the “classification name” item. As shown in FIG. 23, the sites S01 to S04 are roughly positioned in a region near the edges of the wafer W1, and the TEM recipe A suitable for the region is set, and the sites S05 and S06 are positioned near the center of the wafer W1, and the TEM recipe B suitable for the region is set. Therefore, the user U1 sets the “Edge Area” (the classification C1) representing the region near the edges as a classification name for the sites S01 to S04 for which the TEM recipe A is set, and sets the “Center Area” (the classification C2) representing the region near the center as a classification name for the sites S05 and S06 for which the TEM recipe B is set.

The invention is not limited to the present example, the user U1 can freely assign and set a classification name that is easy for the user U1 to understand. Examples of other classification names include an “observation condition A”, an “observation condition B”, and the like, or a “TEM recipe A”, a “TEM recipe B”, and the like having the same “TEM recipe” item value.

For example, the user U1 assigns the same classification name to the thin pieces 4 to be transferred to the same carrier 5 (LC). The thin pieces 4 to which the same classification name is assigned on the above-described screen are controlled such that the thin pieces 4 having the same classification name are transferred to the same carrier 5 (LC) at the time of subsequent inspection processing.

Similarly, the machining instruction and the classification can be set for other sites of the wafer 3. For example, the machining instruction information 53 including the same classification name as in FIG. 23 is created for each wafer 3 when the positions of the six sites S01 to S06 on each wafer 3 are the same for 10 wafers 3 of wafers W1 to W10.

### [Inspection Processing Sequence Execution Start]

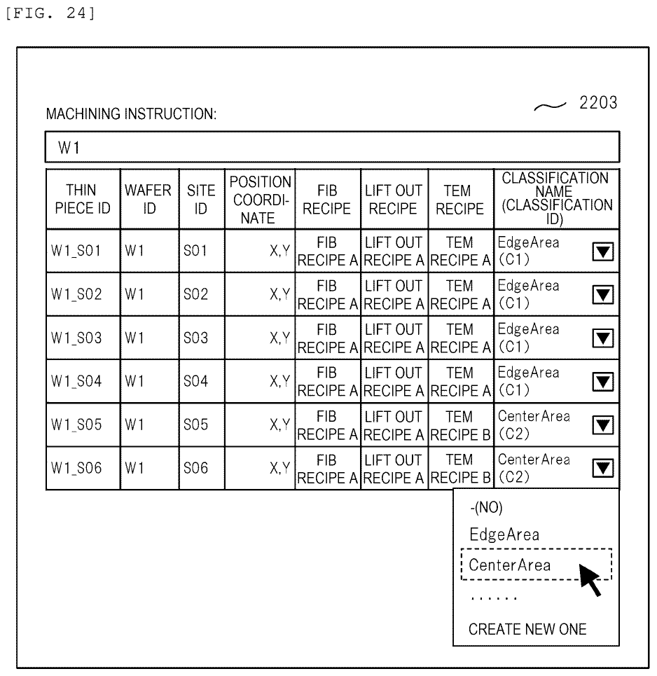

(1-4) After setting the above-described machining instruction and the like, the user U1 starts the inspection processing of the inspection system 1 at a scheduled date and time. FIG. 25 shows an example of a screen for starting the execution of the inspection processing sequence. In the screen example of FIG. 25, a scheduled date and time of the inspection processing sequence, a device and a scheduled processing time used in each step, a machining instruction, and the like are displayed, and an execution start button 2501 and the like are provided. The user U1 confirms contents of the inspection processing sequence on the screen, and operates the execution start button 2501 to start the inspection processing. In response to the operation of the execution start button 2501, the management system 2 transmits an instruction to the inspection system 1 to start the inspection processing.

(1-5) Next, the user U1 or the management system 2 associates a FOUP with a wafer related to a processing operation in the FIB-SEM device 10 in the first step in the first type inspection system 1 as shown in FIG. 6. That is, the user U1 or the management system 2 designates which site of which wafer in which FOUP is to be processed by the FIB-SEM device 10. Here, the FOUP is a FOUP set in the FIB-SEM device 10 based on a FOUP conveyed from the manufacturing line to the FIB-SEM device 10 in the first step, and is also a FOUP used in the first conveyance step. Note that a conveyed FOUP and a FOUP to be set may be the same or may be different due to transfer.

The user U1 reads information (for example, a file) indicating which wafer is stored in which slot of the FOUP on the GUI screen of the management system 2. The information may be any information as long as a correspondence relation between a FOUP and a wafer, a site, or the like can be known, and details thereof are not limited. For example, the management system 2 may acquire such information from the FIB-SEM device 10 of the inspection system 1. The management system 2 may create such information based on information such as an inspection instruction from the manufacturing management system 150. Alternatively, the user U1 may input such information on a screen before the execution start in FIG. 25.

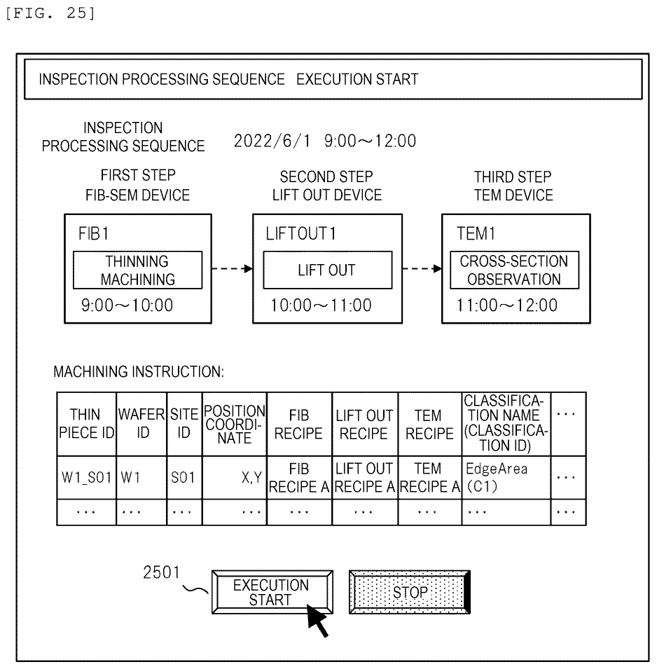

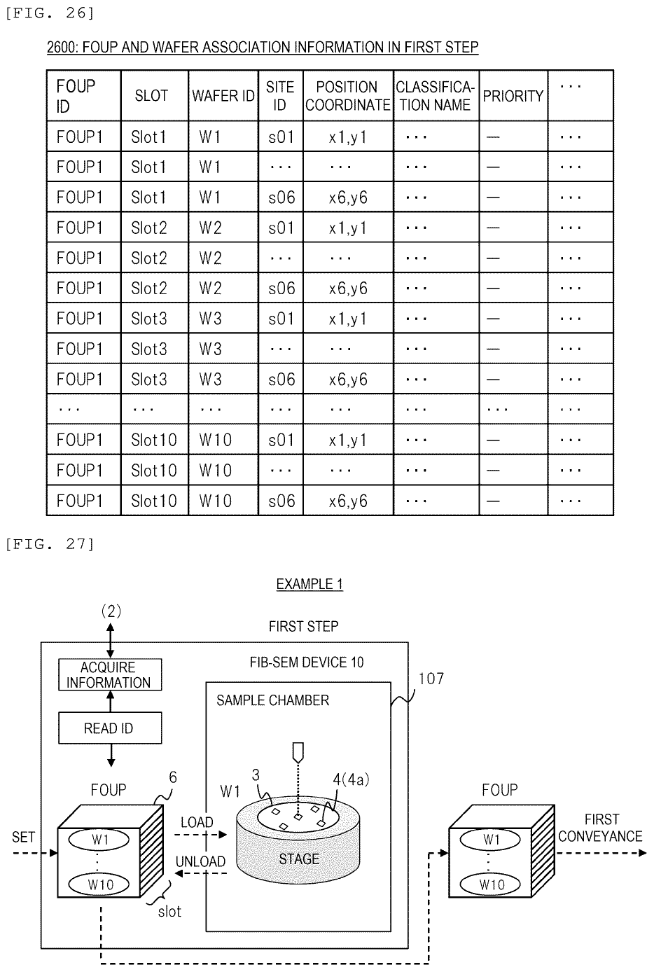

FIG. 26 shows an example of association information 2600 between a FOUP and a wafer in the FIB-SEM device 10 in the first step. A table of the information 2600 includes column items such as a FOUP ID, a slot, a wafer ID, a site ID, position coordinates, a classification name, and a priority. Information such as a classification name can also be associated with the information 2500 based on the machining instruction information 53.

The machining instruction information 53 as shown in FIG. 23 includes a wafer ID. Therefore, at the time when the FOUP and the wafer are associated with each other, that is, at the time when the information 2600 as shown in FIG. 26 is obtained, each wafer 3 and machining instruction information are connected in a one-to-one relation.

(1-6) Next, a user, for example, a worker associated with the first step sets, in the FIB-SEM device 10, a FOUP that stores the associated wafer 3. In the present example, the wafer 3 stored in a FOUP, which is received from the manufacturing line, is stored in a FOUP used in the first conveyance step, and the FOUP is set in the FIB-SEM device 10. The FIB-SEM device 10 appropriately loads the wafer 3 from the FOUP, performs machining for forming the thin piece 4 at a site, unloads the machined wafer 3, and stores the wafer 3 in the FOUP. The FOUP is conveyed in the first conveyance step.

The work of each step is not limited to being performed by one person, and may be performed by multiple persons, and for example, may be performed by appropriate communication and cooperation between an inspection administrator and a worker of each step.

FIG. 27 is a schematic diagram showing setting of a FOUP in the FIB-SEM device 10 in the first step S1 in Example 1. FIG. 27 shows that the FOUP (the holder 6) is set in the FIB-SEM device 10, the wafer 3 is loaded into the sample chamber 107 from the set FOUP, thinning machining is performed on a site of the wafer 3, the machined wafer 3 is unloaded to a FOUP, and the FOUP is conveyed in the first conveyance step.

(1-7) The FIB-SEM device 10 reads an ID of the holder 6 which is the set FOUP. The FIB-SEM device 10 includes a mechanism for reading the ID of the FOUP (the ID reader 171 described above). When the FIB-SEM device 10 does not include such a mechanism, a user such as a worker may perform an operation of reading the ID of the FOUP into the FIB-SEM device 10.

(1-8) Based on the read ID of the FOUP, the FIB-SEM device 10 acquires information on the wafer 3 stored in the FOUP from the inspection management system 2. The information acquired here is information about which wafer 3 is stored in which slot of the FOUP or machining instruction information for each stored wafer 3. The information acquired here includes, for example, information corresponding to the machining instruction information 53 for each wafer 3 as shown in FIG. 23, and includes recipe information in the FIB-SEM device 10. The FIB-SEM device 10 may request the management system 2 to acquire these pieces of information as a response at this time, or may refer to information transmitted from the management system 2 in advance and stored in own device at this time. Each device may acquire only recipe information of own device.

(1-9) Next, the FIB-SEM device 10 loads the wafers 3 specified by the machining instruction information 53 from the FOUP onto a stage in the sample chamber 107 in a specified order. For example, the wafer W1 is first loaded.

(1-10) According to the machining instruction information 53, the FIB-SEM device 10 sequentially executes thinning machining based on irradiation with a charged particle beam in a specified order at machining coordinates of sites (for example, S01 to S06) that are inspection target locations on a surface of the wafer W1 on the stage. The machining for forming the plurality of thin pieces 4 at a plurality of sites is performed, for example, in the order of numbers of the thin piece IDs (FIG. 23). Details of the machining can be specified in the above-described machining instruction.

(1-11) After the thinning machining for all target sites on the target wafer 3 is completed, the FIB-SEM device 10 unloads the wafer 3 (for example, the wafer W1) from the sample chamber 107. In the present example, the unloaded wafer 3 is stored in a slot of the FOUP for the first conveyance.

(1-12) Similarly, the FIB-SEM device 10 sequentially performs thinning machining on other target wafers 3 (for example, the wafers W2 . . . W10) in the FOUP while performing loading and unloading. The FIB-SEM device completes the thinning machining for all target sites of all target wafers in the FOUP.

(1-13) The FIB-SEM device 10 appropriately transmits information indicating a status and a result of a processing operation of the thinning machining to the inspection system 2. The management system 2 grasps the status and the result of the processing operation in the FIB-SEM device 10 in the first step based on the information received from the FIB-SEM device 10, and updates the status and result management information 54. In addition, when there is information related to a result of a processing operation of the FIB-SEM device 10, which needs to be delivered to the lift out device 20 of the next second step, the FIB-SEM device 10 transmits the information to the lift out device 20 of the second step or the management system 2. In the present example, the information includes information about which wafer 3 is stored in which slot of the FOUP used in the first conveyance and information about which thin piece 4 is formed in each site of each wafer 3. The FIB-SEM device 10 transmits such information to the management system 2, and the management system 2 delivers such information by transmitting the information to the lift out device 20 in the second step.

(1-14) Although omitted in the above example, the processing operation when the wafer 3 is stored in the FOUP for the first conveyance, which is a processing operation in the FIB-SEM device 10, can be controlled by the transfer instruction information 57. That is, it is also possible to control in detail which wafer 3 is stored in which FOUP and conveyed to which lift out device 20.

(1-15) In the first conveyance step (FIGS. 1 and 6), the FOUP (the holder 6) that stores the wafer 3 on which the thin piece portion 4a is formed is conveyed from a place of the FIB-SEM device 10 to a designated place of the lift out device 20 by an automatic conveyance system or manual conveyance. Then, a user, for example, a worker associated with the second conveyance step or the second step sets the FOUP in the lift out device 20.

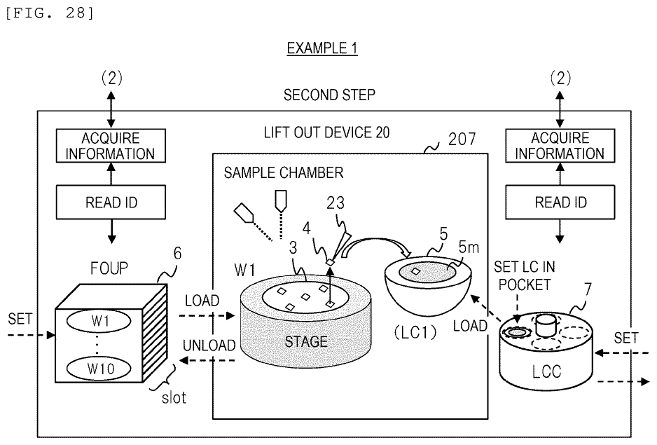

FIG. 28 is a schematic diagram showing setting of a FOUP, an LC, and the like in the lift out device 20 of the second step in Example 1.

(1-16) The lift out device 20 in the second step acquires information on the set FOUP from the FIB-SEM device 10 in the first step or the inspection management system 2. The information is information about the wafer 3 stored in a slot of the FOUP, a site on the wafer 3, and the thin piece portion 4a formed at the site. The information corresponds to the machining instruction information 53 about the wafer 3 and the site. Further, the information includes information indicating to which carrier 5 (LC) the thin piece 4 taken out from the wafer 3 is to be transferred.

In the present example, the lift out device 20 reads an ID of the set FOUP using the ID reader 271 described above. The lift out device 20 acquires the above-described information from the management system 2 based on the read ID. Alternatively, the lift out device 20 may refer to the same information that was received and stored in advance from the management system 2. Based on the information, the lift out device 20 grasps which wafer 3 is loaded from which slot of the FOUP and the thin piece 4 at which site is transferred.

(1-17) On the other hand, in the lift out device 20 of the second step, a user, for example, a worker associated with the second step sets an LC which is the carrier 5 in a pocket of the LCC 7 which is the LCC 7 used in the second conveyance step, and sets the LCC 7 in the lift out device 20. For example, an “LC 1” (an LC having an LC-ID of 1) is set in a “pocket 1” of the LCC 7, and an “LC 2” is set in a “pocket 2”. The lift out device 20 or the management system 2 grasps which LC is set in which pocket of which LCC 7, a maximum number of transfer in each LC, the current number of transfer, the number of vacancies, and the like.

FIG. 28 shows an example in which the LCC 7 (FIG. 6) is set in the lift out device 20. In the present example, the lift out device 20 includes a mechanism capable of setting the LCC 7. The invention is not limited thereto, and the LC may be set without setting the LCC 7 in the lift out device 20. In the second conveyance step, the LC may be conveyed without using the LCC 7.

FIG. 28 shows a case where the wafer 3 loaded from the FOUP, for example, the wafer W1 at the beginning, is disposed on the stage, and the LC, for example, the “LC 1” loaded from a predetermined pocket of the set LCC 7 is disposed in the sample chamber 207. The lift out device 20 can take out the thin piece 4 from a site of the wafer 3 by using the attaching and detaching device 23 and transfer the thin piece 4 onto the mesh 5m of the LC which is the carrier 5 while monitoring an object by irradiation with a charged particle beam.

(1-18) The lift out device 20 reads an ID of the LC stored in a pocket of the set LCC 7 by using the ID reader 271 described above. The lift out device 20 acquires or refers to information on the LC from the management system 2 based on the read ID. The information corresponds to the machining instruction information 53 and the transfer instruction information 57. The information corresponds to the above-described information obtained based on the ID of the FOUP. That is, the information includes information indicating from which site of which wafer 3 in which FOUP the thin piece 4 is taken out and to which position (the support portion 5b described above) of which LC the taken-out thin piece 4 is transferred. Based on the above information, the lift out device 20 grasps from which site of which wafer 3 in which FOUP the thin piece 4 is taken out and transferred to which position of which LC.

The information includes observation instruction information on the thin piece 4 to be transferred. Examples of the observation instruction information include recipe information including a TEM observation condition in the TEM device 30 in the third step, a classification name, and the information delivered from the FIB-SEM device 10. In the example of the machining instruction information 53 as shown in FIG. 23, there are two types of TEM recipes of the “TEM recipe A” and the “TEM recipe B” for six thin pieces (“W1_S01” to “W1_S06”) of the wafer W1. The classification name “Edge Area” is set in the “TEM recipe A” (including an observation condition A) for the four thin pieces (“W1_S01” to “W1_S04”), and the classification name “Center Area” is set in the “TEM recipe B” (including an observation condition B) for the two thin pieces (“W1_S05” and “W1_S06”).

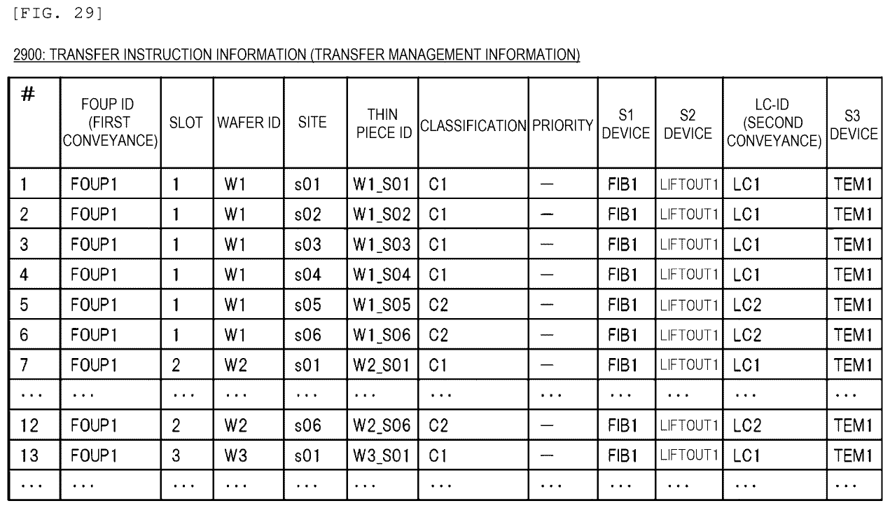

FIG. 29 shows an example of the transfer instruction information 57 related to the second step. A table of transfer instruction information 2900 in FIG. 29 includes item columns of a number (#), a FOUP ID (first conveyance), a slot, a wafer ID, a site, a thin piece ID, a classification, a priority, an S1 device, an S2 device, an LC-ID (second conveyance), and an S3 device. The number indicates a row and a processing order. The “FOUP ID (first conveyance)” indicates an ID of a FOUP used in the first conveyance step. The “S1 device” indicates an ID of the FIB-SEM device 10 used in the first step. The “S2 device” indicates an ID of the lift out device 20 used in the second step. The “LC-ID (second conveyance)” indicates an ID of an LC (the carrier 5) used in the second conveyance step. The “S3 device” indicates an ID of the TEM device 30 used in the third step. For example, as shown in a row of #=1, the thin piece 4 having the thin piece ID “W1_S01” indicates that the thin piece 4 formed at the site S01 of the wafer W1 loaded from a slot 1 of the FOUP 1 is taken out and transferred to the LC having the LC-ID of “LC 1” when the thin piece 4 is processed by the lift out device 20 of a “LIFT OUT 1”. Although omitted in FIG. 29, a position of a transfer destination of the LC (the support portion 5b), an ID of the LCC 7 in which the LC is set, and the like may be further defined.

(1-19) The lift out device 20 performs a processing operation of transferring the thin piece 4 of the wafer 3 to the LC according to the acquired or referred information (the machining instruction information 53 and the transfer instruction information 57). As shown in FIG. 28, the lift out device 20 loads the designated wafer 3 from the slot of the set FOUP into the sample chamber 207, takes out the thin piece 4 from a designated site of the wafer 3, and transfers the taken-out thin piece 4 to a position on a designated LC loaded into the sample chamber 207. When the processing operation is sequentially performed for a plurality of thin pieces, the lift out device 20 appropriately performs loading and unloading of the wafer 3 and loading and unloading of the LC according to an instruction. The loading of the LC corresponds to placing the LC, which is set in a designated pocket in the LCC 7, in the sample chamber 207 at a predetermined position.

In addition, the lift out device 20 sequentially performs a processing operation for a plurality of thin pieces, the processing operation including determination of a transfer destination according to information such as a classification name in the information. For example, the lift out device 20 performs a processing operation of transferring the thin piece 4 to a different LC according to a classification name (particularly, a difference in the on-wafer position or a difference in the TEM recipe).

FIG. 30 shows details of a transfer processing operation in the lift out device 20 in the second step, and shows a case where an LC which is a transfer destination is determined according to a classification for each TEM observation recipe. First, the lift out device 20 loads the wafer W1 from a FOUP into the sample chamber 207 and loads the “LC 1” from the LCC 7. For the wafer W1, the lift out device 20 sequentially takes out the four thin pieces 4 of “W1_S01” to “W1_S04” whose classification name is the “Edge Area” (the classification C1) and transfers the thin pieces 4 to the “LC 1”. Next, the lift out device 20 unloads the “LC 1” and loads the “LC 2”. For the wafer W1, the lift out device 20 sequentially takes out the two thin pieces 4 of “W1_S05” and “W1_S06” whose classification name is the “Center Area” (classification C2) and transfers the thin pieces 4 to the “LC 2”. Since the processing for all the sites of the wafer W1 is completed, the lift out device 20 unloads the wafer W1.

Similarly, the lift out device 20 sequentially performs a transfer processing operation for the wafers W2 to W10 while performing loading and unloading of the wafers 3 and the LCs. The wafer 3 for which the processing is completed is unloaded to a FOUP, and the LC for which the processing is completed is unloaded to the LCC 7.

(1-20) The lift out device 20 completes the transfer processing operation for all the target wafers 3. The lift out device 20 appropriately transmits information indicating a status and a result of the transfer processing operation to the inspection management system 2. The lift out device 20 transmits information that needs to be delivered to the TEM device 30 in the third step to the TEM device 30 or the management system 2. The management system 2 grasps the status and the result of the processing operation of the lift out device 20 based on the information received from the lift out device 20, and updates the status and result management information 54. The management system 2 delivers necessary information to the TEM device 30. The necessary information corresponds to the machining instruction information 53 and the transfer instruction information 57, and includes information indicating which thin piece 4 is transferred to which LC of which LCC 7, observation instruction information of the thin piece 4, and the like.

At this time, for example, for the wafer W1, the four thin pieces 4 of “W1_S01” to “W1_S04” having the classification name “Edge Area” are transferred to the “LC 1”, and the two thin pieces 4 of “W1_S05” and “W1_S06” having the classification name “Center Area” are transferred to the “LC 2”. The two LCs (the LC 1 and the LC 2) are set in designated pockets of the designated LCC 7. The inspection management system 2 grasps such a state according to the transfer instruction information 57, the status and result management information 54, and the like.

(1-21) In the second conveyance step, the LCC 7 in which the designated LC is set is conveyed from a place of the lift out device 20 to a place of the designated TEM device 30 by an automatic conveyance system or manual conveyance. A user such as a worker associated with the second conveyance step or the third step sets the LCC 7 in the TEM device 30. In a specific example, the LC taken out from the LCC 7 as described above is transferred to the cartridge 8 for the TEM device 30, and the cartridge 8 is set in the TEM device 30. Since the cartridge 8 and the LC have a correspondence relation and the correspondence relation is managed, it may be considered that the LC is set in the TEM device 30.

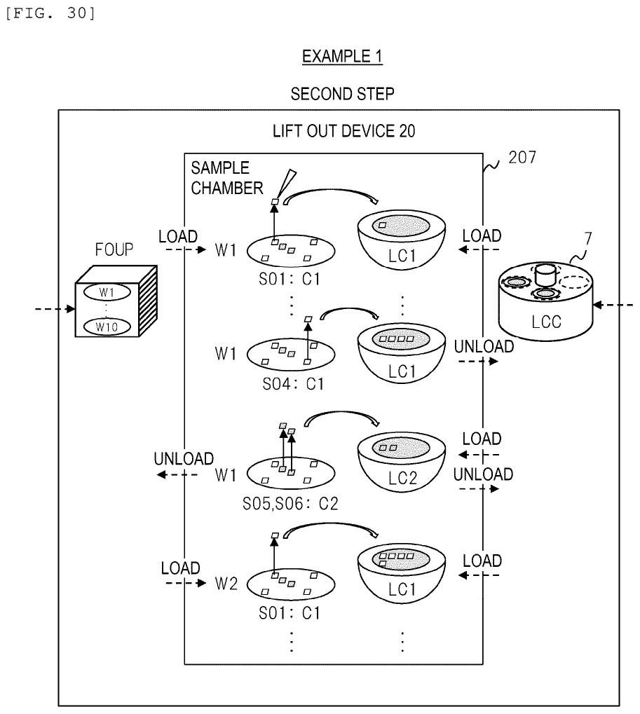

FIG. 31 is a schematic diagram showing setting of an LC and the like in the TEM device 30 in the third step.

(1-22) The TEM device 30 reads an ID of an LC set in a state of being placed in the cartridge 8 by using the ID reader 371 described above. The TEM device 30 acquires or refers to information about the LC and the thin piece 4 transferred to the LC from the inspection management system 2 based on the read ID. The TEM device 30 may request the management system 2 to acquire information, or may refer to information transmitted and stored in advance from the management system 2. The information corresponds to the machining instruction information 53 and the transfer instruction information 57. The information includes observation instruction information about the thin piece 4 transferred to the LC. Examples of the information include recipe information including a TEM observation condition, a classification name, and information delivered from the FIB-SEM device 10 and the lift out device 20.

The TEM device 30 grasps the order of observation, an observation condition, and the like for each thin piece 4 on the set LC based on the information. As described above, for example, the “TEM recipe A” is set for the four thin pieces 4 “W1_S01” to “W1_S04” that have the classification name “Edge Area” and are transferred to the “LC 1”, and the “TEM recipe B” is set for the two thin pieces 4 “W1_S05” and “W1_S06” that have the classification name “Center Area” and are transferred to the “LC 2”.

(1-23) The TEM device 30 loads, into the electron beam column 31, the cartridge 8 in which the LC is placed, and places and fixes the cartridge 8 on the sample holder 303. The TEM device 30 first loads the “LC 1”. The TEM device 30 adjusts and sets an observation condition and the like of the “TEM recipe A” and performs pre-processing such as alignment.

(1-24) The TEM device 30 sequentially executes the cross section observation processing operation for the thin pieces 4 (“W1_S01” to “W1_S04”) in the “LC 1” in the electron beam column 31 according to a designated order and a designated recipe. The TEM device 30 completes the cross section observation processing operation for all the thin pieces 4 in the “LC 1”. Thereafter, the TEM device 30 unloads the “LC 1”.

(1-25) The TEM device 30 then loads the “LC 2” and adjusts and sets an observation condition and the like of the “TEM recipe B”. The TEM device 30 sequentially executes the cross section observation processing operation for the thin pieces 4 (“W1_S05” and “W1_S06”) in the “LC 2” in the electron beam column 31 according to a designated order and a designated recipe. The TEM device 30 completes the cross section observation processing operation for all the target thin pieces 4 in the “LC 2”. Thereafter, the TEM device 30 unloads the “LC 2”.

(1-26) The TEM device 30 appropriately transmits information indicating a status and a result of the observation processing operation to the inspection management system 2. The TEM device 30 stores and outputs the data 9 including an image or the like serving as a result of the cross section observation (TEM image observation) on the thin piece 4. The TEM device 30 also transmits the data 9 to the inspection management system 2. In addition, when there is information that needs to be delivered to the lift out device 20 or the FIB-SEM device 10 in a previous stage, the TEM device 30 transmits the information to the lift out device 20, the FIB-SEM device 10, or the inspection management system 2.

(1-27) Based on the information and the data 9 received from the TEM device 30, the inspection management system 2 grasps the status and the result of the processing operation of the TEM device 30, updates the status and result management information 54, and grasps an overall result of the inspection processing sequence. The inspection management system 2 may output an image of the observation result or the like to the user U1 based on the data 9. When the inspection management system 2 receives, from the TEM device 30, the information that needs to be delivered, the inspection management system 2 transmits the information to the lift out device 20 or the FIB-SEM device 10.

Through the above flow, the inspection processing sequence in the inspection system 1 is completed. In this flow, the inspection management system 2 can perform instructing, control, assisting, and the like by using the machining instruction information 53 including the classification name and the like and the transfer instruction information 57 for a processing operation related to transfer in each device. Accordingly, an effect according to setting of the classification name by the user U1 is obtained.

In the above example, before the inspection processing, the user U1 sets different classification names for sites of the target wafer 3 according to a difference in on-wafer positions and a difference in TEM recipes including TEM observation conditions. The management system 2 and devices of the inspection system 1 perform control to transfer the plurality of thin pieces 4, to which the same classification name (such as a corresponding TEM recipe) is assigned, to the same carrier 5 (LC) according to the machining instruction information 53 including the classification name and the transfer instruction information 57. In other words, the thin pieces 4 having different classification names are controlled to be transferred to different carriers 5 (LCs). Accordingly, when the TEM device 30 observes the thin pieces 4 on the carrier 5 (LC), since the thin pieces 4 having the same recipe are collected in each LC, it is possible to reduce necessary processing for each recipe such as switching of an observation condition for each thin piece 4. Since a plurality of thin pieces on the same LC have the same observation condition, switching of the observation condition is minimized. Accordingly, a TAT for an observation processing operation in the TEM device 30 can be shortened, and observation efficiency can be improved.

When an additional inspection is required based on confirmation of an observation result in the TEM device 30, since the thin pieces 4 for which the additional inspection is required are collected and mounted on the same LC, the LC to be subject to the additional inspection can be easily taken out from a stock shelf at the time of the additional inspection, and efficiency related to the additional inspection is also improved (a modification to be described later).

As for the transfer instruction information 57 as shown in FIG. 29, the management system 2 may specify and control a transfer order, a transfer destination, and the like in details, or each device of the inspection system 1 may determine details of a transfer destination and the like according to an instruction of a rough policy related to the transfer from the management system 2.

Although a case where two classification names are used according to two types of on-wafer positions and TEM recipes is described in Example 1, the invention is not limited thereto, and when there are three or more types of classifications, control can be similarly performed using the three or more types of classifications.

### Example 2

Example 2 is similar to Example 1, but a classification name set by the user U1 is used to instruct and control a processing operation including transfer in Example 2. The Example 2 is different from the Example 1 in that the inspection management system 2 instructs and controls, as the target, the second type inspection system 1 (FIG. 7) that is not provided with the lift out device 20.

A flow in Example 2 is the same as that in Example 1 up to (1-8) described above. The machining instruction information 53 created and set by the user U1 is the same as that in FIG. 23.

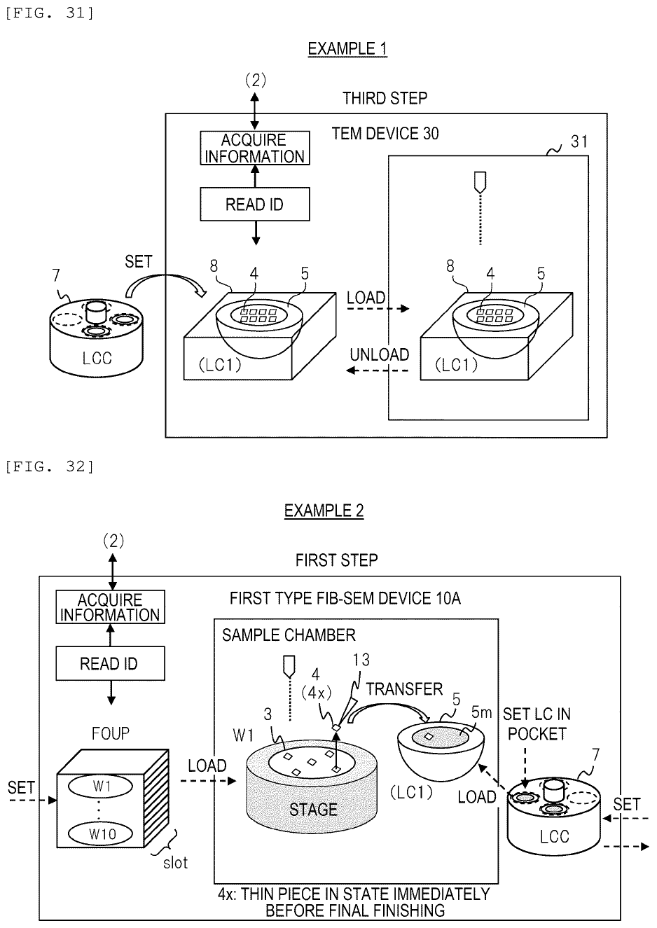

FIG. 32 is a schematic diagram showing setting of a FOUP, an LC and the like in the first type FIB-SEM device 10A in the first step in Example 2.

After the inspection processing starts, a FOUP that stores the target wafer 3 is set in the first type FIB-SEM device 10A in the first step. The first type FIB-SEM device 10A reads an ID of the set FOUP and acquires or refers to information about the wafer 3 stored in the FOUP from the inspection management system 2 based on the ID.

(2-1) Next, a user such as a worker associated with the first step sets an LC in a pocket of the LCC 7 to be used in the first conveyance step, and sets the LCC 7 in the first type FIB-SEM device 10A. For example, the “LC 1” is set in the “pocket 1”, and the “LC 2” is set in the “pocket 2”.

(2-2) Next, the first type FIB-SEM device 10A loads the designated wafer 3, for example, the wafer W1 at the beginning, from a slot of the FOUP into the sample chamber and places the wafer on the stage.

(2-3) Next, the first type FIB-SEM device 10A loads the designated LC, for example, the “LC 1” in the “Pocket 1” at the beginning, from the LCC into the sample chamber and places the LC at a predetermined position.

(2-4) Next, the first type FIB-SEM device 10A forms a thin piece 4x (a thin piece ID=“W1_S01”) up to a state immediately before the final finishing by performing thinning machining by irradiation with a charged particle beam according to a designated recipe on a first site (for example, S01) having a classification name (for example, “Edge Area”) of the first classification C1 on the wafer W1.

(2-5) Next, the first type FIB-SEM device 10A takes out the thin piece 4x (W1_S01) formed at the first site (S01) of the wafer W by cutting out the thin piece 4x (W1_S01) by the above-described machining using the above-described needle 13 (the probe unit 112 in FIG. 8), and transfers the thin piece 4x (W1_S01) to a designated position (the above-described support portion 5b) on the mesh 5m of the “LC 1” in the sample chamber.

(2-6) Next, the first type FIB-SEM device 10A performs thinning machining on a second site (S02) having the same classification name (C1) on the wafer W1 in a similar manner to form a thin piece 4x (“W1_S02”) up to a state immediately before the final finishing. The first type FIB-SEM device 10A takes out the thin piece 4x (“W1_S02”) and transfers the thin piece 4x to a designated position (the support portion 5b) on the mesh 5m of the same “LC 1”.

(2-7) Similarly, the first type FIB-SEM device 10A sequentially performs thinning machining on other sites (for example, S03 and S04) having the same classification name (C1) on the wafer W1 and transfers the thin pieces to the same “LC 1”.

(2-8) Next, the first type FIB-SEM device 10A forms the thin piece 4x (“W1_S05”) up to the state immediately before the final finishing by performing thinning machining on a site (for example, S05) having a classification name (for example, “Center Area”) of the second classification C2 on the wafer W1.

(2-9) Next, the first type FIB-SEM device 10A unloads the “LC 1” from the sample chamber to the LCC 7 and loads the “LC 2” from the LCC 7 into the sample chamber in order to transfer a thin piece having a different classification to another LC.

(2-10) The first type FIB-SEM device 10A takes out the thin piece 4x (“W1_S05”) from the site S05 on the wafer W1 by machining, and transfers the thin piece 4x to a designated position (the support portion 5b) on the mesh 5m of the “LC 2”.

(2-11) Similarly, the first type FIB-SEM device 10A performs thinning machining on a site (S06) having the same second classification C2 on the wafer W1, takes out the thin piece 4x (“W1_S06”), and transfers the thin piece 4x to a designated position on the mesh 5m of the same “LC 2”.

(2-12) After the processing for all target sites of the wafer W1 is completed, the first type FIB-SEM device 10A unloads the wafer W1.

(2-13) Similarly, the first type FIB-SEM device 10A sequentially repeats the processing operation for the other wafers W2 and the like, and completes the processing operation including the transfer for all the target wafers 3.

(2-14) The first type FIB-SEM device 10A appropriately transmits information indicating a status and a result of the processing operation to the inspection management system 2. The management system 2 receives the information, grasps the status and the result of the processing operation in the first type FIB-SEM device 10A, and updates the status and result management information 54. Further, the first type FIB-SEM device 10A transmits information that needs to be delivered to the second type FIB-SEM device 10B in the second step S2 to the second type FIB-SEM device 10A or the inspection management system 2. When the inspection management system 2 receives such information, the inspection management system 2 transmits the information to the second type FIB-SEM device 10B. The information is, for example, information indicating which thin piece is transferred to which LC.

(2-15) At the time when the first step is completed, the thinning machining and the transfer to the LC are completed for all the wafers (for example, W1 to W10) in the FOUP. In the LCC 7, the thin pieces (“W1_S01” to “W1_S04”) of the first classification (“Edge Area”) are transferred to the “LC 1”, and the thin pieces (“W1_S05” and “W1_S06”) of the second classification (“Center Area”) are transferred to the “LC 2”.

In the first conveyance step, the LCC 7 taken out from a place of the first type FIB-SEM device 10A is conveyed to a place of the second type FIB-SEM device 10B in the second step by automatic conveyance or manual conveyance. A user such as a worker associated with the first conveyance step or the second step sets the LCC 7 in the second type FIB-SEM device 10B.

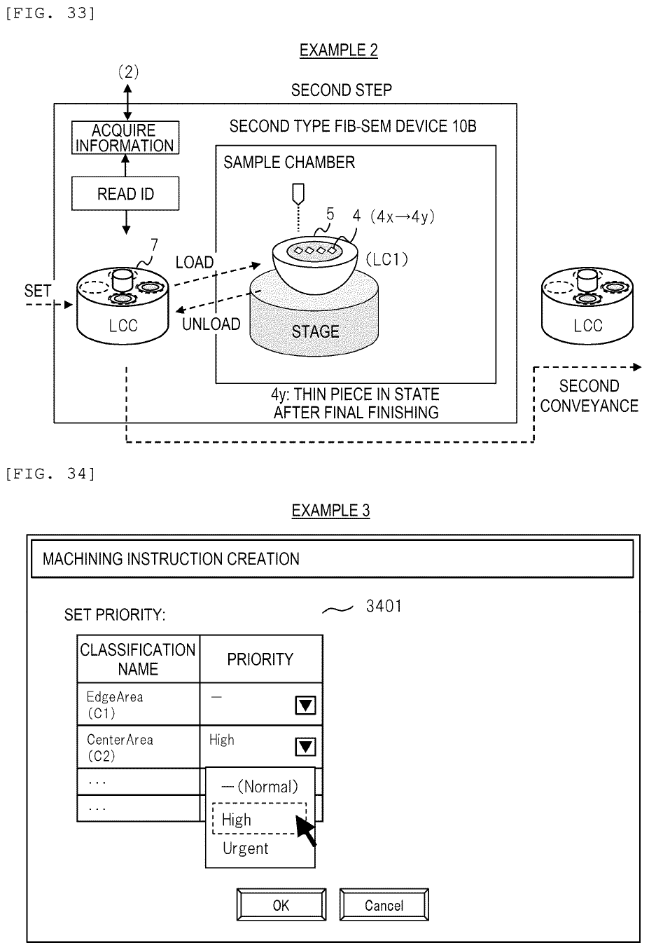

FIG. 33 is a schematic diagram showing setting of an LCC and the like in the second type FIB-SEM device 10B in the second step.

(2-16) The second type FIB-SEM device 10B reads an ID of an LC in the set LCC 7, and acquires or refers to information on the LC from the inspection management system 2 based on the ID. The information on the LC is information such as which thin piece 4 is transferred to which LC. Examples of the information include a recipe of a processing operation in the second type FIB-SEM device 10B, a classification name, and information delivered from the first type FIB-SEM device 10A.

(2-17) The second type FIB-SEM device 10B first loads the designated “LC 1” into the sample chamber from the LCC 7. The loaded “LC 1” is positioned on a stage so that it can be machined by a charged particle beam.

(2-18) The second type FIB-SEM device 10B sequentially performs designated final finishing on the thin piece 4x in the final finishing remaining state on the mesh 5m of the “LC 1”, for example, the four thin pieces 4x of “W1_S01” to “W1_S04” having the same first classification, according to information such as a machining instruction. Each of the thin pieces 4x becomes a finally finished thin piece 4y after the final finishing. Accordingly, the thin pieces 4y (“W1_S01” to “W1_S04”) in the finally finished state are mounted on the “LC 1”.

(2-19) After the machining on all the target thin pieces 4 on the “LC 1” is completed, the second type FIB-SEM device 10B unloads the “LC 1” from the sample chamber to the LCC 7. In the present example, the same LCC 7 is used in the first conveyance step and the second conveyance step. Therefore, an unloading destination of the LC after the end of the machining is the same as the LCC 7 before the start of machining.

(2-20) Next, the second type FIB-SEM device 10B loads the designated “LC 2” from the LCC 7 into the sample chamber. Similarly to the “LC 1”, the second type FIB-SEM device 10B sequentially performs the final finishing on the thin pieces 4 (“W1_S05” and “W1_S06”) having the same second classification on the “LC 2”. After the machining on all the target thin pieces 4 on the “LC 2” is completed, the second type FIB-SEM device 10B unloads the “LC 2” to the LCC 7.

(2-21) The second type FIB-SEM device 10B appropriately transmits information indicating a status and a result of the processing operation to the inspection management system 2. The management system 2 receives the information, grasps the status and the result of the processing operation in the second type FIB-SEM device 10B, and updates the status and result management information 54. The second type FIB-SEM device 10B transmits information that needs to be delivered to the TEM device 30 in the third step to the TEM device 30 or the inspection management system 2. When the inspection management system 2 receives the information, the inspection management system 2 transmits the information to the TEM device 30.

(2-22) In the second conveyance step, the LCC 7 is conveyed from a place of the first type FIB-SEM device 10B to a place of the TEM device 30 in the third step by automatic conveyance or manual conveyance. A user such as a worker associated with the second conveyance step or the third step sets the conveyed LCC 7 in the TEM device 30. In a specific example, an LC taken out from a pocket of the LCC 7 is transferred to and set in the cartridge 8.

(2-23) In the TEM device 30 of the third step, as in FIG. 31, an ID of an LC of the set LCC 7 is read, and information on the LC from the inspection management system 2 is acquired or referred to based on the ID. Examples of the information include a recipe including a TEM observation condition, a classification name, and information delivered from the first type FIB-SEM device 10A and the second type FIB-SEM device 10B for the thin piece 4 transferred to the LC.

(2-24) The TEM device 30 first loads the designated “LC 1” into the electron beam column 31. The TEM device 30 sequentially performs a cross section observation processing operation for the thin pieces 4 (“W1_S01” to “W1_S04”) having the same first classification on the “LC 1” according to a designated recipe. Thereafter, the TEM device 30 unloads the “LC 1”.

(2-25) Next, the TEM device 30 loads the designated “LC 2” into the electron beam column 31. The TEM device 30 sequentially performs the cross section observation processing operation for the thin pieces 4 (“W1_S05” and “W1_S06”) having the same second classification on the “LC 2” according to a designated recipe. Thereafter, the TEM device 30 unloads the “LC 2”.

(2-26) The TEM device 30 appropriately transmits information indicating a status and a result of the processing operation to the inspection management system 2. When there is information that needs to be delivered to the first type FIB-SEM device 10A or the second type FIB-SEM device 10B, the TEM device 30 transmits the information to the first type FIB-SEM device 10A, the second type FIB-SEM device 10B, or the inspection management system 2. When the inspection management system 2 receives the information, the inspection management system 2 transmits the information to the first type FIB-SEM device 10A or the second type FIB-SEM device 10B. The TEM device 30 stores and outputs the data 9 serving as an observation result.

According to the Example 2, the same effects as those of Example 1 can be obtained.

### Example 3

In Example 3, the user U1 of the inspection management system 2 assigns and sets a priority to the thin piece 4 of the wafer 3 in addition to the classification name. Example 3 will be described in a case where the first type inspection system 1 is used. Example 3 is partially common to Example 1. The priority is information on how much priority is to be given to a processing operation for a target site or thin piece to which the priority is given among a plurality of target sites or thin pieces.

Similarly to Example 1, the user U1 creates a machining instruction on a screen of the management system 2 in response to an inspection instruction. For example, similarly to Example 1, the user U1 assigns the same classification name to thin pieces to be transferred to the same LC. For example, a classification name corresponding to a difference in the on-wafer position and a difference in the TEM recipe is assigned in the same manner as described above.

(3-1) Further, in Example 3, the user U1 assigns a priority to the classification name for each site of the target wafer 3 on the screen of the management system 2.

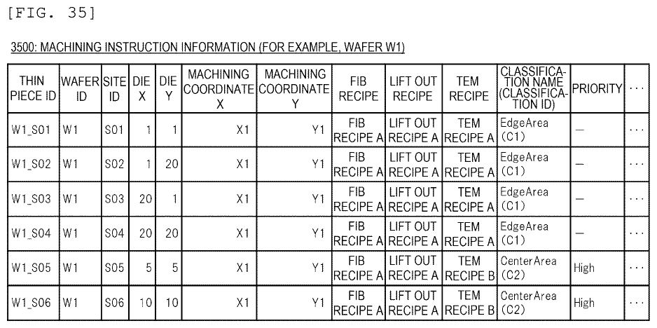

FIG. 34 shows a screen example when a priority is assigned to a classification name in Example 2. The screen in FIG. 34 includes a “priority setting” field 3401 as one GUI in the above-described machining instruction creation screen. In a table of the field 3401, a classification name and a priority are displayed in a correspondence manner. A set classification name is displayed in the classification name item. The user U1 can assign and set a priority for each classification name in this table. For example, the user U1 operates a priority item with a cursor or the like. Then, for example, priority options are displayed in a list box, and a priority can be set by selecting from the options. In the present example, priority options include “-(Normal)”, “High”, and “Urgent”. “-(Normal)” indicates that there is no priority (blank) or the priority is normal. “High” indicates that the priority is high. “Urgent” indicates that the priority is urgent. The order of priority is Normal<High<Urgent. In the present example, the priority “High” is assigned to the classification name “Center Area” (classification C2). For “-(Normal)”, in terms of management and implementation, a data structure may have no value of priority, or may have a value indicating that the priority is normal.

The GUI for setting the priority is not limited to the screen example in FIG. 34, and for example, the priority may be individually set together with the classification name for a site of a wafer in the table of the machining instruction on the above-described screen in FIG. 24. For example, a data structure of the priority may be a numerical value, and the priority may be expressed by the magnitude of the numerical value.

For example, on the screen of FIG. 34, a priority is added to the machining instruction information 53 for the wafer W1 of FIG. 23. In this case, on the wafer W1, the thin pieces 4 corresponding to the four sites S01 to S04 having the classification name “Edge Area” have a priority “Normal”, and the thin pieces 4 corresponding to the two sites S05 and S06 having the classification name “Center Area” have a priority “High”. Similarly, the other wafers 3 are assigned with priorities according to classification names.

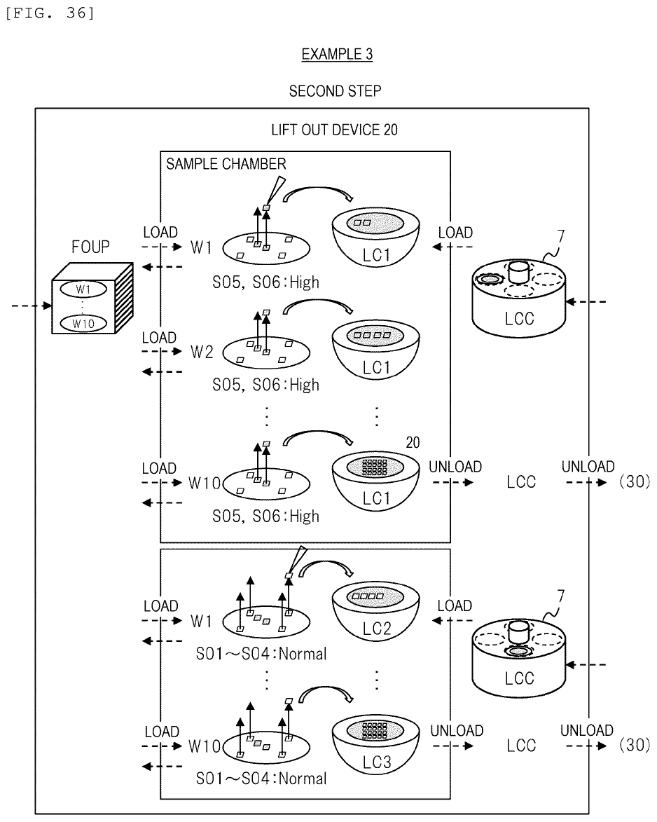

For example, the machining instruction information 53 for the wafer W1 after the priority is added has, for example, contents as shown in FIG. 35. In machining instruction information 3500 in FIG. 35, a value is added to a priority column in addition to the contents of the machining instruction information 2300 in FIG. 23. In the present example, the two sites S05 and S06 having the classification name “Center Area” have the priority “High”, which is a priority higher than the priority “-(Normal)” of the four sites S01 to S04 having the classification name “Edge Area”.

(3-2) After the inspection processing starts, in the FIB-SEM device 10 in the first step, a user such as a worker associated with the first step or the like associates a FOUP with the wafer 3 (similar to Example 1). The user stores the target wafer 3 conveyed from the manufacturing line in a FOUP used in the first conveyance step, and sets the FOUP in the FIB-SEM device 10. At this time, the wafer 3 and the machining instruction information 53 are connected in a one-to-one relation. Each site of each wafer 3 is associated with information on a classification name and a priority.

(3-3) The FIB-SEM device 10 reads an ID of the set FOUP and acquires or refers to information on the wafer 3 in the FOUP from the inspection management system 2 based on the ID. The information includes information on the classification name and the priority. Alternatively, the information is information on contents in which a processing operation such as transfer is controlled according to the classification name and the priority.

(3-4) The FIB-SEM device 10 loads the designated wafer 3, for example, the wafer W1 at the beginning, into the sample chamber from the FOUP (similar to FIG. 27). The FIB-SEM device 10 sequentially performs thinning machining on target sites (for example, S01 to S06) according to information such as a machining instruction for the wafer W1. In the present example, the thinning machining in the first step is not performed in consideration of a difference in a priority for a plurality of sites, but is sequentially performed in the order of numbers of thin piece IDs.

(3-5) After the machining for the first wafer W1 is completed, the FIB-SEM device 10 unloads the wafer W1. The FIB-SEM device 10 loads the second wafer W2 and sequentially performs thinning machining on a plurality of sites of the wafer W2. Similarly, the FIB-SEM device 10 sequentially performs machining on each wafer in the FOUP while performing loading and unloading. Accordingly, the thin piece portion 4a is formed at each site of each wafer 3 in the FOUP.

(3-6) The FIB-SEM device 10 appropriately transmits information indicating a status and a result of the processing operation to the inspection management system 2. The management system 2 grasps the status and the result of the processing operation of the FIB-SEM device 10 based on the information.

In addition, the FIB-SEM device 10 transmits information that needs to be delivered to the lift out device 20 in the second step to the lift out device 20 or the management system 2.

(3-7) In the first conveyance step, the FOUP is conveyed from a place of the FIB-SEM device 10 to a place of the lift out device 20 in the second step by automatic conveyance or manual conveyance. A user such as a worker associated with the first conveyance step or the second step sets the FOUP in the lift out device 20.

(3-8) A user sets an LC to the LCC 7 used in the second conveyance step. For example, the “LC 1” is set in the “pocket 1”, and the “LC 2” is set in the “pocket 2”. The user sets the LCC 7 in the lift out device 20.

(3-9) The lift out device 20 reads an ID of the set FOUP and acquires information on the wafer 3 in the FOUP from the management system 2 based on the ID. Further, the lift out device 20 reads an ID of the LC in the set LCC 7, and acquires information on the LC from the management system 2 based on the ID. The above-described information is the same as the information described in Example 1 and the like, and is information associated with a priority.

(3-10) The lift out device 20 loads a designated wafer, for example, the wafer W1 at the beginning, from the FOUP, and loads a designated LC, for example, the “LC 1” at the beginning, from the LCC 7.

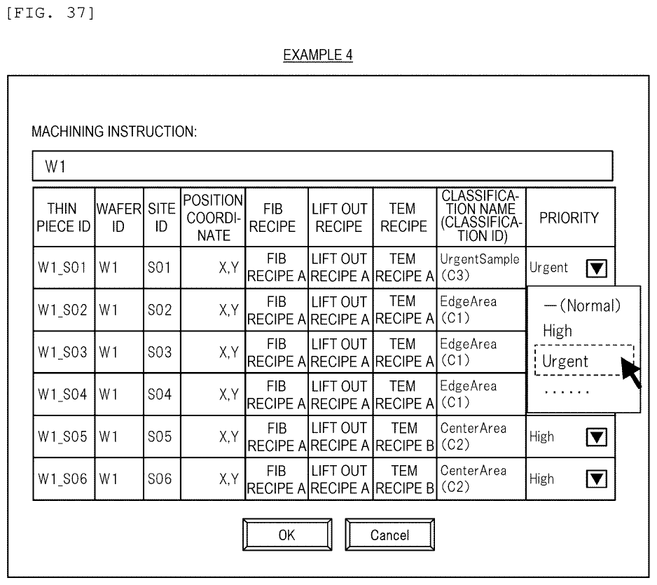

FIG. 36 is a diagram showing a transfer processing operation in consideration of a priority in the lift out device 20 in the second step in Example 3. In the present example, the lift out device 20 in the second step controls the transfer processing operation in consideration of the priority.

(3-11) Based on information on the classification name and the priority in the machining instruction information 53 (for example, FIG. 35), the lift out device 20 performs processing in descending order of the priorities on the six sites S01 to S06 of the wafer W1 in the sample chamber. That is, in the present example, the two sites S05 and S06 having the classification name “Center Area” with the priority “High” are processed before the four sites S01 to S04 having the classification name “Edge Area” with the priority “Normal”.

Therefore, the lift out device 20 first takes out the thin piece 4 from the site S05 of the wafer W1 and transfers the thin piece 4 to a designated position (the support portion 5b) on the mesh of the “LC 1”. Next, the lift out device 20 takes out the thin piece 4 from the site S06 of the wafer W1 and transfers the thin piece 4 to a designated position on the mesh of the “LC 1”. After all the thin pieces 4 with the priority “High” on the wafer W1 are transferred, the lift out device 20 unloads the wafer W1.

(3-12) Next, the lift out device 20 loads the designated second wafer W2 from the FOUP, and similarly takes out the thin pieces 4 from the sites S05 and S06 having the same priority “High” on the wafer W2, and transfers the thin pieces 4 to vacant locations (designated positions) of the “LC 1”. Similarly, for the third and subsequent wafers 3, the lift out device 20 takes out the thin pieces 4 from sites having the priority “High” and transfers the thin pieces 4 to vacant locations (designated positions) of the “LC 1”. The lift out device 20 uses the same “LC 1” as long as there is a vacancy in the “LC 1”. When the number of transfer in the “LC 1” reaches the maximum number of transfer and there is no vacancy, a thin piece is transferred to another LC.

(3-13) The lift out device 20 transfers the thin pieces 4 to the same LC as much as possible from all sites having the priority “High” of the target wafers 3, for example, on the 10 wafers W1 to W10. For example, 20 thin pieces 4 are transferred from the sites S05 and S06 of the wafers W1 to W10 to the “LC 1” whose maximum number of transfer is 20. At this time, all the thin pieces 4 having the classification name “Center Area” and the priority “High” on the wafers W1 to W10 are transferred to the “LC 1”. When the transfer is completed, the lift out device 20 unloads the “LC 1” and unloads the LCC 7 in which the “LC 1” is set. In the present example, the LC and the LCC 7 to be used are divided for each priority. Note that the LCC 7 unloaded at this time may be the LCC 7 different from the LCC 7 in which the “LC 1” is set at the beginning.

The lift out device 20 appropriately transmits information indicating a status and a result of the processing operation to the inspection management system 2. In particular, the lift out device 20 notifies and transmits, to the management system 2, information indicating that the transfer of all the thin pieces 4 having the priority “High” to the “LC 1” is completed. The management system 2 grasps the status and the result of the processing operation of the lift out device 20 based on the information. In particular, the management system 2 grasps that the processing operation of the second step S2 was performed on the thin piece 4 having the priority “High” first, and the LCC 7 in which the “LC 1” is set was delivered to the second conveyance step. Further, the lift out device 20 transmits information that needs to be delivered to the TEM device 30 to the TEM device 30 or the management system 2.

(3-14) In the second conveyance step, the LCC 7 in which the “LC 1” is set is conveyed from a place of the lift out device 20 to a place of the TEM device 30 in the third step by automatic conveyance or manual conveyance. A user such as a worker sets the LCC 7 in the TEM device 30.

(3-14) When the management system 2 receives the notification from the lift out device 20, the management system 2 may grasp that the transfer to the “LC 1” related to the priority “High” is completed, and, for example, display information indicating the completion on a screen to notify the user U1. The user U1 can confirm the information on the screen. The user U1 may set the LCC 7 in which the “LC 1” is set in the TEM device 30 based on the confirmation.

(3-15) The TEM device 30 in the third step S3 performs a cross section observation processing operation on the thin pieces 4 that have the priority “High” and are transferred to the “LC 1” in the set LCC 7. The procedure of the processing operation at this time is the same as that in the above-described Example 1 (for example, FIG. 31). In this manner, the observation of the thin pieces 4 having the priority “High” is performed first.

(3-16) On the other hand, a processing operation for the thin pieces 4 having the classification name “Edge Area” and the priority “Normal” is not performed in the lift out device 20 of the second step. Therefore, the lift out device 20 performs a processing operation related to such thin pieces 4. The lift out device 20 loads the “LC 2” which is a subsequent designated LC from the LCC 7. In the present example, the LCC 7 used at this time is the LCC 7 different from the LCC 7 used for conveying the “LC 1” corresponding to the priority “High”. Accordingly, the operations for the “LC 1” and the “LC 2” can be performed in parallel. When the operations for the “LC 1” and the “LC 2” are sequentially performed, the same LCC 7 may be used.

(3-17) The lift out device 20 first loads the wafer W1 from the FOUP into the sample chamber. The lift out device 20 sequentially takes out the thin pieces 4 from the sites S01 to S04 having the priority “Normal” on the wafer W1, and transfers the thin pieces 4 to designated positions (the support portions 5b) on the mesh of the “LC 2”. Similarly, the lift out device 20 sequentially takes out the thin pieces 4 from the sites S01 to S04 having the priority “Normal” and transfers the thin pieces 4 to vacant locations of the same “LC 2” as much as possible for the wafer W2 and subsequent wafers while loading and unloading the wafer 3. For example, when the “LC 2” and an “LC 3” having the maximum number of transfer of 20 are used, a total of 40 thin pieces 4 can be transferred to the “LC 2” and the “LC 3”, in each of which 20 thin pieces 4 can be transferred, from the sites S01 to S04 of the wafers W1 to W10. The lift out device 20 completes such transfer while appropriately loading and unloading LCs. At this time, all the thin pieces 4 having the classification name “Edge Area” and the priority “Normal” were transferred to the “LC 2” and the “LC 3” which are the carriers 5.

(3-18) When the above transfer is completed, the lift out device 20 unloads the LCC 7 in which the “LC 2” and the “LC 3” are set. The lift out device 20 appropriately transmits information indicating a status and a result of the processing operation to the inspection management system 2, and transmits information that needs to be delivered to the TEM device 30 to the TEM device 30 or the management system 2. In particular, the lift out device 20 may notify and transmit, to the management system 2, information indicating that the transfer of all the thin pieces 4 having the priority “Normal” is completed.

The management system 2 grasps the status and the result of the processing operation of the lift out device 20 based on the information from the lift out device 20. In particular, the management system 2 grasps that the processing operation of the second step S2 is completed for the thin pieces 4 having the priority “Normal” and the LCC 7 in which the “LC 2” and the “LC 3” are set is delivered to the second conveyance step.

(3-19) In the second conveyance step, the LCC 7 in which the “LC 2” and the “LC 3” are set is conveyed from a place of the lift out device 20 to a place of the TEM device 30 of the third step by automatic conveyance or manual conveyance. A user sets the LCC 7 in the TEM device 30.

(3-20) When the management system 2 receives the notification from the lift out device 20, the management system 2 may grasp that the transfer to the “LC 2” and the “LC 3” related to the priority “Normal” is completed, and, for example, display information indicating the completion on a screen to notify the user U1. The user U1 can confirm the information on the screen. The user U1 may set the LCC 7 in which the “LC 2” and the “LC 3” is set in the TEM device 30 based on the confirmation.

(3-21) The TEM device 30 in the third step S3 performs a cross section observation processing operation on the thin pieces 4 that have the priority “Normal” and are transferred to the “LC 2” and the “LC 3” in the set LCC 7. The procedure of the processing operation at this time is the same as that in the above-described Example 1 (for example, FIG. 31). In this manner, observation for the thin piece 4 having the priority “Normal” is performed after observation for the thin piece 4 having the priority “High”.

According to Example 3, for a plurality of wafers 3, when there are sites or thin pieces 4 having different priorities on the wafers 3, the thin pieces 4 are transferred to the carrier 5 (LC) first from the thin piece 4 having a higher priority, and for example, the thin pieces 4 are transferred in a manner of being collected into the same LC for each classification name. Then, the LC in which the thin pieces 4 are separately transferred according to the priority is conveyed to the TEM device 30, and the TEM device 30 performs observation from the thin piece 4 having a high priority. As described above, the relatively higher priority the thin piece 4 has, the preferentially a processing operation related to transfer and observation is performed. Accordingly, for the thin piece 4 to which a relatively high priority is assigned, a TAT up to when the observation in the TEM device 30 is completed can be shortened, and a result of an inspection processing can be obtained earlier than that of the thin piece 4 to which a relatively low priority is assigned. According to Example 3, the same control and effect as those of Example 1 can be achieved based on the classification name, and a control and an effect according to a priority of each thin piece 4 can be achieved using the priority.

### Example 4

Example 4 is similar to Example 3, and shows a function corresponding to a case where a priority assigned to the wafer 3 or a site is changed in the middle. In Example 4, the creation of a machining instruction by the user U1 in response to an inspection instruction, the assignment of a classification name and a priority, the inspection processing execution start, and the thinning machining in the FIB-SEM device 10 of the first step are the same as those in Example 1 or Example 3.

(4-1) The FIB-SEM device 10 in the first step performs, for example, machining for forming the thin pieces 4 at the sites S01 to S06 on the wafer W1, and then unloads the wafer W1.

(4-2) Next, the FIB-SEM device 10 transmits an image (a so-called cut & see image) acquired by imaging by an SEM at the time of the machining and machining result information to the inspection management system 2. The management system 2 receives the information and displays the information to the user U1 on a screen. The user views and confirms the image imaged by the FIB-SEM device 10 and the machining result information on the screen. When the user U1 finds, for example, a unique machining result on the thin piece portion 4a formed on the wafer W1, the user U1 determines a countermeasure for the unique machining result. The unique machining result is, for example, a machining shape deviated from an assumed machining shape. For example, the user U1 determines that the unique machining result needs to be preferentially observed by the TEM device 30.

(4-3) When such a determination is made, on a screen of the management system 2, the user U1 changes a classification name and a priority, or at least a priority for the wafer 3 (for example, W1) on which the thin piece 4 associated with the unique machining result is formed. The change here is not limited to a change in priority for each classification name, and may be a change in priority for each site. That is, different priorities may be assigned to the same classification name.

For example, a classification name is set to “Edge Area” and a priority is set to “Normal” at the beginning for the thin piece 4 (“W1_S01”) at the site S01 on the wafer W1 (similar to FIG. 35). The user U1 changes the classification name and the priority of the thin piece 4 after the user found the unique machining result. Here, as an intention of the user U1, it is assumed that the user U1 only wants to preferentially observe one thin piece (“W1_S01”) associated with the unique machining result using the TEM device 30. For this intention, the management system 2 changes the priority of the thin piece (“W1_S01”) from “Normal” to a higher priority based on an operation of the user U1 on the screen. In the present example, the management system 2 changes both the classification name and the priority for the thin piece.

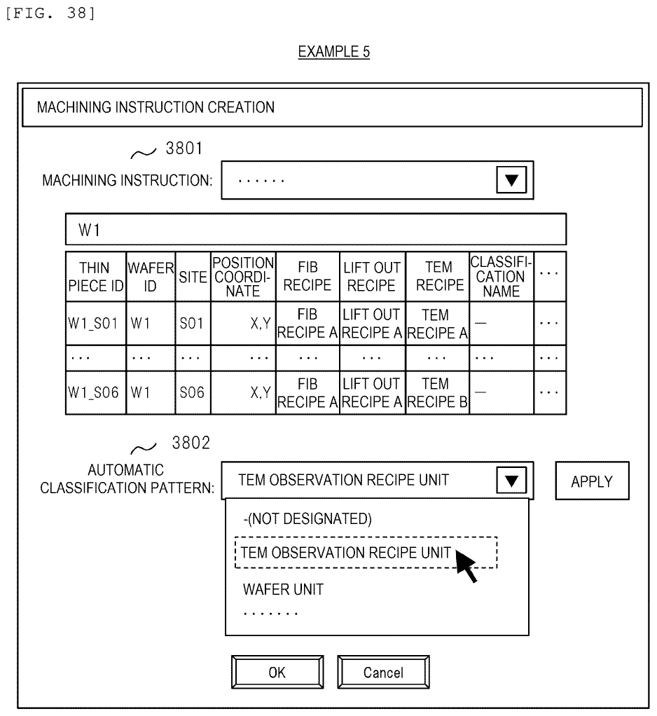

FIG. 37 shows an example of a GUI screen related to the change of the priority in Example 4. The screen example in FIG. 37 shows an example of changing values of the classification name and the priority for contents of the machining instruction information 53 for, for example, the wafer W1 on the machining instruction creation screen described above. The user U1 changes the classification name of the target thin piece (“W1_S01”) to, for example, “Urgent Sample” and changes the priority to “Urgent” on the screen. The priority “Urgent” is higher than the priority “High”. In a case where a correspondence relation between the classification name “Urgent Sample” and the priority “Urgent” is set in advance, for example, when the user U1 performs an operation of changing the classification name to “Urgent Sample” on the screen, the priority can be automatically changed to “Urgent”. The management system 2 may hold and manage a history of candidates and changes for values of the classification name and the priority, and can also perform an operation of returning the change to an original state.

As a modification, only the priority may be changed without changing the classification name. In this case, for example, the priority can be changed to “Urgent” while the classification name remains as “Edge Area”. The management system 2 and each device of the inspection system 1 determines contents of processing or the like by a set of a classification name and a priority.

(4-4) After the setting is changed to the classification name “Urgent Sample” and the priority “Urgent”, the management system 2 notifies and transmits information indicating the change to the FIB-SEM device 10. The FIB-SEM device 10 receives the information indicating the change. Alternatively, the FIB-SEM device 10 may inquire of the management system 2 about the latest classification name and priority, whether there is a change in priority, or the like, and acquire the information before the start of the processing operation of the thinning machining on the wafer 3.

(4-5) For example, when the FIB-SEM device 10 recognizes that the priority of the thin piece 4 at the site S01 of the wafer W1 is changed to “Urgent”, the FIB-SEM device 10 confirms the following matters. The FIB-SEM device 10 confirms whether an empty FOUP in which no wafer 3 is stored or a FOUP in which no unprocessed wafer is stored is set in a FOUP load port (a port in which the FOUP is set) of the FIB-SEM device 10. That is, such a FOUP is a container suitable for conveying the wafer 3 on which the thin piece 4 of “urgent” is formed. When such a FOUP is set, the FIB-SEM device 10 unloads and stores, in the FOUP, the wafer W1 on which the thin piece 4 of “Urgent” is formed. Further, the FIB-SEM device 10 notifies and transmits, to the inspection management system 2, information about the processing operation of storing, in the FOUP, the wafer W1 on which the thin piece 4 of “Urgent” is formed.

At this time, when an unmachined location remains on the wafer 3 during processing in the sample chamber, it is possible to select whether to unload the wafer 3 after the machining of the unmachined location is completed or to unload the wafer 3 in a state where the unmachined location remains. The selection may be separately instructed and set by the user U1 on a screen of the management system 2, or may be automatically determined by the management system 2 or the FIB-SEM device 10.

The thinning machining in the FIB-SEM device 10 depends on a size of the thin piece 4 and the like, and for example, it takes 30 minutes to 1 hour or more for one site. Therefore, when a degree of urgency is high according to a degree of urgency intended by the user U1, as the latter selection, the wafer 3 may be immediately unloaded in a state where the unmachined location remains, and the remaining unmachined location may be machined again later. The management system 2 may calculate and consider a time required for the thinning machining as described above to determine the selection, and in the case of the latter selection, the management system 2 may automatically create the machining instruction information 53 or the like for performing the machining again later.

In the present example, the former is selected. After the wafer is unloaded, the FIB-SEM device 10 continues the machining for the remaining unmachined location on the wafer W1 and ends the entire processing on the wafer W1.

(4-6) On the other hand, in the second conveyance step, the user conveys and sets the FOUP that stores the wafer W1 on which the thin piece 4 (“W1_S01”) of “Urgent” is formed to a place of the lift out device 20 by, for example, manual conveyance.

(4-7) The lift out device 20 loads the designated wafer W1 from the set FOUP, takes out the thin piece 4 from the site S01 having the designated “Urgent” on the wafer W1, and transfers the thin piece 4 to, for example, the carrier 5 which is the “LC 1”.

At this time, when an untransferred location remains on another wafer 3 that was loaded into the lift out device 20, the following selection can be made. That is, the wafer 3 may be unloaded after the transfer of the untransferred location is completed, or the wafer 3 may be unloaded in a state where the untransferred location remains. The selection may also be separately instructed and set by the user U1, or may be automatically determined by the management system 2 or the lift out device 20.

A time required for a transfer processing operation of the thin piece 4 by the lift out device 20 depends on mounting, and is relatively short. However, once the wafer 3 is unloaded, alignment processing or the like is required when the wafer 3 is loaded again. Therefore, basically, as the number of loading and unloading increases, a TAT related to transfer increases.

In the present example, the former is selected. After the transfer of the untransferred location of the existing wafer 3 is completed, the lift out device 20 unloads the wafer 3, loads the wafer W1, takes out the thin piece 4 of “Urgent” from the site S01 of the wafer W1, and transfers the thin piece 4 to the “LC 1”. The lift out device 20 unloads the “LC 1” and sets the “LC 1” in the LCC 7.

(4-8) The user U1 conveys and sets the LCC 7, in which the “LC 1” to which the thin piece 4 of “Urgent” was transferred is set, from the lift out device 20 to the TEM device 30 of the third step S3 by, for example, manual conveyance in the second conveyance step.

(4-9) The TEM device 30 loads the designated “LC 1” from the set LCC 7, performs an observation processing operation on the thin piece 4 of “Urgent” in the “LC 1”, and stores and outputs an observation result. The user U1 confirms the observation result on the screen.

When the “LC 1” is to be loaded, in a case where an unobserved location remains in the existing LC being processed by the TEM device 30, the following selection can be made. That is, the LC may be unloaded after the observation for the unobserved location is completed, or the LC may be unloaded in a state where the unobserved location remains. The selection may also be separately instructed and set by the user U1, or may be automatically determined by the management system 2 or the TEM device 30.

In the present example, the latter is selected. The TEM device 30 unloads the LC in a state where the unobserved location of the existing LC remains, loads the “LC 1”, and observes the thin piece 4 of “Urgent”. The LC in a state where the unobserved location remains is observed later.

According to Example 4, the priority can be changed in consideration of the degree of urgency related to TEM observation according to a machining result in the FIB-SEM device 10 and an imaged image, and the inspection processing sequence can be controlled according to the changed priority. The TEM observation can be performed first on the specific thin piece 4 whose priority was changed to “Urgent”.

In Example 4, as another example related to the priority change, the priority may be changed by the manufacturing management system 150. For example, the inspection management system 2 first receives the designation of the priority “Normal” for the site S01 or the like of the wafer W1 as an inspection instruction from the manufacturing management system 150. Thereafter, the inspection management system 2 receives, from the manufacturing management system 150, the designation of the priority “Urgent” as a priority change for the site S01 or the like of the wafer W1.

In this case, the inspection management system 2 updates instruction information about the inspection processing for the inspection system 1 based on the change to the priority “Urgent” for the site S01 or the like of the wafer W1. The updated instruction information is instruction information for preferentially processing an object whose priority was changed to the priority “Urgent”. A device of the inspection system 1 performs a processing operation related to a target object having the designated priority “Urgent” prior to a processing operation of a target object having a lower priority according to the latest instruction information.

### Example 5

In Example 5, the user U1 does not individually designate the classification name for sites of a target wafer, and the inspection management system 2 automatically designates and assigns the classification name. In this case, in Example 5, the inspection management system 2 automatically assigns a classification name based on a predetermined policy (here, described as an automatic classification pattern) for determining the classification name. The predetermined policy may be fixedly defined and implemented when the present system is designed, or may be selected and set by the user U1 on the GUI screen. Example 5 shows a case where the user U1 can set the automatic classification pattern which is a predetermined policy on the GUI screen. There are a plurality of such policies which are automatic classification patterns. In Example 5, a case where a “TEM observation recipe unit” is used as one of the automatic classification patterns will be described. The automatic classification pattern “TEM observation recipe unit” is a policy for assigning a classification for each TEM recipe including an observation condition of the TEM device 30, and an outline thereof is the same as the contents described in Example 1.

In Example 5, the user U1 creates a machining instruction for the target wafer 3 on the GUI screen of the inspection management system 2 in response to an inspection instruction in a similar manner to Example 1. For example, the machining instruction information 53 similar to that in FIG. 23 is obtained. The user associates a set FOUP with the wafer 3 in the FIB-SEM device 10 of the first step (for example, the same as that in FIG. 26).

In Example 5, the user U1 selects and sets the automatic classification pattern “TEM observation recipe unit” on the GUI screen of the inspection management system 2. The automatic classification pattern is a policy to be applied to a site of the target wafer 3 indicated by the machining instruction and the association information.

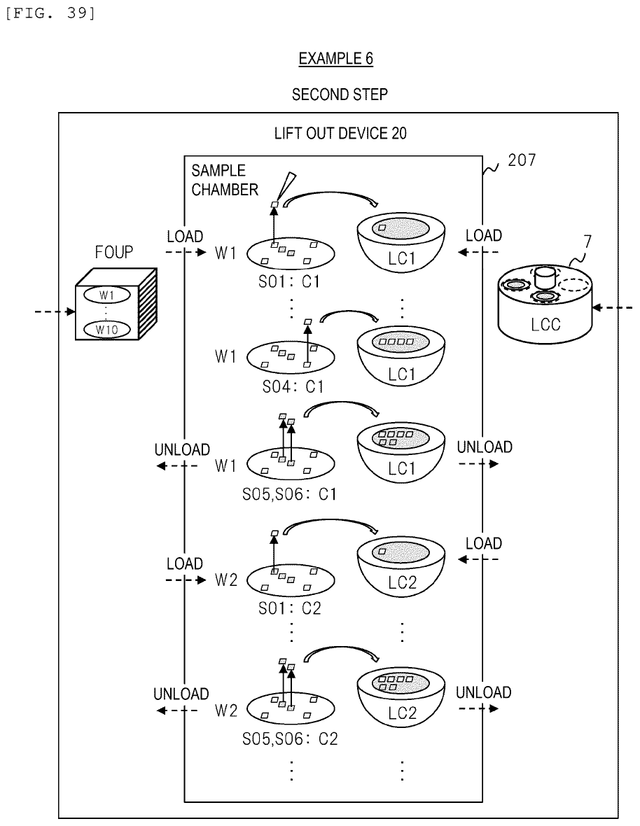

FIG. 38 shows a screen example when an automatic classification pattern is selected and set. In the screen example in FIG. 38, a machining instruction creation screen includes a machining instruction field 3801 and an automatic classification pattern field 3802. In the machining instruction field 3801, contents of the machining instruction information 53 set by the user U1 described above are displayed, and the classification name is not set at the beginning. In the automatic classification pattern field 3802, automatic classification patterns are displayed as options in, for example, a list box in response to an operation of the user U1, and the user U1 can select and set one from the automatic classification patterns. On this screen, the user U1 selects an automatic classification pattern to be applied to the machining instruction. In the present example, the automatic classification pattern “TEM observation recipe unit” is selected. When an “apply” button is operated, the selected automatic classification pattern is applied to the machining instruction information 53.

The inspection management system 2 automatically assigns a classification name to a site of the target wafer 3 in the machining instruction information 53 in response to the application of the selected automatic classification pattern “TEM observation recipe unit”. At this time, the classification management unit 402 in FIG. 19 determines the classification name for each row of the thin piece ID in the machining instruction information 53 based on confirmation of information about each item set by the user U1.

In the present example, based on the automatic classification pattern “TEM observation recipe unit”, the management system 2 determines a different classification name for each value according to a value of the item “TEM recipe” in the row of each thin piece ID, and sets the classification name in the item “classification”. In a default determination, the management system 2 internally sets a classification name to a TEM observation recipe name. For example, in the machining instruction information as shown in FIG. 35, there are two types of “TEM recipe” item values of the “TEM recipe A” and the “TEM recipe B” described above for the sites S01 to S06 of the wafer W1. Therefore, the management system 2 sets classification names of the default determination to the “TEM recipe A” and the “TEM recipe B” using the same values as those of the recipes. That is, a classification name of the sites S01 to S04 is set to the “TEM recipe A”, and a classification name of the sites S05 and S06 is set to the “TEM recipe B”.

The management system 2 displays the classification name serving as a result of the default determination in the machining instruction field 3801 as default. The user U1 may confirm the classification name of the default display of the automatic classification result in the machining instruction field 3801 and directly adopt the classification name, or may correct and set the classification name by the user U1.

Accordingly, in Example 5, the user U1 does not need to individually set the classification names to sites of each wafer 3, and it is possible to reduce the time and effort for advance setting of the classification. The subsequent inspection processing is the same as that described in Example 1. The automatic classification pattern “TEM observation recipe unit” is associated with control for dividing the LCs for transferring the thin pieces 4 for each TEM observation recipe. In Example 5, based on the automatic classification, for example, the thin pieces 4 to which the same TEM observation recipe is assigned have the same classification name, and are transferred in a manner of being collected into the same LC as much as possible during the inspection processing. Therefore, it is possible to minimize the number of times related to setting of observation conditions and the like when observation is performed with the TEM device 30 in a similar manner to Example 1. Therefore, a TAT related to observation can be shortened, and observation efficiency can be increased. In addition, the policy facilitates management of the LC when it is desired to manage the thin piece 4 for each TEM observation recipe.

A modification related to setting of the automatic classification pattern “TEM observation recipe unit” may be as follows. For example, as described above, a difference in the TEM observation recipes is associated with a difference in positions of sites on the wafer 3, for example, near an edge or near the center. Therefore, an “on-wafer position” or the like may be provided as one of the automatic classification patterns. In the case of this pattern, the management system 2 determines a position of a site on the wafer, classifies sites into two types such as near an edge or near the center, and assigns a classification name (for example, “Edge Area” or “Center Area”) according to the classification.

### Example 6

In Example 6, the inspection management system 2 automatically assigns a classification name based on the automatic classification pattern in a similar manner to Example 5. In Example 6, a case where a “wafer unit” is used as one of the automatic classification patterns will be described. The automatic classification pattern “wafer unit” is a policy for assigning a classification to each target wafer.

In Example 6, the user U1 selects and sets the automatic classification pattern “wafer unit” on the GUI screen (the same as that in FIG. 38) of the inspection management system 2. The management system 2 automatically assigns a classification name to a site of the target wafer 3 in the machining instruction information 53 in response to the application of the selected automatic classification pattern “wafer unit”. The management system 2 determines a different classification name for each value according to a value of the “wafer ID” item in a row of each thin piece ID, and sets the classification name in the “classification name” item. In a default determination, the management system 2 internally sets a classification name to a wafer ID. For example, in the machining instruction information as shown in FIG. 35, a value of the “wafer ID” item for the sites S01 to S06 of the wafer W1 is “W1”. Therefore, the management system 2 sets a classification name of the default determination to a “wafer W1”. Similarly, for example, the classification name of the sites S01 to S06 of the wafer W2 is set to a “wafer W2”.

The subsequent processing is the same as that in Example 5. According to Example 6, it is possible to reduce the time and effort for the user U1 to individually set the classification name in a similar manner to that in Example 5.

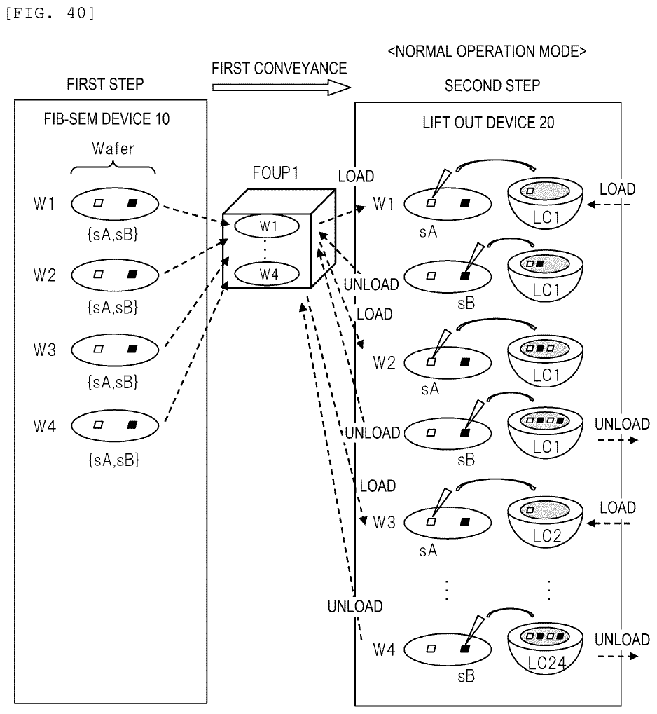

FIG. 39 shows details of the processing operation of the transfer in the lift out device 20 of the second step in Example 6, and shows a case where an LC which is a transfer destination is determined according to a classification for each wafer 3. First, the lift out device 20 loads the wafer W1 from the FOUP into the sample chamber 207 and loads the “LC 1” from the LCC 7. For the wafer W1, the lift out device 20 sequentially takes out the six thin pieces 4 of “W1_S01” to “W1_S06” having the classification name “wafer W1” (the classification C1) and transfers the thin pieces 4 to the “LC 1”. The lift out device 20 unloads the wafer W1 and unloads the “LC 1”.

Next, the lift out device 20 loads the wafer W2 and loads the “LC 2”. For the wafer W2, the lift out device 20 sequentially takes out the six thin pieces 4 of “W2 S01” to “W2_S06” having the classification name “wafer W2” (the classification C2) and transfers the thin pieces 4 to the “LC 2”. The lift out device 20 unloads the wafer W2 and unloads the “LC 2”. The same applies to the wafer W3 and subsequent wafers.

The automatic classification pattern “wafer unit” is associated with control for transferring the plurality of thin pieces 4 taken out from the same wafer 3 in a manner of being collected into the same LC as much as possible. In Example 6, based on the setting of the classification name in the wafer unit, the plurality of thin pieces 4 taken out from the same wafer 3 can be collectively transferred to the same LC as much as possible, and the number of times of loading and unloading of the wafer 3 and the LC in the FIB-SEM device 10 and the lift out device 20 can be reduced. That is, a TAT for a processing operation related to the transfer in the FIB-SEM device 10 or the lift out device 20 can be shortened. The policy facilitates the management of the LC when it is desired to manage the LC separately for each wafer 3.

Further, in Example 6, in a case where an additional inspection is required for each wafer 3, since the thin pieces 4 for which the additional inspection is required are accumulated on the same LC, a target LC can be easily taken out from a stock shelf, and the time and effort can be reduced. In addition, when there are a plurality of inspection target locations on one wafer 3 and TEM observation recipes thereof are common, a TAT for observation in the TEM device 30 can be relatively shortened, and thus the automatic classification pattern “wafer unit” in Example 6 is particularly effective.

As in the above example, when the user U1 can designate an automatic classification pattern but does not designate the automatic classification pattern, the user U1 can individually assign a classification name to each wafer 3 or each site in the machining instruction. In addition, a use method in which the classification name is not set can also be used. For example, by setting an automatic classification pattern to “not designate” on the screen in FIG. 38, it is possible to not assign a classification name. In this case, in the inspection processing, the thin pieces 4 at a plurality of sites of a plurality of the wafers 3 are sequentially transferred to an LC regardless of a difference in recipes or the wafers 3 (FIG. 40 to be described later). This control is a control that does not consider an LC which is a transfer destination or the like, and thin pieces are transferred to vacant locations of a certain LC up to the maximum number of transfer, and when there is no vacancy, the LC is replaced with a subsequent LC to perform transfer.

[Normal Operation Mode (when Classification Name is not Set)]

The inspection management system according to Embodiment 1 can perform a processing operation as shown in a first example in FIG. 49. That is, as a processing operation similar to that in the related art, it is possible to simply and sequentially transfer a plurality of the thin pieces 4 to vacant locations of an LC without considering a classification. For example, modes for performing such a processing operation (for example, names thereof are a “normal operation mode”, a “sequential transfer mode”, or the like) may be provided to enable the user U1 to select a mode on the screen.

FIG. 40 shows an example of a processing operation in the normal operation mode and corresponds to the first example in FIG. 49. In the FIB-SEM device 10 of the first step, for example, the thin pieces 4 are formed at sites (sA and sB) of wafers W1 to W4, and are stored in a FOUP. In the lift out device 20 of the second step, the wafer W1 is first loaded from the FOUP, and an empty “LC 1” is loaded. The lift out device 20 takes out the thin piece from the site sA of the wafer W1, transfers the thin piece to a vacant location of the “LC 1”, then takes out the thin piece 4 from the site sB of the wafer W1, and transfers the thin piece 4 to a vacant location of the “LC 1”. Thereafter, the wafer W1 is unloaded. Next, the lift out device 20 loads the wafer W2. The lift out device 20 sequentially takes out the thin pieces 4 from the respective sites (sA and sB) of the wafer W2, and transfers the thin pieces 4 to vacant locations of the “LC 1”. Thereafter, the wafer W2 is unloaded.

In the present example, it is assumed that the maximum number of transfer of “LC 1” is four. The lift out device 20 unloads the “LC 1” when the thin pieces 4 are mounted on the “LC 1” up to the maximum number and there is no vacancy. Next, the lift out device 20 loads the wafer W3 and loads the “LC 2” as another vacant LC. The lift out device 20 sequentially takes out the thin pieces from sites of the wafer W3 and transfers the thin pieces to vacant locations of the “LC 2”. The lift out device 20 unloads the “LC 2” when the thin pieces 4 are mounted on the “LC 2” up to the maximum number and there is no vacancy.

As described above, according to an instruction, the lift out device 20 transfers the thin piece 4 using a vacant location of an empty LC, and replaces the LC when there is no vacancy. In the case of a policy of the normal operation mode, the number of times of loading and unloading the wafer 3 and the LC in the FIB-SEM device and the lift out device can be reduced, and a TAT can be shortened. In the case of this policy, since a vacancy location of an LC is used to a maximum extent, the number of all used LCs can be saved.

### Effects of Embodiment 1

As described above, according to the inspection management system and the method according to Embodiment 1, it is possible to improve efficiency and the like of the inspection processing including a transfer processing operation for a plurality of sites of a plurality of the wafers 3 in the inspection system 1. According to Embodiment 1, grouping is performed for each wafer, site, or thin piece to which a classification name is assigned, and control can be performed such that, for example, the same container which is a transfer destination is used for each classification. For example, by collectively transferring a plurality of thin pieces having the same classification to the same carrier, the TEM device can collectively observe each carrier under the same observation condition. Accordingly, since switching of observation conditions is reduced, a TAT of an observation processing operation can be shortened, and observation efficiency can be improved.

According to Embodiment 1, it is possible to manage, instruct, and control a processing operation related to transfer of a wafer or a thin piece in the inspection processing sequence using a classification name or a priority, and it is possible to obtain an effect corresponding to a selected policy (for example, an automatic classification pattern).

### <Modification>

Modifications of Embodiment 1 (Examples 1 to 6 or the like) are as follows.

In Example 1, the classification is assigned according to a difference in on-wafer positions and a difference in recipes of the TEM device 30. Examples of a difference in observation conditions include an acceleration voltage and the presence or absence of EDS observation. The invention is not limited thereto, and a classification may be assigned according to a difference in recipes in the FIB-SEM device 10 or a difference in recipes in the lift out device 20 in a modification. For example, when a classification name is set according to the difference in recipes in the FIB-SEM device 10, it is possible to divide a FOUP that stores a target wafer according to a recipe and a classification name for a processing operation of the first processing in the FIB-SEM device 10. For example, when a classification name is set according to the difference in recipes in the lift out device 20, it is possible to divide a FOUP that stores a target wafer or an LC that stores a target thin piece according to a recipe and a classification name for a processing operation of the second processing in the lift out device 20.

### [Modification: Consideration of Loading Number]

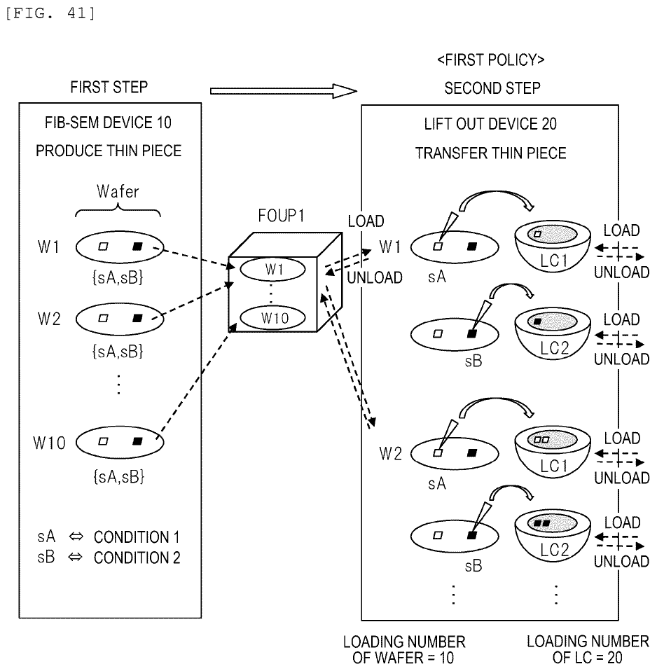

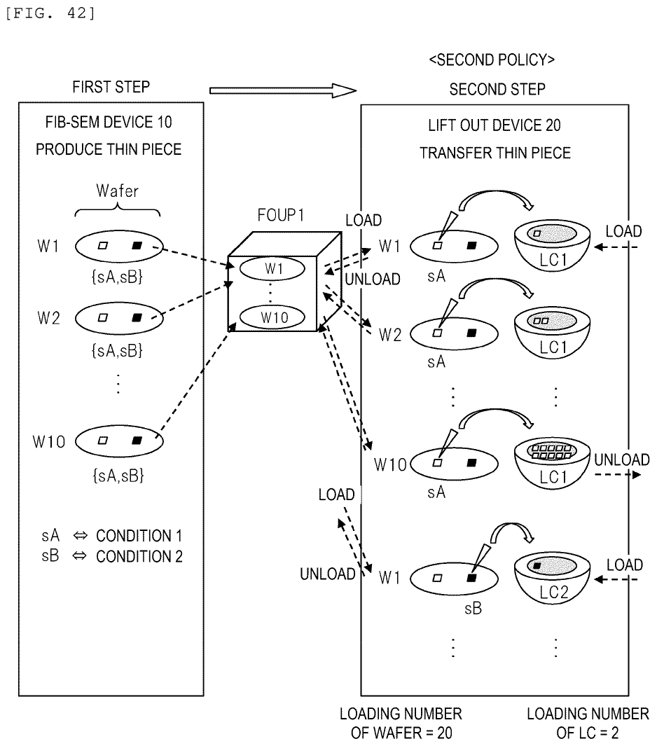

It is also possible to control a transfer processing operation in consideration of the number of loading and unloading in the lift out device 20 or the like according to a modification. FIGS. 41 and 42 show such a modification. For example, the following two policies are possible for details of a transfer processing operation in the lift out device 20. The first policy is to reduce loading and the like of the wafer 3 from a former stage FOUP as much as possible, and the second policy is to reduce loading and the like of a later stage LC as much as possible. The inspection management system 2 may use the transfer instruction information 57 or the like to instruct and control the transfer processing operation according to a policy selected from these policies.

FIG. 41 shows an example of a processing operation according to the first policy. In the FIB-SEM device 10 of the first step, for example, for each of the wafers W1 to W10, the thin pieces 4 are formed at two types of sites (sA and sB) on the wafer and are stored in a FOUP. According to an instruction from the management system 2, the lift out device 20 of the second step first loads the first wafer W1 from the FOUP, sequentially transfers the thin pieces at the two types of sites (sA, sB) of the wafer W1 while loading and unloading LCs (the LC 1 and the LC 2) to replace an LC, and unloads the wafer W1. Next, the lift out device 20 loads the second wafer W2, sequentially transfers the thin pieces at two types of sites of the wafer W2 while loading and unloading LCs (the LC 1 and the LC 2) to replace an LC, and unloads the wafer W2. The same applies to subsequent wafers.

In the case of the first policy, the processing operation is sequentially performed for each wafer as described above. In the case of the first policy, as shown in the drawing, each of the loading and the unloading of the wafer 3 to and from the lift out device 20 is performed for 10 times according to the number of target wafers. Each of the loading and the unloading of the LC to and from the lift out device 20 is performed for 2×10=20 times according to the number of target wafers and the number of sites.

FIG. 42 shows an example of a processing operation according to the second policy. According to an instruction from the management system 2, the lift out device 20 in the second step first loads the “LC 1” from the LCC 7, first loads the first wafer W1 from the FOUP, transfers a thin piece at the site A of the wafer W1 to the “LC 1”, and unloads the wafer W1. Next, the lift out device 20 loads the second wafer W2, transfers a thin piece at the site A of the wafer W2 to the “LC 1”, and unloads the wafer W2. Subsequent wafers up to the wafer W10 are transferred to the “LC 1” in the same manner. Thereafter, the “LC 1” is unloaded. Next, the lift out device 20 loads the “LC 2” from LCC 7, and transfers a thin piece of the site B to the “LC 2” while sequentially loading and unloading the wafers W1 to W10 from the FOUP to replace a wafer. Thereafter, the “LC 2” is unloaded.

In the case of the second policy, the processing operation is sequentially performed for each LC as described above. In the case of the operation according to the second policy, as shown in the drawing, each of the loading and the unloading of the wafer 3 to and from the lift out device 20 is performed for 2×10=20 times according to the number of wafers and the number of sites. Each of the loading and the unloading of the LC to and from the lift out device 20 is performed twice according to the number of sites.

The number of loading and unloading of the wafer 3 and the number of loading and unloading of the LC are different depending on the first policy and the second policy. The inspection management system 2 or the user U1 may select and apply the first policy or the second policy in consideration of the number of loading and unloading. The user U1 may be allowed to select the first policy or the second policy on the GUI screen. The management system 2 may select the first policy or the second policy according to the number of wafers, the number of LCs, the number of corresponding classifications, or the like.

### [Modification: The Number of Vacancies of LC]

As a modification, the inspection management system 2 may manage the number of candidates for the LC that is the carrier 5, the number of vacancies in each LC (the number of vacancy locations where the thin piece 4 can be transferred), and the like in relation to the control of the transfer processing operation, and may determine an LC which is a transfer destination or the like according to the number of vacancies in the LC.

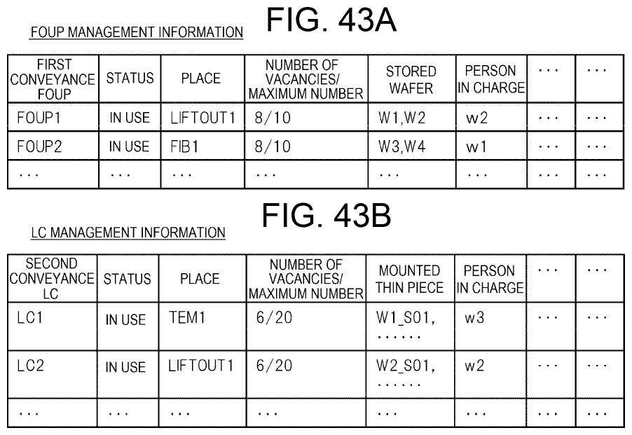

FIG. 43 shows (A) FOUP management information and (B) LC management information as other examples of information managed by the inspection management system 2. The (A) FOUP management information is management information for each FOUP used in the inspection processing sequence. The (B) LC management information is management information for each LC used in the inspection processing sequence. The (A) FOUP management information is, for example, information for managing a configuration and a state of a FOUP (for example, FIG. 27) used in the first conveyance in the first type inspection system 1.

A table of the (A) FOUP management information includes items of columns of a first conveyance FOUP, a status, a place, the number of vacancies/the maximum number, a stored wafer, a person in charge, and the like. The first conveyance FOUP indicates an ID of a FOUP used in the first conveyance step. The status indicates a state value such as “in use” and “unused” of the FOUP. The place indicates a place where the FOUP is currently present. The item “the number of vacancies/the maximum number” indicates the maximum number of wafers (for example, the number of slots) that can be stored in the FOUP and the current number of vacancies. The stored wafer indicates an ID of a wafer that is currently stored in the FOUP. The person in charge indicates a person in charge of the work handling the FOUP. In the present example, the FOUP management information does not include slot information and the like.

A table of the (B) LC management information includes items of columns of a second conveyance LC, a status, a place, the number of vacancies/the maximum number, a mounted thin piece, a person in charge, and the like. The second conveyance LC indicates an ID of an LC used in the second conveyance step. The status indicates a state value such as “in use” and “unused” of the LC. The place indicates a place where the LC is currently present. The item of “the number of vacancies/the maximum number” indicates the maximum number of thin pieces that can be mounted on the LC (for example, the number of support portions 5b) and the current number of vacancies. The mounted thin piece indicates an ID of a thin piece that is currently mounted on the LC. The person in charge indicates a worker in charge of the work handling the LC. In the present example, the LC management information does not include information on a position of the support portion 5b to which a thin piece is to be transferred.

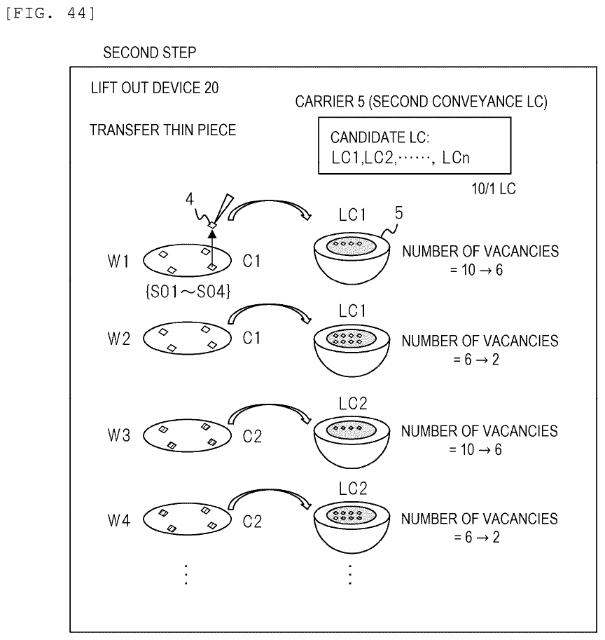

FIG. 44 shows an example in which the management system 2 determines an LC which is a transfer destination of the thin piece 4 in consideration of the number of vacancies LCs. Based on the LC management information as shown in FIG. 43 and the like, the management system 2 grasps the number of available candidate LCs, the number of vacancies of each LC, and a state such as which LC is currently present in which device of which step, and determines, for example, a processing operation in the lift out device 20, an LC which is a transfer destination for the thin piece 4, and the like according to the state. The management system 2 performs control in consideration of the number of vacancies of an LC based on control using the classification name described above.

In the example of FIG. 44, for example, the thin pieces 4 on the wafers W1 to W4 or the like are transferred to an LC by the lift out device 20 in the second step. For example, there are n LCs such as LC 1 to LCn as the candidate LCs used in the second conveyance step. Each LC has the maximum number of transfer, and for example, the maximum number of transfer is 10. Based on instruction information from the management system 2, the lift out device 20 first sequentially takes out the thin pieces 4 from sites (for example, S01 to S04) of the wafer W1 (the classification C1), and sequentially transfers the thin pieces 4 to a designated LC which is a transfer destination. First, the “LC 1” with the number of vacancies=10 is selected, and four thin pieces are transferred to the “LC 1”, so that the number of vacancies=6. Next, the thin pieces 4 are sequentially taken out from sites (for example, S01 to S04) of the wafer W2 (the same classification C1) and sequentially transferred to the designated LC which is a transfer destination. Here, the “LC 1” with the number of vacancies=6 is selected, and four thin pieces are further transferred to the “LC 1”, so that the number of vacancies=2.

Next, the lift out device 20 sequentially takes out the thin pieces 4 from sites (for example, S01 to S04) of the wafer W3 (the classification C2) and sequentially transfers the thin pieces 4 to a designated LC which is a transfer destination. Here, in order to divide LCs according to the classification, the “LC 2” with the number of vacancies=10 is selected instead of the “LC 1” with the number of vacancies=2, and four thin pieces are transferred to the “LC 2”, so that the number of vacancies=6. Next, the thin pieces 4 are sequentially taken out from sites (for example, S01 to S04) of the wafer W4 (the same classification C2) and sequentially transferred to a designated LC which is a transfer destination. Here, the “LC 2” with the number of vacancies=6 is selected, and four thin pieces are further transferred to the “LC 2”, so that the number of vacancies=2.

### [Modification: Additional Inspection]

According to a modification, the user U1 of the inspection management system 2 confirms an image or the like of an observation result in the TEM device 30 on a screen as a result of the inspection processing executed by the inspection system 1, and determines whether an additional inspection is necessary. The inspection management system 2 has a function of supporting the additional inspection. When it is determined that the additional inspection is necessary, the inspection management system 2 creates instruction information about the additional inspection for the thin piece 4 of the target wafer 3 for which the additional inspection processing is necessary. At this time, the management system 2 creates instruction information such that the thin piece 4 to be subject to the additional inspection are transferred to the same LC as much as possible.

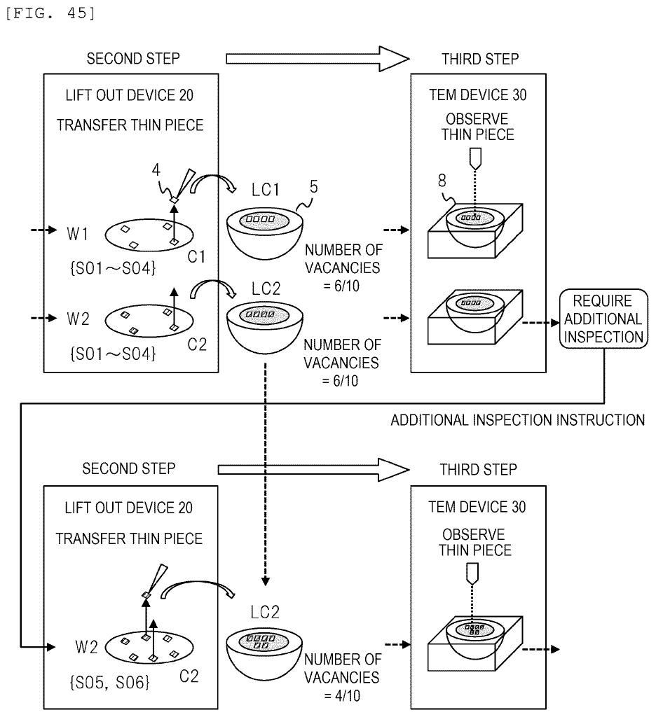

FIG. 45 shows an example of the additional inspection. FIG. 45 shows only the second step and the third step in the first type inspection system 1. In the inspection processing of the first type inspection system 1, for example, for the sites S01 to S04 of the wafer W1 having the first classification C1 and the sites S01 to S04 of the wafer W2 having the second classification, the thin pieces at the sites S01 to S04 of the wafer W1 are transferred to the “LC 1” and the thin pieces at the sites S01 to S04 of the wafer W2 are transferred to the “LC 2”, and these thin pieces are observed in the TEM device 30. As a result of the inspection processing, the management system 2 or the user U1 determines that, for example, an additional inspection for the thin pieces 4 of the wafer W2 is necessary.

The management system 2 creates instruction information to produce the thin pieces 4 to be used in the first step and the second step for sites (for example, the sites S05 and S06) different from the thin pieces 4 at the sites S01 to S04 on the target wafer W2 to be subject to the additional inspection. According to the instruction information, the thin pieces 4 are formed at the sites S05 and S06 of the wafer W2 in the FIB-SEM device 10, and the thin pieces 4 are taken out from the sites S05 and S06 of the wafer W2 and transferred to an LC in the lift out device 20. When determining an LC which is a transfer destination, the management system 2 sets, as the transfer destination, the “LC 2” with the number of vacancies of two or more after the inspected thin pieces 4 having the same classification C2 are transferred. The two thin pieces 4 from the sites S05 and S06 of the wafer W2 are additionally transferred to the “LC 2”. Then, the TEM device 30 performs additional observation on the two additional thin pieces on the “LC 2”.

As described above, even when the additional inspection and the additional observation occurs, for example, the additional thin pieces 4 are transferred in a manner of being collected into the same LC using a classification and the number of vacancies. A worker can easily performing the work of taking out an LC from a stock shelf or the LCC 7. Therefore, work efficiency of the additional inspection including the additional observation can be improved.

### [Instruction Method]

FIG. 46 shows an example of an instruction method and communication between the inspection management system 2 and the inspection system 1 according to Embodiment 1 and a modification. The management system 2 transmits an instruction for execution management of the inspection processing sequence (including an instruction for a transfer processing operation) to each device of the inspection system 1 based on the machining instruction information 53, the transfer instruction information 57, the status and result management information 54, and the like described above and based on an operation of starting execution of an inspection processing from the user U1. Each device of the inspection system 1 performs a processing operation in own device based on the instruction, and appropriately transmits a response indicating an execution status, a progress status, a result, and the like to the management system 2. In other words, each instruction is a request or a signal. Each instruction corresponds to the information described in the above-described Example 1 and the like. A lower part of FIG. 46 shows a flow of the first processing, the first conveyance, the second processing, the second conveyance, and the third processing in the inspection processing sequence with a horizontal axis as a time axis. For example, an instruction 4601 is transmitted at a time t1, and a response 4602 is transmitted at a time t2.

The management system 1 first transmits the instruction 4601 to the FIB-SEM device 10 (for example, the “FIB 1”) in the first step. The FIB-SEM device 10 performs a processing operation of the first processing (for example, thinning machining) in own device according to the instruction 4601. Examples of the processing operation related to transfer in the FIB-SEM device 10 include loading of a wafer from a FOUP and unloading and storing of a wafer on which a thin piece is formed to a FOUP. The FIB-SEM device 10 controls such a processing operation according to the instruction 4601. That is, a target FOUP, a wafer, a site, the presence or absence of loading or unloading, an order, and the like are controlled.

The FIB-SEM device 10 transmits the response 4602 to the management system 2 as appropriate. The response 4602 is, for example, a progress status or a result of the first processing for a plurality of designated target wafers or sites, error information in a case where there is an error, or the like. For example, when the first processing is completed, the FIB-SEM device 10 transmits the response 4602 indicating the completion together with necessary information such as delivery. Based on the response 4602, the management system 2 grasps a state and a result of the processing operation in the FIB-SEM device 10, and updates the status and result management information 54.

Next, the management system 2 transmits an instruction 4603 to the lift out device 20 in the second step. The lift out device 10 performs a processing operation of the second processing (for example, the lift out processing) in own device according to the instruction 4603. For example, a processing operation related to transfer in the lift out device 20 includes loading of a wafer from a FOUP, loading of an LC from an LCC, and transfer of a thin piece taken out from the wafer onto the LC. The lift out device 20 controls such a processing operation according to the instruction 4603. That is, a target FOUP, an LCC, an LC, a wafer, presence or absence of loading or unloading, an order, and the like are controlled.

The lift out device 20 transmits a response 4604 to the management system 2 as appropriate. The response 4604 is, for example, a progress status or a result of the second processing for a plurality of designated target wafers or sites, error information in a case where there is an error, or the like. For example, when the second processing is completed, the lift out device 20 transmits the response 4604 indicating the completion together with necessary information such as delivery. Based on the response 4604, the management system 2 grasps a state, a result, and the like of the processing operation in the lift out device 20, and updates the status and result management information 54.

Next, the management system 2 transmits an instruction 4605 to the TEM device 30 in the third step. The TEM device 30 performs a processing operation of the third processing (for example, cross section observation) in own device according to the instruction 4605. Examples of the processing operation related to transfer in the TEM device 30 include loading of an LC (the cartridge 8) from an LCC. The TEM device 30 controls such a processing operation according to the instruction 4605. That is, a target LC, the thin piece 4, the presence or absence of loading or unloading, an order, and the like are controlled.

The TEM device 30 transmits a response 4606 to the management system 2 as appropriate. The response 4606 is, for example, a progress status or a result of the third processing for the plurality of thin pieces 4 of a designated target LC, error information in a case where there is an error, or the like. For example, when the third processing is completed, the TEM device 30 transmits the response 4606 indicating the completion together with necessary information such as delivery. Based on the response 4606, the management system 2 grasps a state and a result of the processing operation in the TEM device 30, and updates the status and result management information 54.

### [Work Instruction]

FIG. 47 is a diagram showing a case where a work instruction related to a transfer processing operation is transmitted from the management system 2 to a worker in a case where work of the worker is performed in the inspection processing sequence in relation to the above-described instruction method. The case of the first type will be described. The inspection management system 2 creates a work instruction for a worker associated with a step based on the machining instruction information 53 and the transfer instruction information 47 described above. The management system 2 may transmit the work instruction to a device of a corresponding step and display the work instruction on a screen of the device, or may transmit the work instruction to, for example, a mobile terminal carried by the worker.

As an example of a correspondence relation between a step and a worker, it is assumed that a worker w1 is in charge of the first processing of the first step and the first conveyance step, a worker w2 is in charge of the second processing of the second step and the second conveyance step, and a worker w3 is in charge of the third processing of the third step.

For example, the management system 2 transmits a work instruction 4701 related to the first step to the worker w1 at a timing (a time t1) corresponding to the start of the first processing in the FIB-SEM device 10 of the first step. The worker w1 who received the work instruction 4701 confirms contents of the work instruction 4701 and performs work about a processing operation of the first processing in the FIB-SEM device 10 (for example, FIG. 27). The worker w1 sets a designated FOUP in the designated FIB-SEM device 10 (for example, the “FIB 1”) according to the work instruction 4701. The FIB-SEM device 10 performs a processing operation of the first processing on the FOUP according to the above-described instruction and information. As a result, a FOUP that stores the wafer 3 on which the thin piece portion 4a is formed is obtained. The worker w1 conveys the FOUP to the designated lift out device 20 (for example, the “LIFT OUT 1”) of the second step in the first conveyance step.

The management system 2 may transmit a work instruction 4702 related to the first conveyance to the worker w1 at a timing (a time t2) of the end of the first processing.

The management system 2 transmits a work instruction 4703 related to the second step to the worker w2 at a timing (a time t3) corresponding to the start of the second processing in the lift out device 20 of the second step. The worker w2 who received the work instruction 4703 confirms contents of the work instruction 4703, and performs work about a processing operation of the second processing in the lift out device 20 (for example, FIG. 28). According to the work instruction 4703, the worker w2 sets the designated FOUP in the designated lift out device 20 (for example, the “LIFT OUT 1”), and sets the designated LCC 7 in the lift out device 20. The lift out device 20 performs a processing operation of the second processing on the FOUP and the LCC 7 according to the instruction and the information described above. As a result, the LCC 7 that stores an LC to which the thin piece 4 is transferred is obtained. The worker w2 conveys the designated LCC 7 to the designated TEM device 30 (for example, the “TEM 1”) in the third step in the second conveyance step.

The management system 2 may transmit a work instruction 4704 related to the second conveyance to the worker w2 at a timing (a time t4) of the end of the second processing.

The management system 2 transmits a work instruction 4705 related to the third step to the worker w3 at a timing (a time t5) corresponding to the start of the third processing in the lift out device 30 of the third step. The worker w3 who received the work instruction 4705 confirms contents of the work instruction 4705 and performs work about a processing operation of the third processing in the TEM device 30 (for example, FIG. 31). The worker w3 sets a designated LC of the designated LCC 7 in the designated TEM device 30 (for example, the “TEM 1”) according to the work instruction 4705. The TEM device 30 performs a processing operation of the third processing on the LC according to the instruction and information described above.

As in the above example, the inspection processing sequence including human work can be made more efficient by providing a work instruction from the management system 2 to a worker. According to the work instruction, the worker can easily grasp, for example, which FOUP or which LCC 7 is set in which device, which device is conveyed, and the like.

### [Modification: Use of Plural Devices]

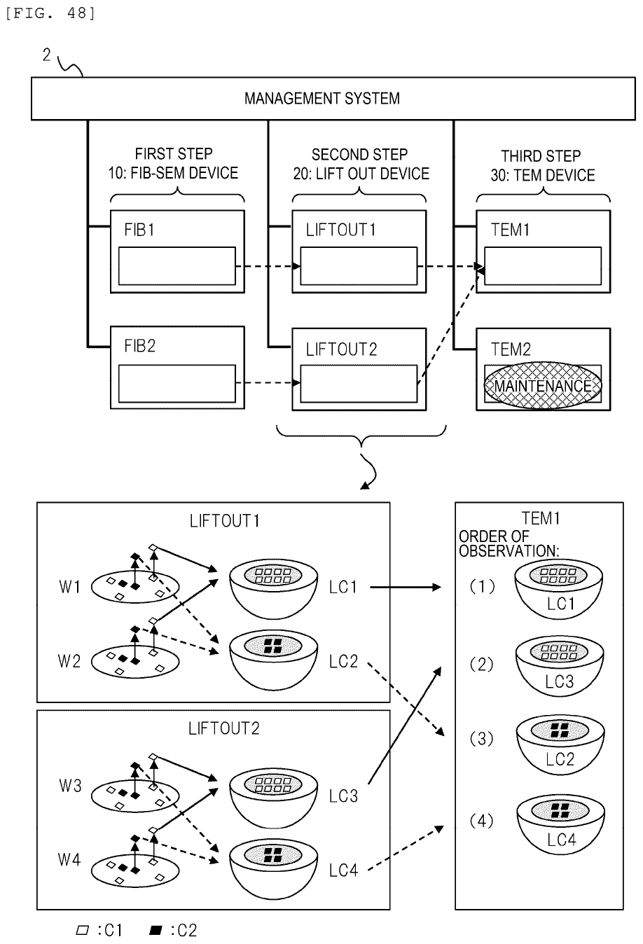

As described above, the number of devices in each step of the inspection system 1 is not limited to one, and a plurality of devices may be used. FIG. 48 shows an example of a case where a plurality of devices are used in each step. In the case of such an inspection system 1, the inspection management system 2 can instruct and control a processing operation such as transfer according to a classification in consideration of the number of devices in each step, a vacancy state, and the like in a similar manner to Embodiment 1.

For example, when a plurality of the lift out devices 20 are operated and only one TEM device 30 is operated, the plurality of lift out devices 20 perform processing in parallel, and efficiency of the observation processing operation in the TEM device 30 can be controlled with emphasis by using the above-described automatic classification pattern “TEM observation recipe unit” or the like, and as a result, efficiency of the overall inspection processing sequence can be improved.

For example, when only one lift out device 20 is operated and a plurality of the TEM devices 30 are operated, the plurality of TEM devices 30 perform processing in parallel, and efficiency of the transfer processing operation in the lift out device 20 can be controlled with emphasis by using the above-described automatic classification pattern “wafer unit” or the like, and as a result, efficiency of the overall inspection processing sequence can be improved.

In the example of FIG. 48, there are two sets of the FIB-SEM device 10, the lift out device 20, and the TEM device 30 in the first type inspection system 1. For example, a “TEM 2” of the TEM 30 cannot be used for maintenance and inspection. In this case, the inspection management system 2 creates an instruction for the inspection system 1 by using the above-described setting of the automatic classification pattern “TEM observation recipe unit” based on an operation of the user U1 in order to improve observation efficiency in the TEM device 30.

In the shown example, thin pieces of the wafers W1 and W2 are transferred to the “LC 1” and the “LC 2” in a divided manner according to the classifications C1 and C2 in the first “LIFT OUT 1” of the lift out device 20. In parallel with this, in a second “LIFT OUT 2”, thin pieces of the wafers W3 and W4 are transferred to the “LC 3” and the “LC4” in a divided manner according to the classifications C1 and C2. Then, the “LC 1” to “LC4” are conveyed to the “TEM 1” which is one of the TEM devices 30, and the “LC 1” to “LC4” are sequentially observed in the “TEM 1”. In the “TEM 1”, since the same observation condition is set for each LC, a TAT for observation can be shortened. As in the above example, it is possible to improve efficiency of the overall inspection processing sequence by effectively utilizing a plurality of devices according to a classification.

Embodiments of the present disclosure have been specifically described above, but are not limited to the embodiments described above, and various modifications can be made without departing from the scope of the present disclosure. In each embodiment, components can be added, deleted, replaced, or the like except for essential components. Unless otherwise specified, each component may be single or plural. The embodiments can be combined.

### REFERENCE SIGNS LIST

1 inspection system
2 inspection management system
3 wafer
4 thin piece
5 carrier
6 holder
10 thin piece production device (FIB-SEM device)
20 thin piece transfer device (lift out device)
30 thin piece observation device (TEM device)

1. An inspection management system for managing an inspection of a sample performed by an inspection system that inspects the sample, wherein
the inspection performed by the inspection system is implemented as an inspection processing sequence in which first processing, second processing, and third processing are sequentially performed by a first type device, a second type device, and a third type device that are devices for performing different kinds of processing,
the inspection system is configured to perform the inspection processing sequence including producing a thin piece from the sample at each site that is a target location of the inspection, transferring the thin piece to a carrier, and performing processing related to the inspection for each of the thin pieces on the carrier, and
the inspection management system is configured to create instruction information including an instruction of an order of transfer and the transfer destination carrier for a processing operation of taking out a plurality of thin pieces from a plurality of the sites of a plurality of the samples and transferring the thin pieces to a plurality of the carriers, which is instruction information related to a processing operation of the inspection processing sequence of the inspection system.

2. The inspection management system according to claim 1, wherein
the inspection management system is configured to
assign classification information to each of the samples or each of the sites, and
create the instruction information for each classification.

3. The inspection management system according to claim 2, wherein
the inspection management system is configured to create the instruction information for transferring the thin pieces having the same classification to the same carrier as much as possible.

4. The inspection management system according to claim 2, wherein
one classification policy is a policy of the classification according to a difference in a type of the site, and
the inspection management system is configured to automatically assign the classification information according to the classification policy according to the difference in the type of the site.

5. The inspection management system according to claim 2, wherein
one classification policy is a policy of the classification according to a difference of wafers which are the samples, and
the inspection management system is configured to automatically assign the classification information according to the classification policy according to the difference of wafers.

6. The inspection management system according to claim 4, wherein
the difference in the type of the site is a difference in an area on the sample where the site belongs or a difference in an observation recipe for the site.

7. The inspection management system according to claim 2, wherein
the inspection management system is configured to provide a user with a screen for setting the classification information for each of the sites on the target sample.

8. The inspection management system according to claim 2, wherein
the inspection management system is configured to provide a user with a screen for setting a machining instruction for giving an instruction of contents including a recipe of a processing operation of each device of the inspection system as contents of the inspection processing sequence for the target sample, and
the inspection management system is configured to assign the classification information for each of the sites of the target sample based on information about the machining instruction.

9. The inspection management system according to claim 2, wherein
the classification policy includes plural policies of a first policy which is a classification policy according to a difference in a type of the site, and a second policy which is a classification policy according to a difference of wafers which are the samples,
the inspection management system is configured to provide a user with a screen for setting the classification policy, and
the inspection management system is configured to automatically assign the classification information according to the set classification policy.

10. The inspection management system according to claim 2, wherein
the inspection management system is configured to
assign priority information related to the inspection to the sample or the site, in addition to the classification information, and
create the instruction information such that the inspection processing sequence for the sample or the site having a relatively high priority is performed before the inspection processing sequence for the sample or the site having a relatively low priority.

11. The inspection management system according to claim 1, wherein
the inspection management system is communicably connected to each device of the first type device, the second type device, and the third type device which are a plurality of devices of the inspection system, and is configured to give an instruction of a processing operation of the inspection processing sequence of the inspection system based on the instruction information.

12. The inspection management system according to claim 1, wherein
each device of the inspection system reads an ID from a container set in the device and acquires the instruction information from the inspection management system based on the read ID.

13. The inspection management system according to claim 1, wherein
the inspection management system is configured to manage a state of a container used in the inspection processing sequence, and create the instruction information for controlling a processing operation of the transfer according to the number of vacancies of the container.

14. The inspection management system according to claim 2, wherein
the inspection management system is configured to create the instruction information such that the classification information is not assigned to the target sample in the case of a setting in which the classification is not performed, and the plurality of thin pieces are sequentially taken out from the plurality of sites of the plurality of samples for the samples that do not have the classification information, and the thin pieces are sequentially transferred to vacant locations of the vacant carrier.

15. The inspection management system according to claim 1, wherein
the first type device is a thin piece production device configured to perform a processing operation of forming the thin piece on the sample,
the second type device is a thin piece transfer device configured to perform a processing operation of taking out the thin piece formed on the sample and transferring the thin piece to the carrier,
the third type device is a thin piece observation device configured to perform a processing operation of observing the thin piece mounted on the carrier, and
in the inspection processing sequence,
a first container that stores the sample is set in the first type device, and in the first type device, the thin piece is produced on the sample loaded from the first container and the sample on which the thin piece is produced is unloaded to the first container,
the first container is conveyed from the first type device to the second type device,
the first container is set in the second type device, and a second container, in which the carrier is set, is set in the second type device, and in the second type device, the thin piece is taken out from the sample loaded from the first container, the taken-out thin piece is transferred onto the carrier loaded from the second container, and the carrier to which the thin piece is transferred is unloaded to the second container,
the second container is conveyed from the second type device to the third type device, and
the carrier taken out from the second container is set in the third type device, and the thin piece on the carrier is observed in the third type device.

16. The inspection management system according to claim 1, wherein
the first type device is a first type thin piece production device configured to perform a processing operation of forming the thin piece on the sample, taking out the thin piece formed on the sample, and transferring the thin piece to the carrier,
the second type device is a second type thin piece production device configured to perform a processing operation of final finishing the thin piece mounted on the carrier,
the third type device is a thin piece observation device configured to perform a processing operation of observing the thin piece mounted on the carrier, and
in the inspection processing sequence,
a first container that stores the sample is set in the first type device, a second container that stores the carrier is set in the first type device, and in the first type device, the thin piece is formed on the sample loaded from the first container, the thin piece is taken out from the sample, the taken-out thin piece is transferred to the carrier loaded from the second container, and the carrier to which the thin piece is transferred is unloaded to the second container,
the second container is conveyed from the first type device to the second type device,
the second container is set in the second type device, and in the second type device, the final finishing is performed on the thin piece mounted on the carrier loaded from the second container, and the carrier on which the finished thin piece is mounted is unloaded to the second container,
the second container is conveyed from the second type device to the third type device, and
the carrier taken out from the second container is set in the third type device, and the thin piece on the carrier is observed in the third type device.

17. An inspection management method for an inspection management system to manage an inspection of a sample performed by an inspection system that inspects the sample, wherein
the inspection performed by the inspection system is implemented as an inspection processing sequence in which first processing, second processing, and third processing are sequentially performed by a first type device, a second type device, and a third type device that are devices for performing different kinds of processing,
the inspection system is configured to perform the inspection processing sequence including producing a thin piece from the sample at each site that is a target location of the inspection, transferring the thin piece to a carrier, and performing processing related to the inspection for each of the thin pieces on the carrier, and
the inspection management system is configured to create instruction information including an instruction of an order of transfer and the transfer destination carrier for a processing operation of taking out the plurality of thin pieces from a plurality of the sites of a plurality of the samples and transferring the thin pieces to a plurality of the carriers, which is instruction information related to a processing operation of the inspection processing sequence of the inspection system.
